(19) United States
(12) Patent Application Publication
(10) Pub. No.: US 2023/0125445 A1
(43) Pub. Date: Apr. 27, 2023

(54) COMPOSITION, TRANSFER FILM, MANUFACTURING METHOD FOR LAMINATE, MANUFACTURING METHOD FOR CIRCUIT WIRE, AND MANUFACTURING METHOD FOR ELECTRONIC DEVICE

(71) Applicant: FUJIFILM Corporation, Tokyo (JP)

(72) Inventors: Satoru YAMADA, Fujinomiya-shi (JP); Akio TAMURA, Fujinomiya-shi (JP); Kazumasa MOROZUMI, Fujinomiya-shi (JP); Tatsuya SHIMOYAMA, Fujinomiya-shi (JP)

(73) Assignee: FUJIFILM Corporation, Tokyo (JP)

(21) Appl. No.: 18/146,009

(22) Filed: Dec. 23, 2022

Related U.S. Application Data
(63) Continuation of application No. PCT/JP2021/023525, filed on Jun. 22, 2021.

(30) Foreign Application Priority Data
Jun. 26, 2020 (JP) 2020-110611

(51) Int. Cl. G03F 7/038; G03F 7/028; C08F 220/28; H05K 3/06

(52) U.S. Cl. CPC G03F 7/0382; G03F 7/028; C08F 220/286; H05K 3/064

(57) ABSTRACT

A first object of the present invention is to provide a composition having excellent coatability. In addition, a second object of the present invention is to provide a composition, a transfer film, a manufacturing method for a laminate, a manufacturing method for a circuit wire, and an electronic device, which are related to the composition.

A composition of the present invention includes a compound A having one or more specific structures selected from the group consisting of (a), (b), and (c), and a resin.
(a) a perfluoroalkenyl group,
(b) a perfluoropolyether group, and
(c) a group represented by General Formula (C1) or General Formula (C2),

*—Cm⁺Am⁻[-L^{m}-(Rf)ₘ₂]ₘ₁ (C1)

*-An⁻Cn⁺[-Lⁿ-(Rf)ₙ₂]ₙ₁ (C2)

### CROSS-REFERENCE TO RELATED APPLICATIONS

This application is a Continuation of PCT International Application No. PCT/JP2021/023525 filed on Jun. 22, 2021, which claims priority under 35 U.S.C. § 119(a) to Japanese Patent Application No. 2020-110611 filed on Jun. 26, 2020. The above applications are hereby expressly incorporated by reference, in their entirety, into the present application.

### BACKGROUND OF THE INVENTION

### 1. Field of the Invention

The present invention relates to a composition, a transfer film, a manufacturing method for a laminate, a manufacturing method for a circuit wire, and an electronic device.

In recent years, a transfer film such as a photosensitive transfer material has been increasingly used in various fields.

Since the photosensitive transfer material can contribute to cost reduction of the product, it has been proposed to use the photosensitive transfer material as a film for an etching resist, a film for a wire protective film, or the like.

Accordingly, depending on each field, not only the properties of a polymer as a matrix but also the coatability in producing a transfer film has become important.

For example, in WO2018/008376A, a transfer film is produced by using a photosensitive composition to which an oligomer containing a fluorine-containing group and a lipophilic group is added (see [0211], [0214], [0215], and the like in WO2018/008376A).

### SUMMARY OF THE INVENTION

As a result of studies by the inventors of the present invention, it was found that there is room for improvement in the coatability of such a composition (a photosensitive composition) as disclosed in WO2018/008376A.

It is noted that the excellent coatability of a composition is intended to mean that in a case where a composition is applied, the cissing of the composition is less likely to occur, the coating unevenness of the composition is less likely to occur, and thus a uniform film (a composition layer) is easily obtained.

An object of the present invention is to provide a composition having excellent coatability. In addition, another object of the present invention is to provide a composition, a transfer film, a manufacturing method for a laminate, a manufacturing method for a circuit wire, and an electronic device, which are related to the composition.

As a result of carrying out intensive studies to achieve the objects, the inventors of the present invention found that the objects can be achieved by the following configurations.

[1] A composition comprising:

a compound A having one or more specific structures selected from the group consisting of (a), (b), and (c); and

a resin;

(a) a perfluoroalkenyl group,

(b) a perfluoropolyether group, and

(c) a group represented by General Formula (C1) or General Formula (C2),

*—Cm⁺Am⁻[-L^{m}-(Rf)ₘ₂]ₘ₁ (C1)

*-An⁻Cn⁺[-Lⁿ-(Rf)ₙ₂]ₙ₁ (C2)

in General Formula (C1), * represents a bonding position, m1 represents an integer of 1 or more, m2 represents an integer of 1 or more, Cm⁺ represents a cationic group, Am⁻ represents an anionic group, L^{m} represents a single bond or an (m2+1)-valent linking group, and Rf represents a fluoroalkyl group,

in General Formula (C2), * represents a bonding position, n1 represents an integer of 1 or more, n2 represents an integer of 1 or more, An⁻ represents an anionic group, Cn⁺ represents a cationic group, Lⁿ represents a single bond or an (n2+1)-valent linking group, and Rf represents a fluoroalkyl group,

[2] The composition according to [1], in which the (a) is a group selected from the group consisting of a group represented by General Formula (a1), a group represented by General Formula (a2), and a group represented by General Formula (a3),

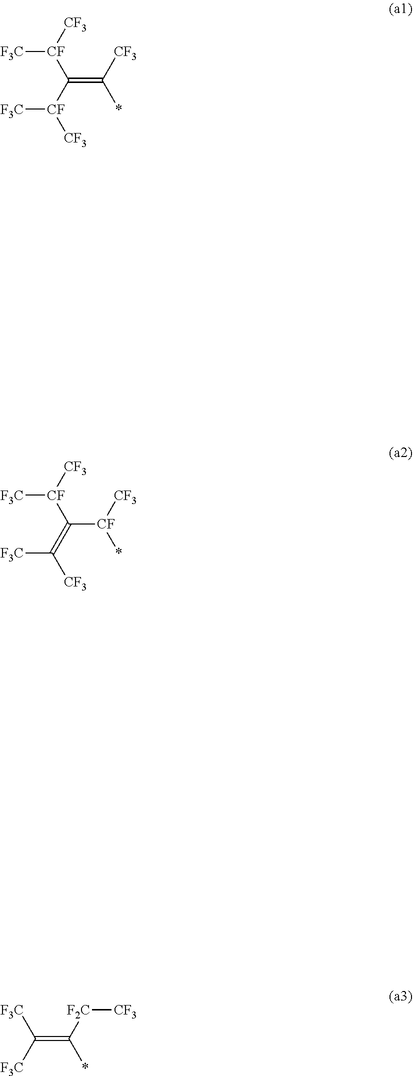

in General Formulae (a1) to (a3), * represents a bonding position.

[3] The composition according to [1] or [2], in which the compound A is a high-molecular-weight compound containing a constitutional unit having the specific structure in a side chain.

[4] The composition according to [1] or [2], in which the compound A has a molecular weight of 2,000 or less.

[5] The composition according to any one of [1] to [4], further comprising a polymerizable compound and a polymerization initiator, in which the resin is an alkali-soluble resin.

[6] The composition according to any one of [1] to [4], further comprising a photoacid generator, in which the resin is a resin having an acid group protected by an acid-decomposable group.

[7] The composition according to any one of [1] to [4], in which the resin is a water-soluble resin.

[8] The composition according to any one of [1] to [4], in which the resin is a thermoplastic resin.

[9] The composition according to any one of [1] to [4], further comprising one or more kinds of materials selected from the group consisting of a metal oxide, a compound having a triazine ring, and a compound having a fluorene skeleton.

[10] The composition according to any one of [1] to [4], further comprising a pigment.

[11] A transfer film comprising:

a temporary support; and

one or more composition layers,

in which at least one layer of the composition layers is a layer formed of the composition according to any one of [1] to [10].

[12] A manufacturing method for a laminate, comprising:

an affixing step of bringing a substrate into contact with a surface of the transfer film according to [11] on a side opposite to the temporary support and affixing the transfer film to the substrate to obtain a transfer film-attached substrate;

an exposure step of subjecting the composition layer to pattern exposure;

a development step of developing the exposed composition layer to form a resin pattern; and

a peeling step of peeling the temporary support from the transfer film-attached substrate, between the affixing step and the exposure step or between the exposure step and the development step.

[13] A manufacturing method for a circuit wire, comprising:

an affixing step of bringing a surface of the transfer film according to [11] on a side opposite to the temporary support into contact with a substrate having a conductive layer and affixing the transfer film to the substrate having the conductive layer to obtain a transfer film-attached substrate;

an exposure step of subjecting the composition layer to pattern exposure;

a development step of developing the exposed composition layer to form a resin pattern;

an etching step of subjecting the conductive layer in a region where the resin pattern is not disposed to an etching treatment; and

a peeling step of peeling the temporary support from the transfer film-attached substrate, between the affixing step and the exposure step or between the exposure step and the development step.

[14] A manufacturing method for an electronic device, comprising:

the manufacturing method for a laminate according to [12],

in which the electronic device includes the resin pattern as a cured film.

According to the present invention, it is possible to provide a composition having excellent coatability. In addition, it is possible to provide a composition, a transfer film, a manufacturing method for a laminate, a manufacturing method for a circuit wire, and an electronic device, which are related to the composition.

### BRIEF DESCRIPTION OF THE DRAWINGS

FIG. 1 is a schematic view illustrating an example of a configuration of a transfer film.

### DESCRIPTION OF THE PREFERRED EMBODIMENTS

Hereinafter, the present invention will be described in more detail.

The following description of configuration requirements is based on representative embodiments of the invention; however, the present invention is not limited thereto.

In the present invention, the numerical value range indicated by using “to” means a range including the numerical values before and after “to” as the lower limit value and the upper limit value, respectively.

In addition, a bonding direction of a divalent group (for example, —CO—O—) described in the present specification is not particularly limited.

In the present specification, (meth)acrylate indicates acrylate and methacrylate. The (meth)acrylic acid indicates acrylic acid and methacrylic acid. The (meth)acryloyl group indicates a methacryloyl group or an acryloyl group.

In describing a group (an atomic group) of the present specification, in a case where a description does not indicate substitution and non-substitution, the description means the group includes a group having a substituent as well as a group having no substituent. For example, the description “alkyl group” includes not only an alkyl group that does not have a substituent (an unsubstituted alkyl group) but also an alkyl group that has a substituent (a substituted alkyl group). Further, the “organic group” in the present specification means a group containing at least one carbon atom.

Further, in the present specification, the kind of substituent, the position of substituent, and the number of substituents are not particularly limited in a case of being described as “may have a substituent”. The number of substituents may be, for example, one, two, three, or more. In addition, it may be unsubstituted.

Examples of the substituent include a monovalent non-metal atomic group excluding a hydrogen atom, and for example, the following substituent group T can be selected.

(Substituent T)

Examples of the substituent T include halogen atoms such as a fluorine atom, a chlorine atom, a bromine atom, and an iodine atom; alkoxy group such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and tert-butylsulfanyl group; arylsulfanyl groups such as a phenylsulfanyl group and a p-tolylsulfanyl group; an alkyl group; a cycloalkyl group; an aryl group; a heteroaryl group; a hydroxyl group; a carboxy group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group; and combinations thereof.

In the present specification, unless otherwise specified, the weight-average molecular weight (Mw) and the number-average molecular weight (Mn) are values calculated in terms of polystyrene by gel permeation chromatography (GPC).

The measurement by GPC is carried out under the following conditions.

[Eluent] tetrahydrofuran (THF)

[Device name] EcoSEC HLC-8320GPC (manufactured by Tosoh Corporation)

[Column] TSKgel SuperHZM-H, TSKgel SuperHZ4000, TSKgel SuperHZ200 (manufactured by Tosoh Corporation)

[Column temperature] 40° C.

[Flow rate] 0.35 mL/min

In the present specification, unless otherwise specified, the molecular weight of a compound having a molecular weight distribution is the weight-average molecular weight (Mw).

In the present specification, unless otherwise specified, the room temperature is 25° C.

In the present specification, “alkali-soluble” means that the solubility in 100 g of an aqueous solution of 1% by mass sodium carbonate at 22° C. is 0.1 g or more.

In the present specification, “water-soluble” means that the solubility in 100 g of water having a liquid temperature of 22° C. and a pH of 7.0 is 0.1 g or more.

In the present specification, the layer thickness (the film thickness) of each layer included in the transfer film or the like is measured by observing a cross section of a layer (a film) in a direction perpendicular to the main surface of the photosensitive transfer material with a scanning electron microscope (SEM), measuring the thickness of each layer at 10 points or more based on the obtained observation image, and calculating the average value thereof.

[Composition]

A composition according to the embodiment of the present invention contains a compound A having a specific structure, and a resin.

The mechanism by which the objects of the present invention are achieved by such configurations is not clear; however, the inventors of the present invention presume as follows.

First, in a case where the compound A has a perfluoropolyether group (a specific structure (b)), flexibility is introduced into the compound, and in a case where it has a group (a specific structure (c)) represented by General Formula (C1) or General Formula (C2), an ion bonding site is introduced. Such a compound A has good compatibility with a resin or the like in the composition and good solubility in an organic solvent (which may be a water-soluble solvent) to be added as desired. As a result, it is conceived that the aggregation of the compound A in the composition is less likely to occur, the coating unevenness of the composition is less likely to occur, and thus the coatability is improved.

In addition, in a case where the compound A has a perfluoroalkenyl group (a specific structure (a)), the transferability of the compound A to the surface of the coating film is improved. Due to the presence of such a compound A in the composition, the surface tension of the coating film is reduced, and the wettability of the composition with respect to the substrate and the plane shape of the surface of the coating film at the time of coating are improved, which is also conceived to affects the improvement of the coatability.

[Compound A]

The composition according to the embodiment of the present invention contains a compound A.

The compound A has one or more specific structures selected from the group consisting of (a), (b), and (c);

(a) a perfluoroalkenyl group,

(b) a perfluoropolyether group, and

(c) a group represented by General Formula (C1) or General Formula (C2),

Hereinafter, the specific structures (a) to (c) will be described in detail, and then, a specific form of the compound will be described.

<Specific Structure>

The compound A has at least one kind of the specific structures (a) to (c), and it may have two or more kinds thereof.

It suffices that the total number of the specific structures included in the compound A is 1 or more, where the upper limit thereof is not limited, and it is, for example, 1,000.

(Specific Structure (a))

The specific structure (a) is a perfluoroalkenyl group.

The perfluoroalkenyl group may be linear or branched.

The perfluoroalkenyl group preferably has 2 to 100 carbon atoms, more preferably 2 to 20 carbon atoms, and still more preferably 5 to 10 carbon atoms.

The number of C═C double bonds contained in the perfluoroalkenyl group is 1 or more, preferably 1 to 5, more preferably 1 to 2, and still more preferably 1.

Among the above, the specific structure (a) is preferably a group selected from the group consisting of a group represented by General Formula (a1), a group represented by General Formula (a2), and a group represented by General Formula (a3). In General Formulae (a1) to (a3), * represents a bonding position.

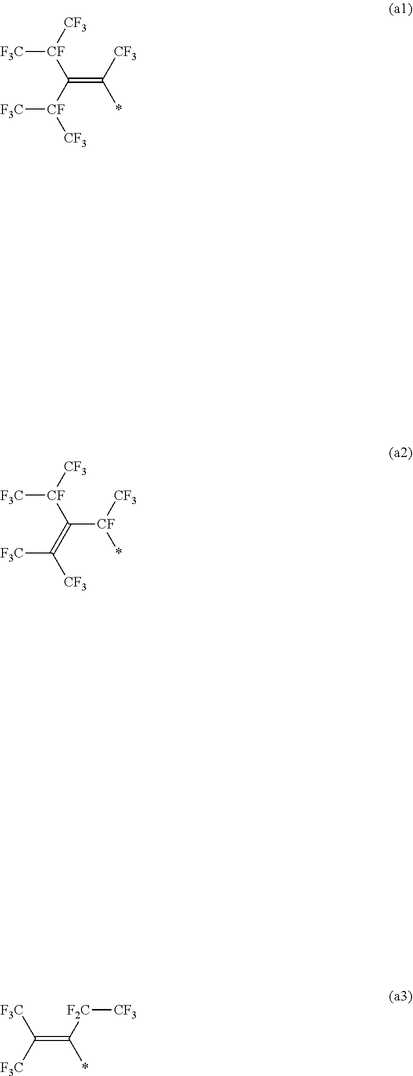

In addition, in a case where the compound A has a plurality of specific structures (a), it is also preferable that the compound A has a plurality of kinds of the specific structures (a). Examples of the form having a plurality of kinds of the specific structure (a) include a form having at least a group represented by General Formula (a1) and a group represented by General Formula (a2).

In addition, in a case where the compound A having the specific structure (a) is used, it is also preferable to use the compounds A respectively having the specific structures (a) differing in kind. Examples of the form in which the compounds A respectively having the specific structures (a) differing in kind are used include a form in which at least the compound A having a group represented by General Formula (a1) and the compound A having a group represented by General Formula (a2) are used in combination.

(Specific Structure (b))

The specific structure (b) is a perfluoropolyether group.

The perfluoropolyether group is a divalent group in which a plurality of perfluoroalkylene groups are bonded by an ether bond. The perfluoropolyether group may be linear, branched, or cyclic, and it is preferably linear or branched and more preferably linear.

The specific structure (b) is preferably a group represented by General Formula (b1).

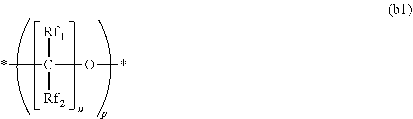

In General Formula (b1), * represents a bonding position.

u represents an integer of 1 or more. u is preferably 1 to 10, more preferably 1 to 6, and still more preferably 1 to 3.

p represents an integer of 1 or more. p is 1 or more, and it is more preferably 2 or more. The upper limit of p is preferably 100 or less, more preferably 80 or less, and still more preferably 60 or less.

Rf₁ and Rf₂ each independently represent a fluorine atom or a perfluoroalkyl group. The perfluoroalkyl group may be linear or branched, and it preferably has 1 to 10 carbon atoms.

In a case where a plurality of u's, Rf₁'s, and Rf₂'s are present in General Formula (b1), the plurality of u's, Rf₁'s, and Rf₂'s may be the same or different from each other. In a case where a plurality of pieces of ([CRf₁Rf₂]ᵤO) are present in General Formula (b1), the pieces of ([CRf₁Rf₂]ᵤO) may be the same or different from each other.

The group bonded at the bonding position (*) on the right side in General Formula (b1) is a hydrogen atom or a substituent, and it is preferably a hydrogen atom, a halogen atom, or an organic group, and it is more preferably a fluorine atom or an alkyl group. The alkyl group may be linear or branched, and it preferably has 1 to 10 carbon atoms. The substituent which may be contained in the alkyl group is preferably a fluorine atom or a hydroxyl group. It is also preferable that the alkyl group is a perfluoroalkyl group.

It is also preferable that the specific structure (b) forms a group represented by General Formula (b2) in combination with a structure other than the specific structure (b).

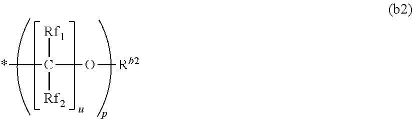

In General Formula (b2), * represents a bonding position.

The partial structure represented by “([CRf₁Rf₂]ᵤO)ₚ” in General Formula (b2) is the same as the partial structure represented by “([CRf₁Rf₂]ᵤO)ₚ” in General Formula (b1).

In General Formula (b2), R^{b2} represents a hydrogen atom or a substituent. The substituent is preferably a fluorine atom or an alkyl group. The alkyl group may be linear or branched, and it preferably has 1 to 10 carbon atoms. The substituent which may be contained in the alkyl group is preferably a fluorine atom or a hydroxyl group. It is also preferable that the alkyl group is a perfluoroalkyl group.

(Specific Structure (c))

The specific structure (c) is a group represented by General Formula (C1) or General Formula (C2).

General Formula (C1)

General formula (C1) is shown below.

*—Cm⁺Am⁻[-L^{m}-(Rf)ₘ₂]ₘ₁ (C1)

In General Formula (C1), * represents a bonding position.

m1 represents an integer of 1 or more. m1 is preferably 1 to 5, more preferably 1 to 3, and still more preferably 1.

m2 represents an integer of 1 or more. m2 is preferably 1 to 5, more preferably 1 to 3, and still more preferably 1.

In General Formula (C1), Cm⁺ represents a cationic group.

Examples of the cationic group represented by Cm⁺ include “—N⁺R^{N}₃”, “—C⁺R^{C}₂”, and a pyridinium-yl group.

In “—N⁺R^{N}₃”, three pieces of R^{N}'s each independently represent a hydrogen atom or a substituent, where the substituent is preferably an organic group and more preferably an alkyl group. The alkyl group may be linear or branched, and it preferably has 1 to 10 carbon atoms. It is also preferable that one to three pieces of R^{N}'s are a hydrogen atom.

In “—C⁺R^{C}₂”, two pieces of R^{C}'s each independently represent a hydrogen atom or a substituent. The substituent is preferably an organic group.

In General Formula (C1), Am⁻ represents an anionic group.

Examples of the anionic group represented by Am⁻ include —COO⁻, —O⁻, and —SO₃⁻.

In a case where Am⁻ is —COO⁻, —O⁻, or —SO₃⁻, m1 is 1.

In General Formula (C1), L^{m} represents a single bond or an (m2+1)-valent linking group.

In a case where L^{m} is a single bond, m2 in “—(Rf)ₘ₂” to which L^{m} is bonded represents 1.

In addition, the value of m2 in L^{m} which is an (m2+1)-valent linking group is intended to be the value of m2 in “—(Rf)ₘ₂” to which L^{m} is bonded.

Examples of L^{m} which is an (m2+1)-valent linking group include an ether group, a carbonyl group, an ester group, a thioether group, —SO₂—, —NR^{X}— (R^{X} is a hydrogen atom or a substituent), an alkylene group, an alkenylene group, an alkynylene group, a trivalent group represented by “—N<”, a trivalent group represented by “—CR^{Y}<” (R^{Y} is a hydrogen atom or a substituent), a tetravalent group represented by “>C<”, an aromatic ring group, an alicyclic group, and a group obtained by combining these.

The alkylene group may be linear or branched, and it preferably has 1 to 10 carbon atoms.

Examples of the alkylene group include a linear alkylene group such as a methylene group, an ethylene group, a propylene group, a butylene group, a pentylene group, a hexylene group, or a decylene group; and a branched alkylene group such as a dimethylmethylene group, a methylethylene group, a 2,2-dimethylpropylene group, and a 2-ethyl-2-methylpropylene group.

The aromatic ring group and the alicyclic group each independently may have or may not have one or more (for example, 1 to 3) heteroatoms. The aromatic ring group and the alicyclic group may be each independently monocyclic or polycyclic. The number of ring members of the aromatic ring group is, for example, 5 to 15, and the number of ring members of the alicyclic group is, for example, 3 to 15. It is preferable that the aromatic ring group and the alicyclic group are each independently a divalent to hexavalent group.

Examples of the aromatic ring group include aromatic hydrocarbon ring groups such as a benzene ring group (a phenylene group, a benzene-1,2,4-yl group, or the like), a naphthalene ring group (a naphthylene group or the like), an anthracene ring group, and a phenanthroline ring group; and aromatic heterocyclic groups such as a furan ring group, a pyrrole ring group, a thiophene ring group, a pyridine ring group, a thiazole ring group, and a benzothiazole ring group.

In addition, by combining two or more aromatic ring groups or one or more aromatic ring groups and a group other than the aromatic ring group, L^{m} which is an (m2+1)-valent linking group may have, as a part or the whole thereof, a biphenyl-diyl group, a 2,2′-methylenebisphenyldiyl group, or the like.

Examples of the alicyclic group include cycloalkane ring groups such as a cyclopropane ring group, a cyclobutane ring group, a cyclopentane ring group, a cyclohexane ring group, a cyclooctane ring group, a cyclodecane ring group, an adamantane ring group, a norbornane ring group, and an exo-tetrahydrodicyclopentadiene ring group, and a cyclohexene ring group.

The substituent other than Rf, which may be contained in the alkylene group, the alkenylene group, the alkynylene group, the aromatic ring group, and the alicyclic group, and the substituent which is represented by R^{X} and R^{Y} are preferably an alkyl group, an alkoxy group, a halogen atom, or a hydroxyl group. The alkyl group is preferably a linear, branched, or cyclic alkyl group having 1 to 18 carbon atoms, more preferably an alkyl group having 1 to 8 carbon atoms (for example, a methyl group, an ethyl group, a propyl group, an isopropyl group, an n-butyl group, an isobutyl group, a sec-butyl group, a t-butyl group, or a cyclohexyl group), still more preferably an alkyl group having 1 to 4 carbon atoms, and particularly preferably a methyl group or an ethyl group. The alkoxy group is preferably, for example, an alkoxy group having 1 to 18 carbon atoms, more preferably an alkoxy group having 1 to 8 carbon atoms (for example, a methoxy group, an ethoxy group, an n-butoxy group, or a methoxyethoxy group), still more preferably an alkoxy group having 1 to 4 carbon atoms, and particularly preferably a methoxy group or an ethoxy group. The halogen atom is preferably a fluorine atom or a chlorine atom.

In addition, L^{m} which is an (m2+1)-valent linking group may have, as a part or the whole thereof, a perfluoropolyether group as described as the specific structure (b).

Examples of L^{m} which is an (m2+1)-valent linking group include an alkylene group, -an alkylene group-an ester group-, -an alkylene group-an ester group-an alkylene group-, -a carbonyl group-an alkylene group-, -an ether group-an alkylene group-, and -an aromatic ring group (-an ether group-an alkylene group-)ₘ₂.

In General Formula (C1), Rf represents a fluoroalkyl group.

The fluoroalkyl group may be linear or branched.

The fluoroalkyl group has 1 or more carbon atoms, and it preferably has 2 or more carbon atoms and more preferably 6 or more carbon atoms. The upper limit of the number of carbon atoms is preferably 100 or less, more preferably 20 or less, and still more preferably 10 or less.

It suffices that the fluoroalkyl group has one or more (for example, 1 to 30) fluorine atoms as the substituent, and the fluoroalkyl group may have or may not have a substituent other than the fluorine atom.

The fluoroalkyl group may be a perfluoroalkyl group.

In General Formula (C1), L^{m}'s, m2's, and Rf's in a case where a plurality of L^{m}'s, m2's, and Rf's are present may be the same or different from each other. In addition, in a case where a plurality of pieces of [-L^{m}-(Rf)ₘ₂] are present, the pieces of [-L^{m}-(Rf)ₘ₂] may also be the same or different from each other.

The partial structure represented by “Am⁻[-L^{m}-(Rf)ₘ₂]ₘ₁” in General Formula (C1) will be exemplified below.

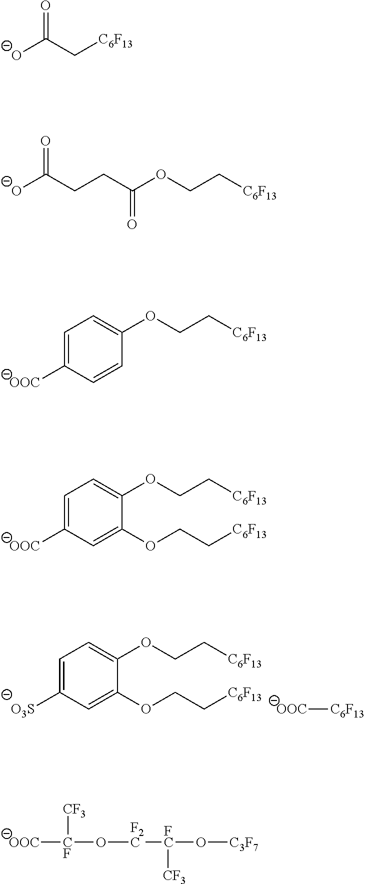

General Formula (C2)

General formula (C2) is shown below.

*-An⁻Cn⁺[-Lⁿ-(Rf)ₙ₂]ₙ₁ (C2)

in General Formula (C2), * represents a bonding position,

n1 represents an integer of 1 or more, n1 is preferably 1 to 5, more preferably 1 to 3, and still more preferably 1.

n2 represents an integer of 1 or more, n2 is preferably 1 to 5, more preferably 1 to 3, and still more preferably 1.

In General Formula (C2), An⁻ represents an anionic group.

Examples of the anionic group represented by An⁻ include —COO⁻, —O⁻, and —SO₃⁻.

In General Formula (C2), Cn⁺ represents a cationic group.

Examples of the cationic group represented by Cn⁺ include “R^{S}₍₄₋ₙ₁₎N⁺(—*)ₙ₁”, “R^{T}₍₃₋ₙ₁₎C⁺(—*)ₙ₁”, and a pyridinium ring group.

In “R^{S}₍₄₋ₙ₁₎N⁺(—*)ₙ₁”, the n1 pieces of *'s are bonding positions to [-Lⁿ-(Rf)ₙ₂]. In a case where Cn⁺ is “R^{S}₍₄₋ₙ₁₎N⁺(—*)ₙ₁”, n1 in General Formula (C2) is an integer of 1 to 4. The (4−n1) pieces of R^{S}'s each independently represent a hydrogen atom or a substituent. However, the substituent is other than [-Lⁿ-(Rf)ₙ₂]. The substituent is preferably an organic group and more preferably an alkyl group. The alkyl group may be linear or branched, and it preferably has 1 to 10 carbon atoms. Two pieces of R^{S}'s may be bonded to each other to form a ring.

In “R^{T}₍₃₋ₙ₁₎C⁺(—*)ₙ₁”, the n1 pieces of *'s are bonding positions to [-Lⁿ-(Rf)ₙ₂]. In a case where Cn⁺ is “R^{T}₍₃₋ₙ₁₎C⁺(—*)ₙ₁”, n1 in General Formula (C2) is an integer of 1 to 3. The (3−n1) pieces of R^{T}'s each independently represent a hydrogen atom or a substituent. However, the substituent is other than [-Lⁿ-(Rf)ₙ₂]. Two pieces of R^{T}'s may be bonded to each other to form a ring.

In a case where Cn⁺ is a pyridinium ring group, n1 in General Formula (C2) is an integer of 1 to 6, and it is preferably 1 to 3 and more preferably 1. The ring member atom of the pyridinium ring group bonded to [-Lⁿ-(Rf)ₙ₂] may be only a carbon atom, may be only a nitrogen atom, or may be both a carbon atom and a nitrogen atom.

In General Formula (C2), Lⁿ represents a single bond or an (n2+1)-valent linking group.

The details of the (n2+1)-valent linking group represented by Lⁿ in General Formula (C2) are, for example, the same as the details of the (m2+1)-valent linking group represented by L^{m} in General Formula (C1).

For example, a linking group having a form in which “m2” in the (m2+1)-valent linking group represented by L^{m} in General Formula (C1) is replaced with “n2” can be used as an (n2+1)-valent linking group represented by Lⁿ in General Formula (C2).

In General Formula (C2), Rf represents a fluoroalkyl group.

Rf in General Formula (C2) is, for example, the same as Rf in General Formula (C1).

In General Formula (C2), Lⁿ's, n2's, and Rf's in a case where a plurality of Lⁿ's, n2's, and Rf's are present may be the same or different from each other. In addition, in a case where a plurality of pieces of [-Lⁿ-(Rf)ₙ₂] are present, the pieces of [-Lⁿ-(Rf)ₙ₂] may also be the same or different from each other.

The partial structure represented by “Cn⁻[-Lⁿ-(Rf)ₙ₂]ₙ₁” in General Formula (C2) will be exemplified below.

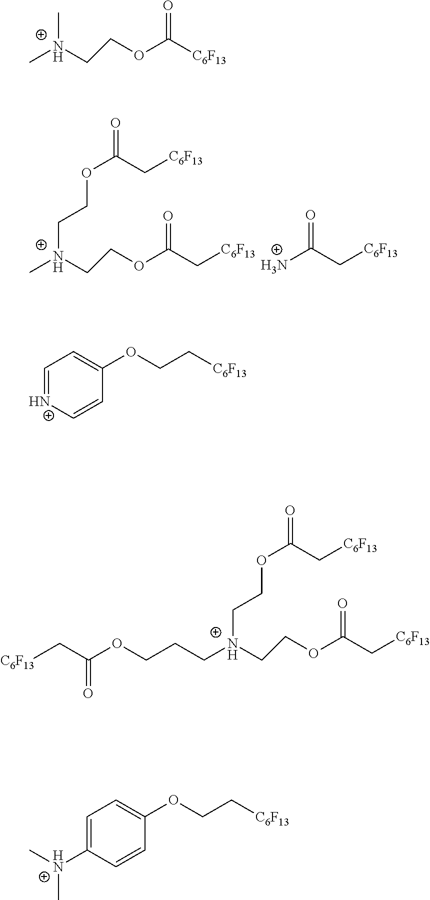

<Structure of Compound A>

It suffices that the compound A is a compound having a specific structure, and the compound A may be a high-molecular-weight compound or may be a low-molecular-weight compound.

In addition, for example, the molecular weight of the compound A may be 2,000 or less or may be more than 2,000.

Hereinafter, an aspect in which the compound A is a high-molecular-weight compound and an aspect in which the compound A is a low-molecular-weight compound will be described.

(Compound a which is High-Molecular-Weight Compound (High-Molecular-Weight Compound A))

The compound A, which is a high-molecular-weight compound, is also referred to as particularly a high-molecular-weight compound A.

The molecular weight (the weight-average molecular weight) of the high-molecular-weight compound A is preferably 1,000 to 100,000, more preferably 1,500 to 90,000, and still more preferably more than 2,000 and 80,000 or less. The number-average molecular weight (Mn) of the high-molecular-weight compound A is preferably 500 to 40,000, more preferably 600 to 35,000, and still more preferably 600 to 30,000.

The dispersivity (Mw/Mn) of the high-molecular-weight compound A is preferably 1.00 to 12.00, more preferably 1.00 to 11.00, and still more preferably 1.00 to 10.00.

The high-molecular-weight compound A is preferably a high-molecular-weight compound containing a constitutional unit having a specific structure in the side chain.

Constitutional Unit Represented by General Formula (I)

The high-molecular-weight compound A preferably has a constitutional unit represented by General Formula (I).

The constitutional unit represented by General Formula (I) is also an example of a constitutional unit having a specific structure in the side chain.

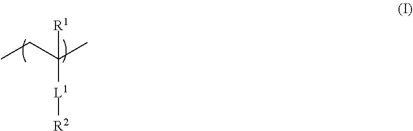

In General Formula (I), R¹ represents a hydrogen atom, a fluorine atom, a chlorine atom, or an alkyl group having 1 to 20 carbon atoms.

The alkyl group may be linear or branched.

In General Formula (I), R² represents a group having a specific structure. R² may be a group having a specific structure as a part thereof or may be a specific structure itself.

For example, R² may be a group having the specific structure (a). In this case, R² is preferably a group having the specific structure (a) and more preferably a group represented by General Formula (a1), a group represented by General Formula (a2), or a group represented by General Formula (a3).

R² may be a group having the specific structure (b), and in this case, it is preferably a group represented by General Formula (b2).

R² may be a group having the specific structure (c). In this case, R² is preferably a group represented by General Formula (C1) or a group represented by General Formula (C2).

The specific structure is as described above.

Among the above, R² is preferably a group having the specific structure (a).

In General Formula (I), L¹ represents a single bond or a divalent linking group.

Examples of the divalent linking group include an ether group, a carbonyl group, an ester group, a thioether group, —SO₂—, —NR^{X}— (R^{X} is a hydrogen atom or a substituent), an alkylene group, an alkenylene group, an alkynylene group, an aromatic ring group, an alicyclic group, and a group obtained by combining these.

Examples of the divalent linking group represented by L¹ include a group having a form in which m2 is 1 in the (m2+1)-valent linking group represented by L^{m} in General Formula (C1) described above.

Among the above, the divalent linking group represented by L¹ preferably has —O—, —CO—O—, and/or —CO—NH—.

Examples of the divalent linking group represented by L¹ include *^{A}—CO—O-an alkylene group-*^{B}, *^{A}—O-an alkylene group-CO—O—*^{B}, *^{A}—CO—NH-an alkylene group-*^{B}, *^{A}—CO—O-an alkylene group-NH—CO—*^{B}, *^{A}—CO—O-an alkylene group-NH—CO-an alkylene group-*^{B}, and *^{A}—CO—O—R^{1B}—O—*^{B}.

In each of the above divalent linking groups, *^{A} and *^{B} represent a bonding position. Either *^{A} or *^{B} may be the bonding position on the R² side, and it is preferable that *^{B} is the bonding position on the R² side.

In the above *^{A}—CO—O—R^{1B}—O—*^{B}, R^{1B} represents a divalent linking group having 2 to 50 carbon atoms.

The divalent linking group having 2 to 50 carbon atoms may have a heteroatom, and it may be an aromatic group, a heteroaromatic group, a heterocyclic group, an aliphatic group, or an alicyclic group.

Examples of R^{1B} include the following groups:

—(CH₂)_{w1}— (w1=2 to 50)

—X—Y—(CH₂)_{w2}— (w2=2 to 43)

—X—(CH₂)_{w3}— (w3=1 to 44)

—CH₂CH₂(OCH₂CH₂)_{w4}— (w4=1 to 24)

—XCO(OCH₂CH₂)_{w5}— (w5=1 to 21)

In each of the above-described groups, the bonding site at the left end may be bonded on the *^{A} side of *^{A}—CO—O—R^{1B}—O—*^{B} or may be bonded on the *^{B} side thereof. In each of the above groups, X represents a phenylene group, a biphenyl-diyl group, or a naphthylene group. It is also preferable that these groups each independently have one to three substituents selected from the group consisting of an alkyl group having 1 to 3 carbon atoms (a methyl group, an ethyl group, a propyl group, or the like), an alkoxy group having 1 to 4 carbon atoms (a methoxy group, an ethoxy group, a propoxy group, a butoxy group, or the like), and a halogen atom (F, Cl, Br, I, or the like).

X is preferably a 1,2-phenylene group, a 1,3-phenylene group, or a 1,4-phenylene group, and it is more preferably a 1,4-phenylene group.

Y represents —O—CO—, —CO—O—, —CONH—, or —NHCO—.

Among the above, R^{1B} is preferably the following group.

—(CH₂)_{w6}— (w6=2 to 10)

—C₆H₄OCO(CH₂)_{w7}— (w7=2 to 10)

—C₆H₄(CH₂)_{w8}— (w8=1 to 10)

—CH₂CH₂(OCH₂CH₂)_{w9}— (w9=1 to 10)

—C₆H₄CO(OCH₂CH₂)_{w10}— (w10=1 to 10)

Above the above, in a case where R² in General Formula (I) has the specific structure (a), it is also preferable that L¹ is *^{A}—CO—O—R^{1B}—O—*^{B}.

In a case where the high-molecular-weight compound A is a copolymer, the content of the constitutional unit represented by General Formula (I) is preferably 2% to 100% by mass, more preferably 3% to 90% by mass, and still more preferably 5% to 80% by mass, with respect to the total mass of the high-molecular-weight compound A.

One kind of the constitutional unit represented by General Formula (I) may be used alone, or two or more kinds thereof may be used.

The constitutional unit having a specific structure (preferably a constitutional unit represented by General Formula (I)) can be synthesized by a known method.

It is also preferable that the high-molecular-weight compound A has a constitutional unit having no specific structure.

Hereinafter, an example of a constitutional unit having no specific structure will be described.

Constitutional Unit Having Fluorine Atom

The high-molecular-weight compound A may have a constitutional unit having a fluorine atom.

However, the constitutional unit having a fluorine atom does not include the specific structure.

The constitutional unit having a fluorine atom is preferably a constitutional unit represented by General Formula (UF).

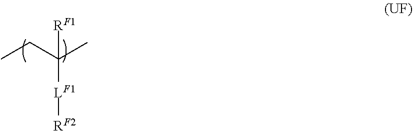

In General Formula (UF), R^{F1} represents a hydrogen atom, a fluorine atom, a chlorine atom, or an alkyl group having 1 to 20 carbon atoms. The alkyl group may be linear or branched.

L^{F1} represents a single bond or a divalent linking group. The divalent linking group represented by L^{F1} in General Formula (UF) may have, for example, the same configuration as the configuration of the divalent linking group represented by L¹ in General Formula (I) described above.

Among the above, L^{F1} is preferably —CO—O-an alkylene group-. The alkylene group may be linear or branched, and it preferably has 1 to 10 carbon atoms. In the —CO—O-an alkylene group-, —CO— is preferably present on the main chain side.

R^{F2} represents an organic group having a fluorine atom, and it is preferably a fluoroalkyl group. The fluoroalkyl group may be linear or branched, and it preferably has 1 to 10 carbon atoms. It suffices that the fluoroalkyl group has one or more (for example, 1 to 30) fluorine atoms as the substituent, and the fluoroalkyl group may have or may not have a substituent other than the fluorine atom.

The fluoroalkyl group may be a perfluoroalkyl group.

In a case where the high-molecular-weight compound A contains a constitutional unit having a fluorine atom, the content thereof is preferably 1% to 65% by mass, more preferably 5% to 55% by mass, and still more preferably 15% to 45% by mass, with respect to the total mass of the high-molecular-weight compound A.

One kind of the constitutional unit having a fluorine atom may be used alone, or two or more kinds thereof may be used.

Constitutional Unit Having Polymerizable Group

The high-molecular-weight compound A may have a constitutional unit having a polymerizable group.

Examples of the polymerizable group include an ethylenically unsaturated group (for example, an (meth)acryloyl group, a vinyl group, or a styryl group) and a cyclic ether group (for example, an epoxy group or an oxetanyl group), where an ethylenically unsaturated group is preferable, and an (meth)acryloyl group is more preferable.

The constitutional unit having a polymerizable group is preferably a constitutional unit represented by General Formula (UP).

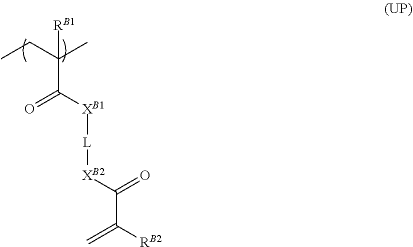

In General Formula (UP), X^{B1} and X^{B2} each independently represent —O— or —NR^{N}—. R^{N} represents a hydrogen atom or an alkyl group. The alkyl group may be linear or branched, and it preferably has 1 to 5 carbon atoms.

L represents an alkylene group or an arylene group. The alkylene group may be linear or branched, and it preferably has 1 to 5 carbon atoms. The arylene group may be monocyclic or polycyclic, and it preferably has 6 to 15 carbon atoms. The alkylene group and the arylene group may have a substituent, and examples of the substituent include a hydroxyl group.

R^{B1} and R^{B2} each independently represent a hydrogen atom or an alkyl group. The alkyl group may be linear or branched. The alkyl group preferably has 1 to 5 carbon atoms and more preferably has one carbon atom.

In a case where the high-molecular-weight compound A contains a constitutional unit having a polymerizable group, the content thereof is preferably 1% to 50% by mass, more preferably 2% to 30% by mass, and still more preferably 5% to 15% by mass, with respect to the total mass of the high-molecular-weight compound A.

One kind of constitutional unit having a polymerizable group may be used alone, or two or more kinds thereof may be used.

Constitutional Unit Having Polyoxyalkylene Group

The high-molecular-weight compound A may have a constitutional unit having a polyoxyalkylene group.

The constitutional unit having a polyoxyalkylene group is preferably a constitutional unit having a group represented by (-AL-O—)_{nAL}.

In “(-AL-O—)_{nAL}”, nAL represents an integer of 1 or more, and it is preferably 2 or more, more preferably 2 to 100, and still more preferably 4 to 20.

AL represents an alkylene group. The alkylene group may be linear or branched, and it preferably has 1 to 10 carbon atoms. Among the above, AL is preferably —CH₂CH₂—, —CH(CH₃)CH₂—, or —CH(CH₂CH₃)CH₂—. The nAL pieces of AL's may be the same or different from each other.

The constitutional unit having a polymerizable group is preferably a constitutional unit represented by General Formula (UA).

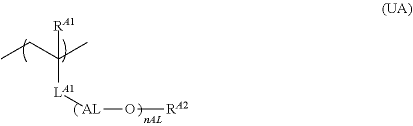

In General Formula (UA), R^{A1} represents a hydrogen atom, a fluorine atom, a chlorine atom, or an alkyl group having 1 to 20 carbon atoms. The alkyl group may be linear or branched.

L^{A1} represents a single bond or a divalent linking group. The divalent linking group represented by L^{A1} in General Formula (UA) may have, for example, the same configuration as that of the divalent linking group represented by L¹ in General Formula (I) described above.

Among the above, L^{A1} is preferably —CO—O—. In this case, it is preferable that —CO— is present on the main chain side.

(-AL-O—)_{nAL} in General Formula (UA) is the same as the group represented by (-AL-O—)_{nAL} described above.

R^{A2} represents a hydrogen atom or a substituent. R^{A2} is preferably a hydrogen atom.

In a case where the high-molecular-weight compound A contains a constitutional unit having a polyoxyalkylene group, the content thereof is preferably 5% to 90% by mass, more preferably 10% to 80% by mass, and still more preferably 20% to 70% by mass, with respect to the total mass of the high-molecular-weight compound A.

One kind of constitutional unit having a polymerizable group may be used alone, or two or more kinds thereof may be used.

In a case where the high-molecular-weight compound A is a copolymer, it is also preferable that the high-molecular-weight compound A has a block structure, a graft structure, a branch structure, and/or a star structure.

(Compound A which is Low-Molecular-Weight Compound (Low-Molecular-Weight Compound A))

The compound A, which is a low-molecular-weight compound, is also referred to as particularly a low-molecular-weight compound A.

The low-molecular-weight compound A is a compound having at least one (for example, 1 to 3) specific structure.

The molecular weight of the low-molecular-weight compound A is preferably 100 or more and more preferably 500 or more. The upper limit of the molecular weight of the low-molecular-weight compound A is preferably 5,000 or less, more preferably 3,000 or less, and still more preferably 2,000 or less.

Compound Represented by General Formula (II)

The low-molecular-weight compound A is preferably a compound represented by General Formula (II).

General formula (II) is shown below.

R²-L²-R³ (II)

In General Formula (II), R² represents a group having a specific structure.

R² in General Formula (II) is the same as R² in General Formula (I).

In General Formula (II), L² represents a single bond or a divalent linking group. The divalent linking group represented by L² in General Formula (II) may have, for example, the same configuration as the configuration of the divalent linking group represented by L¹ in General Formula (I) described above.

Among the above, the divalent linking group represented by L² preferably has, for example, —O—, —CO—O—, and —CO—NH—. The carbonyl group in —CO—O— and —CO—NH— described above may be present on the R² side or may be present on the R³ side.

In General Formula (II), R³ represents a hydrophilic group.

The hydrophilic group is preferably, for example, a group having a polyethyleneoxy group, a group having a polypropyleneoxy group, a group having a polybutyleneoxy group, a group having a phenyleneoxy group, a carbobetaine group, or a sulfobetaine group, and it is more preferably a group having a polyethyleneoxy group or a group having a polypropyleneoxy group.

The carbobetaine group is, for example, “*-L^{A}-N⁺R₂-L^{B}-COO—”, and the sulfobetaine group is, for example, “*-L^{A}-N⁺R₂-L^{B}-SO₃—” (L^{A} and L^{B} are each independently a linear or branched alkylene group having 1 to 6 carbon atoms, and R's each independently a linear or branched alkyl group having 1 to 6 carbon atoms).

It is also preferable that R³ is a group represented by *—(-AL-O—)_{nAL}—R^{3R}.

In the above, * represents a bonding position.

nAL represents an integer of 1 or more, and it is preferably 2 or more, more preferably 2 to 100, and still more preferably 4 to 20.

AL represents an alkylene group or an arylene group (a phenylene group or the like). The alkylene group may be linear or branched, and it preferably has 1 to 10 carbon atoms. Among the above, AL is preferably —CH₂CH₂—, —CH(CH₃)CH₂—, or —CH(CH₂CH₃)CH₂—. The nAL pieces of AL's may be the same or different from each other.

R^{3R} represents a hydrogen atom or a substituent. The substituent is preferably an alkyl group. The alkyl group may be linear or branched, and it preferably has 1 to 10 carbon atoms.

The compound A will be exemplified below. In the following compounds, Rfₐ is a group represented by any of General Formula (a1) to (a3).

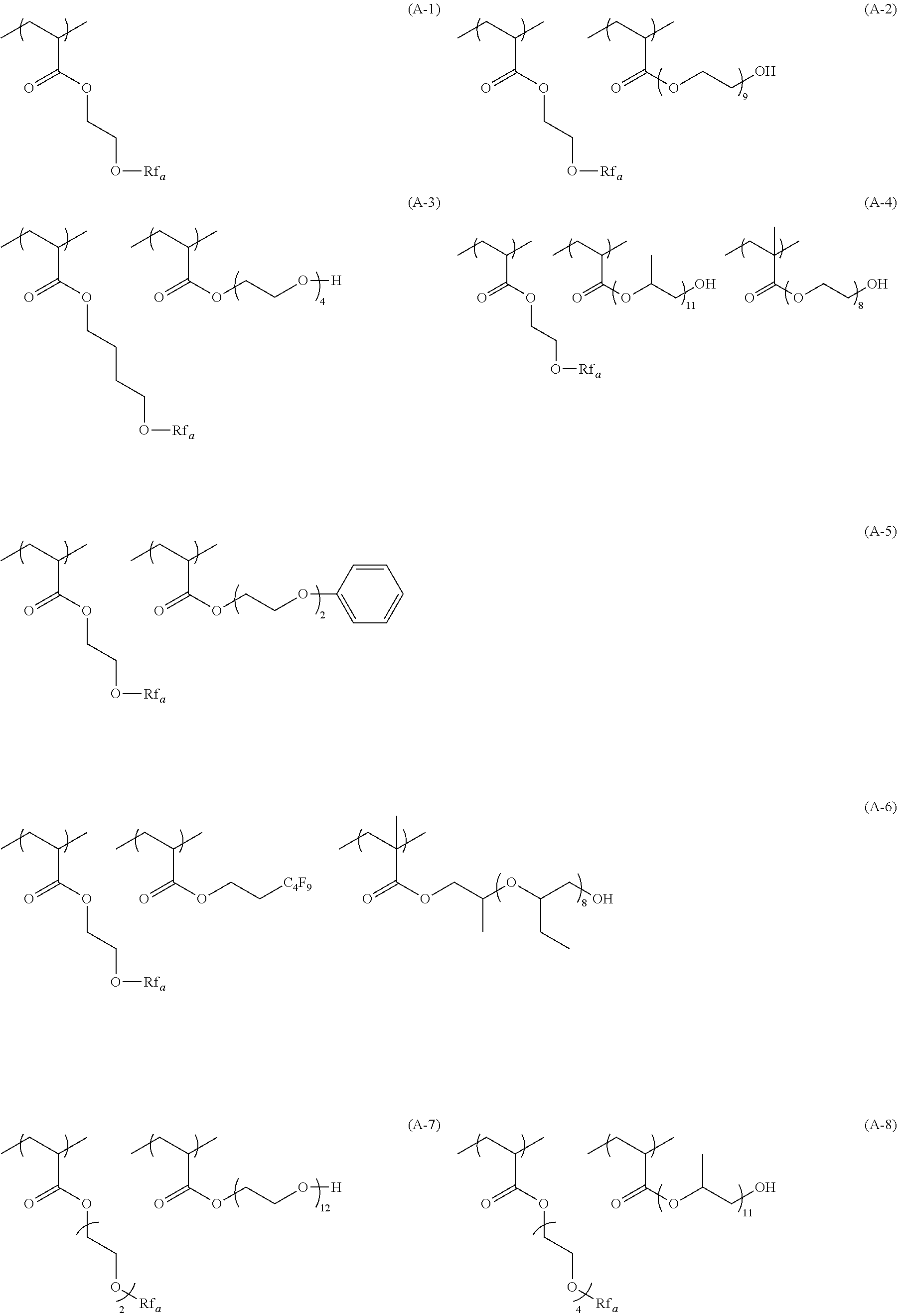

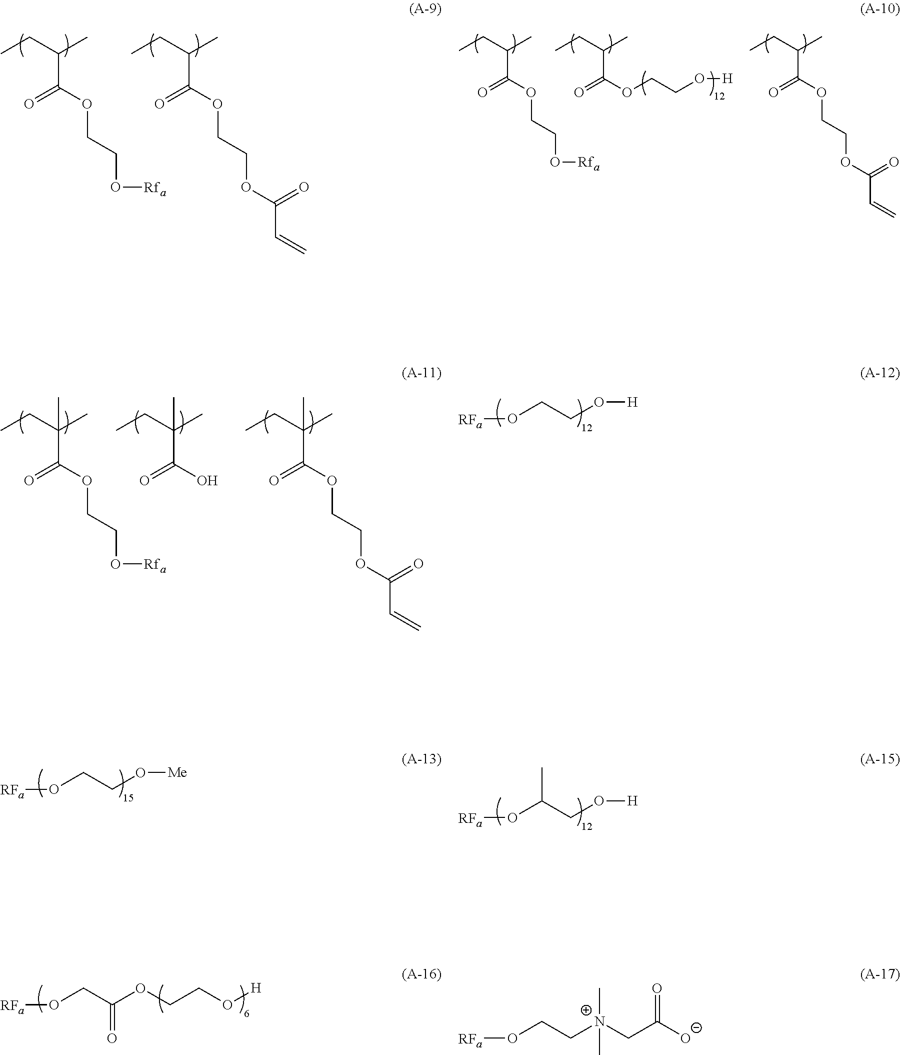

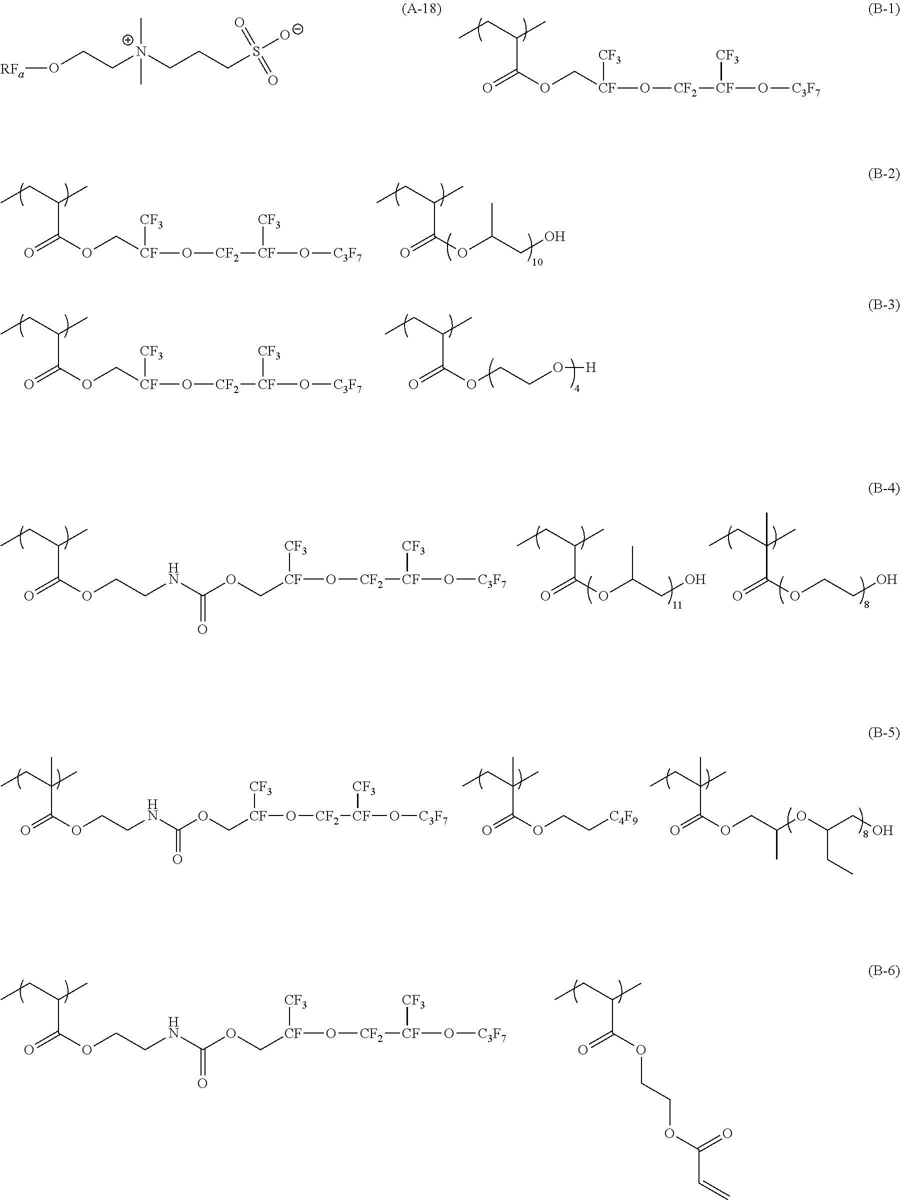

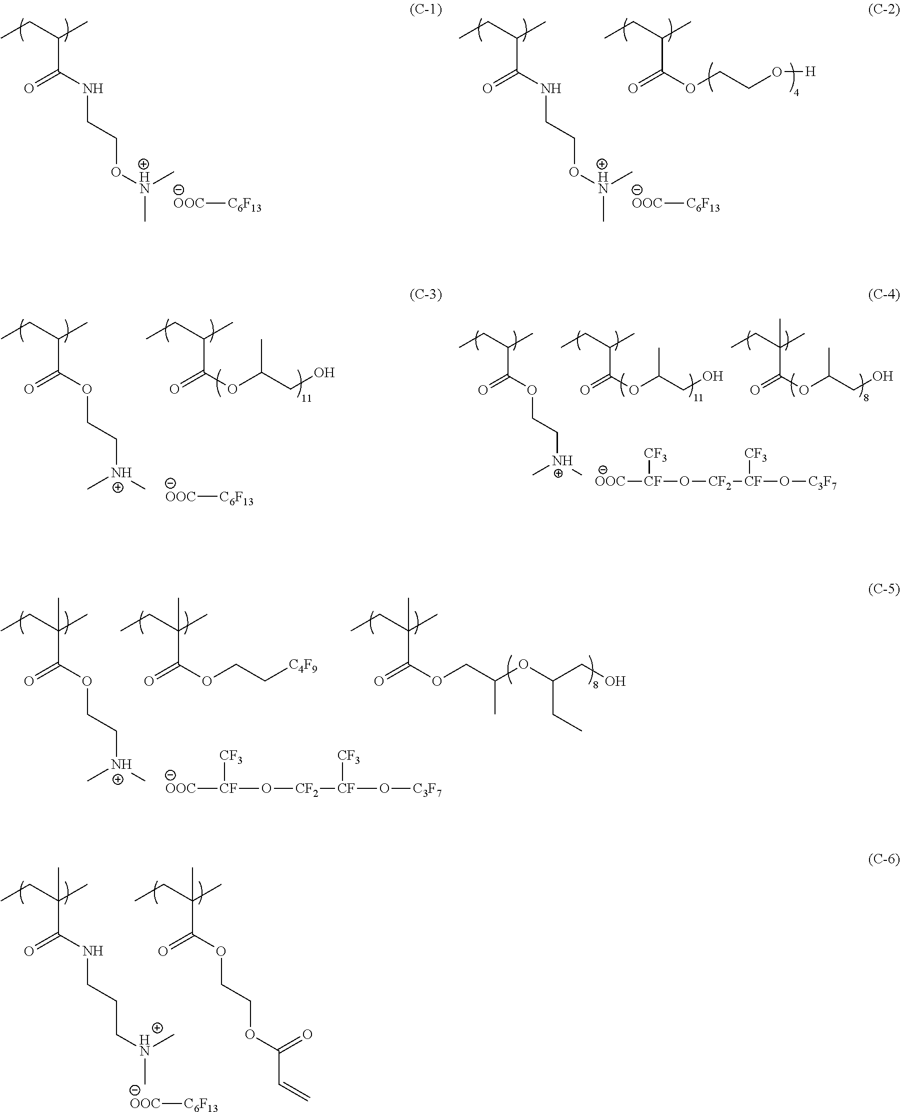

With respect to the total solid content of the composition (a negative type photosensitive resin composition, a chemical amplification type photosensitive resin composition, a thermoplastic resin composition, a water-soluble resin composition, a composition containing a specific material, a coloration resin composition, and/or the like, which is described below), the content of the compound A is preferably 0.001% to 10% by mass, more preferably 0.01% to 3% by mass, and still more preferably 0.02% to 1% by mass.

In the present specification, the “solid content” of the composition means a component that forms a composition layer (for example, a negative type photosensitive resin layer) formed of the composition, and in a case where the composition contains a solvent (an organic solvent, water, or the like), the solid content means all components excluding the solvent. In addition, in a case where the components are components that form a composition layer, the components are considered to be the solid content even in a case where they are liquid components.

[Resin]

The composition according to the embodiment of the present invention contains a resin.

The resin is a component different from the high-molecular-weight compound A.

The properties and/or characteristics of the resin are not limited, and the resin can be appropriately selected depending on the use application of the composition.

Details of the resin contained in the composition according to the embodiment of the present invention will be described later according to each form of the composition.

[Aspect of Composition]

The aspect of the composition according to the embodiment of the present invention is not particularly limited.

For example, the composition according to the embodiment of the present invention may be a negative type photosensitive resin composition that is used for forming a negative type photosensitive resin layer, may be a chemical amplification type photosensitive resin composition that is used for forming a chemical amplification type photosensitive resin layer, may be a thermoplastic resin composition that is used for forming a thermoplastic resin layer, may be a water-soluble resin composition that is used for forming a water-soluble resin layer such as an interlayer, may be a composition containing a specific material that is used for forming a refractive index adjusting layer, or may be a coloration resin composition that is used for forming a coloration resin layer.

Hereinafter, a component that can be contained in each composition in each aspect will be described.

It is noted that a component described as a component of a composition of a certain aspect is not intended to be contained only in a case where the composition is the aspect and it can be used as a component of a composition of another aspect. For example, a component described below as a component of the negative type photosensitive resin layer composition may be used as a component of a composition other than the negative type photosensitive resin composition.

[Negative Type Photosensitive Resin Composition]

In a display device (an organic electroluminescence (EL) display device, a liquid crystal display device, or the like) that includes a touch panel such as a capacitive input device, an electrode pattern corresponding to a sensor of a visual recognition part and a conductive layer pattern of a wire or the like of a peripheral wiring portion or a lead-out wiring portion are provided inside the touch panel.

Generally, a method of providing a layer (a photosensitive layer) of a negative type photosensitive resin composition on a substrate using a transfer film or the like, subjecting the photosensitive layer to exposure through a mask having a desired pattern, and then carrying out development is widely employed for forming a patterned layer.

Here, first, in a case where the composition is a negative type photosensitive resin composition, a component that can be contained as a component other than the compound A will be described.

In a case where the composition is a negative type photosensitive resin composition, the negative type photosensitive resin composition preferably contains a polymerizable compound and a polymerization initiator in addition to the compound A and the resin. In addition, in a case where the composition is a negative type photosensitive resin composition, it is also preferable that an alkali-soluble resin (a polymer A or the like which is an alkali-soluble resin) is contained as a part or the whole of the resin, as will described below.

That is, in one aspect, it is also preferable that the composition according to the embodiment of the present invention contains a polymerizable compound and a polymerization initiator, and the resin is an alkali-soluble resin.

Such a composition (a negative type photosensitive resin composition or the like) preferably contains, in terms of the total solid content mass of the composition; a resin of 10% to 90% by mass, a polymerizable compound of 5% to 70% by mass, and a photopolymerization initiator of 0.01% to 20% by mass. Hereinafter, each component will be described in order.

<Polymer a (Resin)>

In a case where the composition is a negative type photosensitive resin composition, the resin contained in the composition is particularly referred to as a polymer A.

The polymer A is preferably an alkali-soluble resin.

The acid value of the polymer A is preferably 220 mgKOH/g or less, more preferably less than 200 mgKOH/g, and still more preferably less than 190 mgKOH/g, from the viewpoint of the more excellent resolution by suppressing the swelling of the negative type photosensitive resin layer due to the developer.

The lower limit of the acid value of the polymer A is not particularly limited; however, it is preferably 60 mgKOH/g or more, more preferably 120 mgKOH/g or more, still more preferably 150 mgKOH/g or more, and particularly preferably 170 mgKOH/g or more, from the viewpoint of the more excellent developability.

It is noted that the acid value is the mass [mg] of potassium hydroxide required to neutralize 1 g of the sample, and the unit thereof is described as mgKOH/g in the present specification. The acid value can be calculated, for example, from the average content of acid groups in the compound.

The acid value of the polymer A may be adjusted according to the kind of the constitutional unit that constitutes the polymer A and the content of the constitutional unit including an acid group.

The weight-average molecular weight of the polymer A is preferably 5,000 to 500,000. A case where the weight-average molecular weight is 500,000 or less is preferable from the viewpoint of improving resolution and developability. The weight-average molecular weight is more preferably 100,000 or less and still more preferably 60,000 or less. On the other hand, a case where the weight-average molecular weight is 5,000 or more is preferable from the viewpoint of controlling property of the developed aggregate and the property of the unexposed film such as edge fuse property and cut chip property in a case of forming a negative type photosensitive resin laminate. The lower limit of the weight-average molecular weight is more preferably 10,000 or more, still more preferably 20,000 or more, and particularly preferably 30,000 or more. The edge fuse property refers to a degree of ease with which the negative type photosensitive resin layer (that is, a layer consisting of the negative type photosensitive resin composition) protrudes from the edge surface of the roll in a case of being wound backward in a roll shape as a negative type photosensitive resin laminate. The cut chip property refers to a degree of ease of chip flying in a case where the unexposed film is cut with a cutter. In a case where this chip adheres to the upper surface of the negative type photosensitive resin laminate or the like, it is transferred to the mask in the later exposure step or the like, which causes a defective product. The dispersivity of the polymer A is preferably 1.0 to 6.0, more preferably 1.0 to 5.0, still more preferably 1.0 to 4.0, and particularly preferably 1.0 to 3.0.

In the negative type photosensitive resin composition, the polymer A preferably contains a constitutional unit based on a monomer having an aromatic hydrocarbon group from the viewpoint of suppressing line width thickening and deterioration of resolution in a case where the focal position has deviated during exposure. Examples of such an aromatic hydrocarbon group include a substituted or unsubstituted phenyl group and a substituted or unsubstituted aralkyl group. The content of the constitutional unit based on a monomer having an aromatic hydrocarbon group in the polymer A is preferably 20% by mass or more and more preferably 30% by mass or more with respect to the total mass of the polymer A. The upper limit thereof is not particularly limited; however, it is preferably 95% by mass or less and more preferably 85% by mass or less. In a case where a plurality of kinds of the polymer A are contained, the average value of the contents of the constitutional units based on a monomer having an aromatic hydrocarbon group is preferably within the above range.

Examples of the monomer having an aromatic hydrocarbon group include a monomer having an aralkyl group, styrene, and a polymerizable styrene derivative (for example, methyl styrene, vinyl toluene, tert-butoxy styrene, acetoxy styrene, 4-vinylbenzoic acid, a styrene dimer, or a styrene trimer). Among them, a monomer having an aralkyl group or styrene is preferable. In one aspect, in a case where the monomer component having an aromatic hydrocarbon group in the polymer A is styrene, the content of the constitutional unit based on the styrene is preferably 20% to 70% by mass, more preferably 25% to 65% by mass, still more preferably 30% to 60% by mass, and particularly preferably 30% to 55% by mass, with respect to the total mass of the polymer A.

Examples of the aralkyl group include a substituted or unsubstituted phenylalkyl group (excluding a benzyl group) and a substituted or unsubstituted benzyl group, where a substituted or unsubstituted benzyl group is preferable.

Examples of the monomer having a phenylalkyl group include phenylethyl (meth)acrylate.

Examples of the monomer having a benzyl group include (meth)acrylate having a benzyl group, for example, benzyl (meth)acrylate or chlorobenzyl (meth)acrylate; and a vinyl monomer having a benzyl group, for example, vinylbenzyl chloride or vinylbenzyl alcohol. Among them, benzyl (meth)acrylate is preferable. In one aspect, in a case where the monomer component having an aromatic hydrocarbon group in the polymer A is benzyl (meth)acrylate, the content of the constitutional unit based on the benzyl (meth)acrylate is preferably 50% to 95% by mass, more preferably 60% to 90% by mass, still more preferably 70% to 90% by mass, and particularly preferably 75% to 90% by mass, with respect to the total mass of the polymer A.

The polymer A containing a constitutional unit based on a monomer having an aromatic hydrocarbon group is preferably obtained by polymerizing a monomer having an aromatic hydrocarbon group with at least one kind of the first monomer described later and/or at least one kind of the second monomer described later.

The polymer A containing no constitutional unit based on a monomer having an aromatic hydrocarbon group is preferably obtained by polymerizing at least one kind of the first monomers described later, and more preferably obtained by copolymerizing at least one kind of the first monomer and at least one kind of the second monomer described later.

The first monomer is a monomer having a carboxy group in the molecule. Examples of the first monomer include (meth)acrylic acid, fumaric acid, cinnamic acid, crotonic acid, itaconic acid, 4-vinylbenzoic acid, a maleic acid anhydride, and a maleic acid semi-ester. Among these, (meth)acrylic acid is preferable.

The content of the constitutional unit based on the first monomer in the polymer A is preferably 5% to 50% by mass, more preferably 10% to 40% by mass, and still more preferably 15% to 30% by mass, with respect to the total mass of the polymer A.

It is preferable that the content is 5% by mass or more from the viewpoint of exhibiting good developability and the viewpoint of controlling the edge fuse property and the like. It is preferable that the content is 50% by mass or less from the viewpoints of the high resolution of the resist pattern and the viewpoint of the skirt shape, as well as the viewpoint of the chemical resistance of the resist pattern.

The second monomer is a monomer that is non-acidic and has at least one polymerizable unsaturated group in the molecule. Examples of the second monomer include (meth)acrylate such as methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, 2-hydroxyethyl (meth)acrylate, 2-hydroxypropyl (meth)acrylate, cyclohexyl (meth)acrylate, 2-ethylhexyl (meth)acrylate; esters of vinyl alcohols such as vinyl acetate; and (meth)acrylonitriles. Among them, methyl (meth)acrylate, 2-ethylhexyl (meth)acrylate, or n-butyl (meth)acrylate is preferable, and methyl (meth)acrylate is more preferable.

The content of the constitutional unit based on the second monomer in the polymer A is preferably 5% to 60% by mass, more preferably 15% to 50% by mass, and still more preferably 17% to 45% by mass, with respect to the total mass of the polymer A.

A case where the polymer A contains a constitutional unit based on a monomer having an aralkyl group and/or a constitutional unit based on a monomer having styrene is preferable from the viewpoint of suppressing line width thickening and deterioration of resolution in a case where the focal position has deviated during exposure. For example, a copolymer containing a constitutional unit based on methacrylic acid, a constitutional unit based on benzyl methacrylate, and a constitutional unit based on styrene, a copolymer containing a constitutional unit based on methacrylic acid, a constitutional unit based on methyl methacrylate, a constitutional unit based on benzyl methacrylate, and a constitutional unit based on styrene, or the like is preferable.

In one aspect, the polymer A is preferably a polymer which contains 25% to 55% by mass of a constitutional unit based on a monomer having an aromatic hydrocarbon group, 20% to 35% by mass of a constitutional unit based on the first monomer, and 15% to 45% by mass of a constitutional unit based on the second monomer. In addition, in another aspect, it is preferably a polymer which contains 70% to 90% by mass of a constitutional unit based on a monomer having an aromatic hydrocarbon group and 10% to 25% by mass of a constitutional unit based on the first monomer.

The polymer A may have a branched structure and/or an alicyclic structure in the side chain. In a case where a monomer containing a group having a branched structure in the side chain or a monomer containing a group having an alicyclic structure in the side chain is used, it is possible to introduce a branched structure or an alicyclic structure into the side chain of polymer A. The group having an alicyclic structure may be a monocyclic ring or a polycyclic ring.

Specific examples of the monomer containing a group having a branched structure in the side chain include i-propyl (meth)acrylate, i-butyl (meth)acrylate, s-butyl (meth)acrylate, t-butyl (meth)acrylate, i-amyl (meth)acrylate, t-amyl (meth)acrylate, sec-iso-amyl (meth)acrylate, 2-octyl (meth)acrylate, 3-octyl (meth)acrylate, and t-octyl (meth)acrylate. Among these, i-propyl (meth)acrylate, i-butyl (meth)acrylate, or t-butyl methacrylate is preferable, and i-propyl methacrylate or t-butyl methacrylate is more preferable.

Specific examples of the monomer having an alicyclic structure in the side chain include an (meth)acrylate having an alicyclic hydrocarbon group having 5 to 20 carbon atoms. More specific examples thereof include (bicyclo[2.2.1]heptyl-2) (meth)acrylate, 1-adamantyl (meth)acrylate, 2-adamantyl (meth)acrylate, 3-methyl-1-adamantyl (meth)acrylate, 3,5-dimethyl-1-adamantyl (meth)acrylate, 3-ethyladamantyl (meth)acrylate, 3-methyl-5-ethyl-1-adamantyl (meth)acrylate, 3,5,8-triethyl-1-adamantyl (meth)acrylate, 3,5-dimethyl-8-ethyl-1-adamantyl (meth)acrylate, 2-methyl-2-adamantyl (meth)acrylate, 2-ethyl-2-adamantyl (meth)acrylate, 3-hydroxy-1-adamantyl (meth)acrylate, octahydro-4,7-menthanoinden-5-yl (meth)acrylate, octahydro-4,7-menthanoinden-1-ylmethyl (meth)acrylate, 1-menthyl (meth)acrylate, tricyclodecane (meth)acrylate, 3-hydroxy-2,6,6-trimethyl-bicyclo[3.1.1]heptyl (meth)acrylate, 3,7,7-trimethyl-4-hydroxy-bicyclo[4.1.0]heptyl (meth)acrylate, (nor)bornyl (meth)acrylate, isobornyl (meth)acrylate, fenchyl (meth)acrylate, 2,2,5-trimethylcyclohexyl (meth)acrylate, and cyclohexyl (meth)acrylate. Among these (meth)acrylate esters, cyclohexyl (meth)acrylate (nor)bornyl (meth)acrylate, isobornyl (meth)acrylate, 1-adamantyl (meth)acrylate, 2-adamantyl (meth)acrylate, fenchyl (meth)acrylate, 1-menthyl (meth)acrylate, or tricyclodecane (meth)acrylate is preferable, and cyclohexyl (meth)acrylate, (nor)bornyl (meth)acrylate, isobornyl (meth)acrylate, 2-adamantyl (meth)acrylate, or tricyclodecane (meth)acrylate is more preferable.

One kind of the polymer A may be used alone, or two or more kinds thereof may be used.

In a case where two or more kinds are used, it is preferable that two kinds of the polymer A containing a constitutional unit based on a monomer having an aromatic hydrocarbon group are mixed and used, or it is preferable that the polymer A containing a constitutional unit based on a monomer having an aromatic hydrocarbon group and the polymer A containing no constitutional unit based on a monomer having an aromatic hydrocarbon group are mixed and used. In the latter case, the using proportion of the polymer A containing a constitutional unit based on a monomer having an aromatic hydrocarbon group is preferably 50% by mass or more, more preferably 70% by mass or more, still more preferably 80% by mass or more, and particularly preferably 90% by mass or more, with respect to the total amount of the polymer A.

The synthesis of the polymer A is preferably carried out by adding an appropriate amount of a radical polymerization initiator such as benzoyl peroxide or azoisobutyronitrile to a solution obtained by diluting the one or more monomers described above with a solvent such as acetone, methyl ethyl ketone, or isopropanol, and then stirring and heating the resultant mixture. In some cases, the synthesis is carried out while a part of the mixture is added dropwise to the reaction solution. After completion of the reaction, a solvent may be further added to adjust the concentration to a desired level. As the synthesis means, bulk polymerization, suspension polymerization, or emulsion polymerization may be used in addition to the solution polymerization.

The glass transition temperature Tg of the polymer A is preferably 30° C. to 135° C. In a case where the polymer A having a Tg of 135° C. or lower is used, it is possible to suppress line width thickening and deterioration of resolution in a case where the focal position has deviated during exposure. From this viewpoint, the Tg of the polymer A is more preferably 130° C. or lower, still more preferably 120° C. or lower, and particularly preferably 110° C. or lower. Further, it is preferable to use the polymer A having a Tg of 30° C. or higher from the viewpoint of improving the edge fuse resistance. From this viewpoint, the Tg of the polymer A is more preferably 40° C. or higher, still more preferably 50° C. or higher, particularly preferably 60° C. or higher, and most preferably 70° C. or higher.

The negative type photosensitive resin composition may contain a resin other than those described above, as the polymer A.

Examples of the other resin include an acrylic resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

As the polymer A, an alkali-soluble resin described in the description of the thermoplastic resin composition described later may be used.

The content of the polymer A is preferably 10% to 90% by mass, more preferably 20% to 80% by mass, still more preferably 30% to 70% by mass, and particularly preferably 40% to 60% by mass, with respect to the total solid content of the composition. It is preferable that the content of the polymer A is 90% by mass or less from the viewpoint of controlling the development time. On the other hand, it is preferable that the content of the polymer A is 10% by mass or more from the viewpoint of improving the edge fuse resistance.

<Polymerizable Compound>

The negative type photosensitive resin composition preferably contains a polymerizable compound having a polymerizable group.

In the present specification, the “polymerizable compound” means a compound that polymerizes under the action of a polymerization initiator described later, where it means a compound different from the above-described compound A and polymer A.

The polymerizable group contained in the polymerizable compound is not particularly limited as long as it is a group involved in the polymerization reaction, and examples thereof include groups having an ethylenically unsaturated group, such as a vinyl group, an acryloyl group, a methacryloyl group, a styryl group, and a maleimide group; and groups having a cationically polymerizable group, such as an epoxy group and an oxetane group.

The polymerizable group is preferably a group having an ethylenically unsaturated group, and more preferably an acryloyl group or a methacryloyl group.

From the viewpoint that the negative type photosensitive resin layer is more excellent in photosensitivity, the polymerizable compound is preferably a compound having one or more ethylenically unsaturated groups (an ethylenically unsaturated compound) and more preferably a compound having two or more ethylenically unsaturated groups in one molecule (a polyfunctional ethylenically unsaturated compound).

In addition, from the viewpoint of being excellent in resolution and peelability, the number of ethylenically unsaturated groups contained in one molecule of the ethylenically unsaturated compound is preferably 6 or less, more preferably 3 or less, and still more preferably 2 or less.

From the viewpoint that the balance of the photosensitivity, the resolution, and the peelability of the negative type photosensitive resin layer is more excellent a bifunctional or trifunctional ethylenically unsaturated compound having two or three ethylenically unsaturated groups in one molecule is preferably contained, and a bifunctional ethylenically unsaturated compound having two ethylenically unsaturated groups in one molecule is more preferably contained.

From the viewpoint of excellent peelability, the content of the bifunctional ethylenically unsaturated compound with respect to the total mass of the polymerizable compound is preferably 20% by mass or more, more preferably more than 40% by mass, and still more preferably 55% by mass or more, with respect to the total solid content of the composition. The upper limit thereof is not particularly limited and may be 100% by mass. That is, all the polymerizable compounds may be bifunctional ethylenically unsaturated compounds.

In addition, the ethylenically unsaturated compound is preferably an (meth)acrylate compound having an (meth)acryloyl group as the polymerizable group.

(Polymerizable Compound B1)

It is also preferable that the negative type photosensitive resin composition contains a polymerizable compound B1 having an aromatic ring and two ethylenically unsaturated groups. The polymerizable compound B1 is a bifunctional ethylenically unsaturated compound having one or more aromatic rings in one molecule among the above-described polymerizable compounds B.

From the viewpoint of the more excellent resolution, the mass ratio of the content of the polymerizable compound B1 to the total mass of the polymerizable compound in the negative type photosensitive resin composition is preferably 40% by mass or more, more preferably 50% by mass or more, still more preferably 55% by mass or more, and particularly preferably 60% by mass or more. The upper limit thereof is not particularly limited. However, from the viewpoint of peelability, it is, for example, 100% by mass or less, and it is preferably 99% by mass or less, more preferably 95% by mass or less, still more preferably 90% by mass or less, and particularly preferably 85% by mass or less.

Examples of the aromatic ring contained in the polymerizable compound B1 include aromatic hydrocarbon rings such as a benzene ring, a naphthalene ring, and an anthracene ring, aromatic heterocyclic rings such as a thiophene ring, a furan ring, a pyrrole ring, an imidazole ring, a triazole ring, and a pyridine ring, and fused rings thereof, where an aromatic hydrocarbon ring is preferable, and a benzene ring is more preferable. It is noted that the aromatic ring may have a substituent.

The polymerizable compound B1 may have only one aromatic ring or may have two or more aromatic rings.

The polymerizable compound B1 preferably has a bisphenol structure from the viewpoint of improving the resolution by suppressing the swelling of the photosensitive resin layer due to the developer.

Examples of the bisphenol structure include a bisphenol A structure derived from bisphenol A (2,2-bis(4-hydroxyphenyl)propane) a bisphenol F structure derived from bisphenol F (2,2-bis(4-hydroxyphenyl)methane), and a bisphenol B structure derived from bisphenol B (2,2-bis(4-hydroxyphenyl)butane), where a bisphenol A structure is preferable.

Examples of the polymerizable compound B1 having a bisphenol structure include a compound having a bisphenol structure and two polymerizable groups (preferably (meth)acryloyl groups) bonded to both ends of the bisphenol structure.

Both ends of the bisphenol structure and the two polymerizable groups may be directly bonded or may be bonded through one or more alkyleneoxy groups. The alkyleneoxy group to be added to both ends of the bisphenol structure is preferably an ethyleneoxy group or a propyleneoxy group and more preferably an ethyleneoxy group. The number of alkyleneoxy groups to be added to the bisphenol structure is not particularly limited; however, it is preferably 4 to 16 and more preferably 6 to 14 per molecule.

The polymerizable compound B1 having a bisphenol structure is described in paragraphs 0072 to 0080 of JP2016-224162A, and the content described in this publication is incorporated in the present specification.

The polymerizable compound B1 is preferably a bifunctional ethylenically unsaturated compound having a bisphenol A structure, and it is more preferably 2,2-bis(4-((meth)acryloxypolyalkoxy)phenyl)propane.

Examples of the 2,2-bis(4-((meth)acryloxypolyalkoxy)phenyl)propane include 2,2-bis(4-(methacryloxydiethoxy)phenyl)propane (FA-324M, manufactured by Showa Denko Materials Co., Ltd.), 2,2-bis(4-(methacryloxyethoxypropoxy)phenyl)propane, 2,2-bis(4-(methacryloxypentaethoxy)phenyl)propane (BPE-500, manufactured by SHIN-NAKAMURA CHEMICAL Co., Ltd.), 2,2-bis(4-(methacryloxydodecaethoxytetrapropoxy)phenyl)propane (FA-3200MY, manufactured by Showa Denko Materials Co., Ltd.), 2,2-bis(4-(methacryloxypentadecaethoxy)phenyl)propane (BPE-1300, manufactured by SHIN-NAKAMURA CHEMICAL Co., Ltd.), 2,2-bis(4-(methacryloxydiethoxy)phenyl)propane (BPE-200, manufactured by SHIN-NAKAMURA CHEMICAL Co., Ltd.), and ethoxylated (10) bisphenol A diacrylate (NK Ester A-BPE-10, manufactured by SHIN-NAKAMURA CHEMICAL Co., Ltd.).

The polymerizable compound B1 is preferably a compound represented by General Formula (B1).

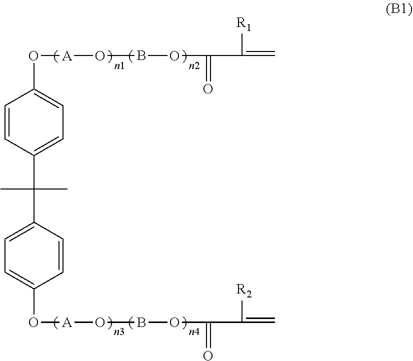

In General Formula B1, R_{1,} and R₂ each independently represent a hydrogen atom or a methyl group. A represents C₂H₄. B represents C₃H₆. n1 and n3 are each independently an integer of 1 to 39, and n1+n3 is an integer of 2 to 40. n2 and n4 are each independently an integer of 0 to 29, and n2+n4 is an integer of 0 to 30. The sequences of constitutional units of -(A-O)— and —(B—O)— may be a random type or a block type. Here, in a case of a block type, any one of -(A-O)— or —(B—O)— may be on the bisphenyl group side.

In one aspect, n1+n2+n3+n4 is preferably 2 to 20, more preferably 2 to 16, and still more preferably 4 to 12. In addition, n2+n4 is preferably 0 to 10, more preferably 0 to 4, still more preferably 0 to 2, and particularly preferably 0.

One kind of the polymerizable compound B1 may be used alone, or two or more kinds thereof may be used.

From the viewpoint of the more excellent resolution, the content of the polymerizable compound B1 is preferably 10% by mass or more and more preferably 20% by mass or more with respect to the total solid content of the composition. The upper limit is not particularly limited; however, it is preferably 70% by mass or less and more preferably 60% by mass or less from the viewpoint of transferability and edge fusion (a phenomenon in which a photosensitive resin exudes from an end portion of a transfer member).

The negative type photosensitive resin composition may contain a polymerizable compound other than the above-described polymerizable compound B1.

The polymerizable compound other than the polymerizable compound B1 is not particularly limited and can be appropriately selected from known compounds. Examples thereof include a compound having one ethylenically unsaturated group in one molecule (a monofunctional ethylenically unsaturated compound), a bifunctional ethylenically unsaturated compound having no aromatic ring, and a trifunctional or higher functional ethylenically unsaturated compound.

Examples of the monofunctional ethylenically unsaturated compound include ethyl (meth)acrylate, ethylhexyl (meth)acrylate, 2-(meth)acryloyloxyethyl succinate, polyethylene glycol mono(meth)acrylate, polypropylene glycol mono(meth)acrylate, and phenoxyethyl (meth)acrylate.

Examples of the bifunctional ethylenically unsaturated compound having no aromatic ring include alkylene glycol di(meth)acrylate, polyalkylene glycol di(meth)acrylate, urethane di(meth)acrylate, and trimethylolpropane diacrylate.

Examples of the alkylene glycol di(meth)acrylate include tricyclodecanedimethanol diacrylate (A-DCP, manufactured by SHIN-NAKAMURA CHEMICAL Co., Ltd.), tricyclodecanedimethanol dimethacrylate (DCP, manufactured by SHIN-NAKAMURA CHEMICAL Co., Ltd.), 1,9-nonandiol diacrylate (A-NOD-N, manufactured by SHIN-NAKAMURA CHEMICAL Co., Ltd.), 1,6-hexanediol diacrylate (A-HD-N, manufactured by SHIN-NAKAMURA CHEMICAL Co., Ltd.), ethylene glycol dimethacrylate, 1,10-decanediol diacrylate, and neopentyl glycol di(meth)acrylate.

Examples of the polyalkylene glycol di(meth)acrylate include polyethylene glycol di(meth)acrylate, dipropylene glycol diacrylate, tripropylene glycol diacrylate, and polypropylene glycol di(meth)acrylate.

Examples of the urethane di(meth)acrylate include propylene oxide-modified urethane di(meth)acrylate, as well as ethylene oxide- and propylene oxide-modified urethane di(meth)acrylates. Examples of the commercially available product include 8UX-015A (manufactured by Taisei Fine Chemical Co., Ltd.), UA-32P (manufactured by SHIN-NAKAMURA CHEMICAL Co., Ltd.), and UA-1100H (manufactured by SHIN-NAKAMURA CHEMICAL Co., Ltd.).

Examples of the trifunctional or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, trimethylolethane tri(meth)acrylate, isocyanuric acid tri(meth)acrylate, glycerin tri(meth)acrylate, and an alkylene oxide-modified product thereof.

Here, “(tri/tetra/penta/hexa)(meth)acrylate” has a concept including tri(meth)acrylate, tetra(meth)acrylate, penta(meth)acrylate, and hexa(meth)acrylate, and “(tri/tetra)(meth)acrylate” has a concept that includes tri(meth)acrylate and tetra(meth)acrylate. In one aspect, the negative type photosensitive resin composition also preferably contains the above-described polymerizable compound B1 and the above-described trifunctional or higher functional ethylenically unsaturated compound, and it more preferably contains the above-described polymerizable compound B1 and two or more kinds of trifunctional or higher functional ethylenically unsaturated compounds. In this case, the mass ratio of the polymerizable compound B1 to the trifunctional or higher functional ethylenically unsaturated compound ((the total mass of the polymerizable compound B1):(the total mass of the trifunctional or higher functional ethylenically unsaturated compound)) is preferably 1:1 to 5:1, more preferably 1.2:1 to 4:1, and still more preferably 1.5:1 to 3:1.

Further, in one aspect, the negative type photosensitive resin composition preferably contains the above-described polymerizable compound B1 and two or more kinds of trifunctional ethylenically unsaturated compounds.

Examples of the alkylene oxide-modified product of the trifunctional or higher functional ethylenically unsaturated compound include a caprolactone-modified (meth)acrylate compound (KAYARAD (registered trade name) DPCA-20 manufactured by Nippon Kayaku Co., Ltd., A-9300-1CL manufactured by SHIN-NAKAMURA CHEMICAL Co., Ltd., or the like), an alkylene oxide-modified (meth)acrylate compound (KAYARAD RP-1040 manufactured by Nippon Kayaku Co., Ltd., ATM-35E or A-9300 manufactured by SHIN-NAKAMURA CHEMICAL Co., Ltd., EBECRYL (registered trade name) 135 manufactured by DAICEL-ALLNEX Ltd., or the like), ethoxylated glycerin triacrylate (A-GLY-9E manufactured by SHIN-NAKAMURA CHEMICAL Co., Ltd. or the like), ARONIX (registered trade name) TO-2349 (manufactured by Toagosei Co., Ltd.), ARONIX M-520 (manufactured by Toagosei Co., Ltd.), and ARONIX M-510 (manufactured by Toagosei Co., Ltd.).

Further, as the polymerizable compound, a polymerizable compound having an acid group (a carboxy group or the like) may be used. The acid group may form an acid anhydride group. Examples of the polymerizable compound having an acid group include ARONIX (registered trade name) TO-2349 (manufactured by Toagosei Co., Ltd.), ARONIX (registered trade name) M-520 (manufactured by Toagosei Co., Ltd.), and ARONIX (registered trade name) M-510 (manufactured by Toagosei Co., Ltd.).

As the polymerizable compound having an acid group, for example, the polymerizable compound having an acid group described in paragraphs 0025 to 0030 of JP2004-239942A may be used.

One kind of polymerizable compound may be used alone, or two or more kinds thereof may be used.

The content of the polymerizable compound is preferably 10% to 70% by mass, more preferably 15% to 70% by mass, still more preferably 20% to 60% by mass, and particularly preferably 20% to 50% by mass, with respect to the total solid content of the composition.

The molecular weight (the weight-average molecular weight in a case of having a molecular weight distribution) of the polymerizable compound (including the polymerizable compound B1) is preferably 200 to 3,000, more preferably 280 to 2,200, and still more preferably 300 to 2,200.

<Polymerization Initiator>

It is also preferable that the negative type photosensitive resin composition contains a polymerization initiator.

The polymerization initiator is selected according to the type of the polymerization reaction, and examples thereof include a thermal polymerization initiator and a photopolymerization initiator.

The polymerization initiator may be a radical polymerization initiator or a cationic polymerization initiator.

The negative type photosensitive resin composition preferably contains a photopolymerization initiator.

The photopolymerization initiator is a compound that initiates the polymerization of a polymerizable compound by receiving an actinic ray such as an ultraviolet ray, visible light, or an X-ray. The photopolymerization initiator is not particularly limited, and a known photopolymerization initiator can be used.

Examples of the photopolymerization initiator include a photoradical polymerization initiator and a photocationic polymerization initiator, where a photoradical polymerization initiator is preferable.

Examples of the photoradical polymerization initiator include a photopolymerization initiator having an oxime ester structure, a photopolymerization initiator having an α-aminoalkyl phenone structure, a photopolymerization initiator having an α-hydroxyalkyl phenone structure, a photopolymerization initiator having an acylphosphine oxide structure, and a photopolymerization initiator having an N-phenyl glycine structure.

Further, from the viewpoints of the photosensitivity, the visibility of the exposed portion and the non-exposed portion, and the resolution, the photosensitive resin layer preferably contains at least one selected from the group consisting of 2,4,5-triarylimidazole dimer and a derivative thereof, as a photoradical polymerization initiator. The two 2,4,5-triarylimidazole structures in the 2,4,5-triarylimidazole dimer and the derivative thereof may be the same or different from each other.

Examples of the derivative of the 2,4,5-triarylimidazole dimer include a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, a 2-(o-methoxyphenyl)-4,5-diphenylimidazole dimer, and a 2-(p-methoxyphenyl)-4,5-diphenylimidazole dimer.

Examples of the photoradical polymerization initiator which may be used include polymerization initiators described in paragraphs 0031 to 0042 of JP2011-95716A and paragraphs 0064 to 0081 of JP2015-14783A.

Examples of the photoradical polymerization initiator include ethyl dimethylaminobenzoate (DBE, CAS No. 10287-53-3), benzoin methyl ether, anisyl (p,p′-dimethoxybenzyl), TAZ-110 (product name: Midori Kagaku Co., Ltd.), benzophenone, 4,4′-bis(diethylamino)benzophenone, TAZ-111 (product name: Midori Kagaku Co., Ltd.), Irgacure OXE01, OXE02, OXE03, OXE04 (BASF SE), Omnirad 651 and 369 (product name: IGM Resins B.V.), and 2,2′-bis(2-chlorophenyl)-4,4′,5,5′-tetraphenyl-1,2′-biimidazole (manufactured by Tokyo Chemical Industry Co., Ltd.).

Examples of the commercially available product of the photoradical polymerization initiator include 1-[4-(phenylthio)]-1,2-octanedione-2-(O-benzoyloxime) (product name: IRGACURE (registered trade name)), OXE-01 (manufactured by BASF SE), 1-[9-ethyl-6-(2-methylbenzoyl)-9H-carbazole-3-yl]ethanone-1-(O-acetyloxime) (product name: IRGACURE OXE-02, manufactured by BASF SE), IRGACURE OXE-03 (manufactured by BASF SE), IRGACURE OXE-04 (manufactured by BASF SE), 2-(dimethylamino)-2-[(4-methylphenyl)methyl]-1-[4-(4-morpholinyl)phenyl]-1-butanone (product name: Omnirad 379EG, IGM Resins B.V.), 2-methyl-1-(4-methylthiophenyl)-2-morpholinopropane-1-one (product name: Omnirad 907, IGM Resins B.V.), 2-hydroxy-1-{4-[4-(2-hydroxy-2-methylpropionyl)benzyl]phenyl}-2-methylpropane-1-one (product name: Omnirad 127, IGM Resins B.V.), 2-benzyl-2-dimethylamino-1-(4-morpholinophenyl)butanone-1 (product name: Omnirad 369, manufactured by IGM Resins B.V.), 2-hydroxy-2-methyl-1-phenylpropane-1-one (product name: Omnirad 1173, manufactured by IGM Resins B.V.), 1-hydroxycyclohexylphenylketone (product name: Omnirad 184, manufactured by IGM Resins B.V.), 2,2-dimethoxy-1,2-diphenylethane-1-one (product name: Omnirad 651, manufactured by IGM Resins B.V.), 2,4,6-trimethylbenzoyl-diphenylphosphinoxide (product name: Omnirad TPO H, IGM Resins B.V.), bis(2,4,6-trimethylbenzoyl)phenylphosphine oxide (product name: Omnirad 819, IGM Resins B.V.), an oxime ester-based photopolymerization initiator (product name: Lunar 6, DKSH Management Ltd.), 2,2′-bis(2-chlorophenyl)-4,4′,5,5′-tetraphenylbisimidazole (a 2-(2-chlorophenyl)-4,5-diphenylimidazole dimer (product name: B-CIM, manufactured by Hampford Research Inc.), a 2-(o-chlorophenyl)-4,5-diphenylimidazole dimer (product name: BCTB, manufactured by Tokyo Chemical Industry Co., Ltd.), 1-[4-(phenylthio)phenyl]-3-cyclopentylpropane-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propane-1,2-di one-2-(O-benzoyloxime) (product name: TR-PBG-391, manufactured by Changzhou Tronly New Electronic Materials Co., Ltd.).

The photocationic polymerization initiator (a photoacid generator) is a compound that generates an acid by receiving an actinic ray. The photocationic polymerization initiator is preferably a compound which becomes sensitive to an actinic ray having a wavelength of 300 nm or more, preferably 300 to 450 nm, and generates an acid; however, the chemical structure thereof is not limited. A photocationic polymerization initiator which does not directly become sensitive to an actinic ray having a wavelength of 300 nm or more can also be preferably used in combination with a sensitizing agent as long as it is a compound which becomes sensitive to an actinic ray having a wavelength of 300 nm or more and then generates an acid by being used in combination with the sensitizing agent.

The photocationic polymerization initiator is preferably a photocationic polymerization initiator that generates an acid having a pKa of 4 or less, more preferably a photocationic polymerization initiator that generates an acid having a pKa of 3 or less, and particularly preferably a photocationic polymerization initiator that generates an acid having a pKa of 2 or less. The lower limit value of pKa is not particularly defined; however, it is, for example, preferably −10.0 or more.

Examples of the photocationic polymerization initiator include an ionic photocationic polymerization initiator and a nonionic photocationic polymerization initiator.

Examples of the ionic photocationic polymerization initiator include onium salt compounds such as diaryliodonium salts and triarylsulfonium salts, and quaternary ammonium salts.

As the ionic photocationic polymerization initiator, the ionic photocationic polymerization initiators described in paragraphs 0114 to 0133 of JP2014-085643A may be used.

Examples of the nonionic photocationic polymerization initiator include trichloromethyl-s-triazines, diazomethane compounds, imide sulfonate compounds, and oxime sulfonate compounds. As the trichloromethyl-s-triazines, the diazomethane compounds, and the imide sulfonate compounds, the compounds described in paragraphs 0083 to 0088 of JP2011-221494A may be used. Further, as the oxime sulfonate compound, the compounds described in paragraphs 0084 to 0088 of WO2018/179640A may be used.

Examples of the photocationic polymerization initiator (the photoacid generator) include a photoacid generator described in the description of the chemical amplification type photosensitive resin composition described later and a photoacid generator described in the description of the thermoplastic resin composition described later.

The negative type photosensitive resin composition preferably contains a photoradical polymerization initiator, and it more preferably contains at least one selected from the group consisting of a 2,4,5-triarylimidazole dimer and a derivative thereof.

One kind of polymerization initiator may be used alone, or two or more kinds thereof may be used.

The content of the polymerization initiator (preferably, the photopolymerization initiator) is not particularly limited. However, it is preferably 0.1% by mass or more, more preferably 0.5% by mass or more, and still more preferably 1.0% by mass or more, with respect to the total solid content of the composition. The upper limit thereof is not particularly limited; however, it is preferably 20% by mass or less, more preferably 15% by mass or less, and still more preferably 10% by mass or less, with respect to the total solid content of the composition.

<Coloring Agent>

From the viewpoints of visibility of the exposed portion and the non-exposed portion, the pattern visibility after development, and the resolution, it is also preferable that the negative type photosensitive resin composition contains a coloring agent (also referred to as a “coloring agent N”) that has a maximum absorption wavelength of 450 nm or more in a wavelength range of 400 to 780 nm at the time of color development, where the maximum absorption wavelength is changed by an acid, a base, or a radical. In a case where the coloring agent N is contained, the adhesiveness to an adjacent layer (for example, the temporary support and the interlayer) is improved, and thus the resolution is more excellent although the detailed mechanism is unknown.

In the present specification, the description that “the maximal absorption wavelength of the coloring agent is changed by an acid, a base, or a radical” may mean any one of an aspect in which a coloring agent in a colored state is decolorized by an acid, a base, or a radical, an aspect in which a coloring agent in a decolorized state develops a color by an acid, a base, or a radical, or an aspect in which a colored state of a coloring agent changes to a colored state of another color tone.

Specifically, the coloring agent N may be a compound that changes from the decolorized state to develop a color upon exposure or may be a compound that changes from the colored state to be decolorized upon exposure. In this case, it may be a coloring agent of which the color developing state or decolorized state changes by an action of an acid, a base, or a radical, which is generated upon exposure in the photosensitive resin layer, or it may be a coloring agent of which the color developing state or decolorized state changes due to a change in the state (for example, pH) of the inside of the photosensitive resin layer, the change being caused by an acid, a base, or a radical. Further, it may be a coloring agent of which the color developing state or decolorized state changes by directly receiving an acid, a base, or a radical as a stimulus without undergoing exposure.

Among the above, the coloring agent N is preferably a coloring agent of which the maximum absorption wavelength is changed by an acid or a radical, and more preferably a coloring agent of which the maximum absorption wavelength is changed by a radical, from the viewpoints of the visibility of the exposed portion and the non-exposed portion and the resolution.

From the viewpoints of the visibility of the exposed portion and the non-exposed portion and the resolution, the negative type photosensitive resin composition preferably contains both a coloring agent of which the maximum absorption wavelength is changed by a radical as the coloring agent N and a photoradical polymerization initiator.

Further, from the viewpoint of the visibility of the exposed portion and the non-exposed portion, the coloring agent N is preferably a coloring agent that develops color by an acid, a base, or a radical.

Examples of the color development mechanism of the coloring agent N include an aspect in which a photoradical polymerization initiator, a photocationic polymerization initiator (a photoacid generator), or a photobase generator is added to the photosensitive resin layer so that a radical-reactive coloring agent, an acid-reactive coloring agent, or a base-reactive coloring agent (for example, a leuco coloring agent) develops a color by a radical, an acid, or a base, which is generated after exposure from the photoradical polymerization initiator, the photocationic polymerization initiator, or the photobase generator.

From the viewpoint of the visibility of the exposed portion and the non-exposed portion, the coloring agent N preferably has a maximal absorption wavelength of 550 nm or more, more preferably 550 to 700 nm, and still more preferably 550 to 650 nm, in a wavelength range of 400 to 780 nm at the time of color development.

In addition, the coloring agent N may have only one maximal absorption wavelength in a wavelength range of 400 to 780 nm at the time of color development or may have two or more coloring agents N. In a case where the coloring agent N has two or more maximal absorption wavelengths in a wavelength range of 400 to 780 nm at the time of color development, it suffices that the maximal absorption wavelength having the highest absorbance among the two or more maximal absorption wavelengths may be 450 nm or more.

The maximal absorption wavelength of the coloring agent N is obtained by measuring a transmission spectrum of a solution (solution temperature: 25° C.) containing the coloring agent N in a range of 400 to 780 nm using a spectrophotometer: UV3100 (manufactured by Shimadzu Corporation) in atmospheric air and detecting a wavelength (a maximal absorption wavelength) at which the intensity of light is minimal.

Examples of the coloring agent that develops a color or is decolorized under exposure include a leuco compound.

Examples of the coloring agent that is decolorized under exposure include a leuco compound, a diarylmethane-based coloring agent, an oxazine-based coloring agent, a xanthene-based coloring agent, an iminonaphthoquinone-based coloring agent, an azomethine-based coloring agent, and an anthraquinone-based coloring agent.

From the viewpoint of the visibility of the exposed portion and the non-exposed portion, the coloring agent N is preferably a leuco compound.

Examples of the leuco compound include a leuco compound having a triarylmethane skeleton (a triarylmethane-based coloring agent), a leuco compound having a spiropyran skeleton (a spiropyran-based coloring agent), a leuco compound having a fluoran skeleton (a fluoran-based coloring agent), a leuco compound having a diarylmethane skeleton (a diarylmethane-based coloring agent), a leuco compound having a rhodamine lactam skeleton (a rhodamine lactam-based coloring agent), a leuco compound having an indolyl phthalide skeleton (an indolyl phthalide-based coloring agent), and a leuco compound having a leuco auramine skeleton (a leuco auramine-based coloring agent).

Among them, a triarylmethane-based coloring agent or a fluoran-based coloring agent is preferable, and a leuco compound having a triphenylmethane skeleton (a triphenylmethane-based coloring agent) or a fluoran-based coloring agent is more preferable.

From the viewpoint of the visibility of the exposed portion and the non-exposed portion, the leuco compound preferably has a lactone ring, a sultine ring, or a sultone ring. As a result, the lactone ring, the sultine ring, or the sultone ring contained in the leuco compound is reacted with a radical generated from the photoradical polymerization initiator or an acid generated from the photocationic polymerization initiator to change the leuco compound into a closed ring state, thereby being decolorized, or change the leuco compound to an open ring state, whereby a color is developed. It is preferable that the leuco compound is a compound having a lactone ring, a sultine ring, or a sultone ring, where the lactone ring, the sultine ring, or the sultone ring is opened by a radical or an acid to develop a color, and it is more preferable that it is a compound having a lactone ring, where the lactone ring is opened by a radical or an acid to develop a color.

Examples of the coloring agent N include the following dyes and leuco compounds.

Among the coloring agents N, specific examples of the dye include Brilliant green, Ethyl violet, Methyl green, Crystal violet, Basic fuchsine, Methyl violet 2B, Quinaldine red, Rose bengal, Metanil yellow, thymol sulfonphthalein, Xylenol blue, Methyl orange, Paramethyl red, Congo red, Benzopurpurine 4B, α-Naphthyl red, Nile blue 2B, Nile blue A, Methyl violet, Malachite green, Parafuchsine, Victoria pure blue-naphthalene sulfonate, Victoria pure blue BOH (manufactured by HODOGAYA CHEMICAL CO., LTD.), Oil blue #603 (manufactured by ORIENT CHEMICAL INDUSTRIES CO., LTD.), Oil pink #312 (manufactured by ORIENT CHEMICAL INDUSTRIES CO., LTD.), Oil red 5B (manufactured by ORIENT CHEMICAL INDUSTRIES CO., LTD.), Oil scarlet #308 (manufactured by ORIENT CHEMICAL INDUSTRIES CO., LTD.), Oil red OG (manufactured by ORIENT CHEMICAL INDUSTRIES CO., LTD.), Oil red RR (manufactured by ORIENT CHEMICAL INDUSTRIES CO., LTD.), Oil green #502 (manufactured by ORIENT CHEMICAL INDUSTRIES CO., LTD.), Spiron red BEH special (manufactured by HODOGAYA CHEMICAL CO., LTD.), m-Cresol purple, Cresol red, rhodamine B, rhodamine 6G, sulforhodamine B, auramine, 4-p-diethylaminophenyliminonaphthoquinone, 2-carboxyanilino-4-p-diethylaminophenyliminonaphthoquinone, 2-carboxystearylamino-4-p-N,N-bis(hydroxyethyl) amino-phenyliminonaphthoquinone, 1-phenyl-3-methyl-4-p-diethylaminophenylimino-5-pyrazolone, and 1-β-naphthyl-4-p-diethylaminophenylimino-5-pyrazolone.

Among the coloring agents N, specific examples of the leuco compound include p,p′,p″-hexamethyltriaminotriphenylmethane (Leucocrystal violet), Pergascript blue SRB (manufactured by Ciba-Geigy AG), Crystal violet lactone, Malachite green lactone, benzoyl leucomethylene blue, 2-(N-phenyl-N-methylamino)-6-(N-p-tolyl-N-ethyl) aminofluoran, 2-anilino-3-methyl-6-(N-ethyl-p)-toluidino) fluoran, 3,6-dimethoxyfluoran, 3-(N,N-diethylamino)-5-methyl-7-(N,N-dibenzylamino) fluoran, 3-(N-cyclohexyl-N-methyl)amino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino) fluoran, 3-(N,N-diethylamino)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindole-3-yl)phthalide, 3,3-bis(1-n-butyl-2-methylindole-3-yl)phthalide, 3,3-bis(p-dimethylaminophenyl)-6-dimethylaminophthalide, 3-(4-diethylamino-2-ethoxyphenyl)-3-(1-ethyl-2-methylindole-3-yl)-4-azaphthalide, 3-(4-diethylaminophenyl)-3-(1-ethyl-2-methylindole-3-yl)phthalide, and 3′,6′-bis(diphenylamino)spiroisobenzofuran-1 (3H),9′-[9H]xanthene-3-one.

From the viewpoints of visibility of the exposed portion and the non-exposed portion, the pattern visibility after development, and the resolution, the coloring agent N is preferably a coloring agent of which the maximum absorption wavelength is changed by a radical, and more preferably a coloring agent that develops a color by a radical.

The coloring agent N is preferably Leucocrystal violet, Crystal violet lactone, Brilliant green, or Victoria pure blue-naphthalene sulfonate.

One kind of the coloring agent N may be used alone, or two or more kinds thereof may be used.

From the viewpoints of visibility of the exposed portion and the non-exposed portion, the pattern visibility after development, and the resolution, the content of the coloring agent N is preferably 0.1% by mass or more, more preferably 0.1% to 10% by mass, still more preferably 0.1% to 5% by mass, and particularly preferably 0.1% to 1% by mass, with respect to the total solid content of the composition.

The content of the coloring agent N means the content of the coloring agent in a case where the whole coloring agent N contained in the total solid content of the composition is in a colored state. Hereinafter, a method of quantifying the content of the coloring agent N will be described by taking a coloring agent that develops color by a radical as an example.

0.001 g and 0.01 g of a coloring agent are each dissolved in 100 mL of methyl ethyl ketone to prepare a solution. A photoradical polymerization initiator Irgacure OXE01 (product name, BASF Japan Ltd.) is added to each of the obtained solutions, and radicals are generated by the irradiation with light of 365 nm to bring the whole coloring agent into a colored state.

Then, in the atmospheric air, the absorbance of each solution having a liquid temperature of 25° C. is measured using a spectrophotometer (UV3100, manufactured by Shimadzu Corporation), and a calibration curve is created.

Next, the absorbance of the solution in which the whole coloring agent has been caused to develop a color is measured by the same method as the above except that 3 g of the solid content of the composition is dissolved in methyl ethyl ketone instead of the coloring agent. From the obtained absorbance of the solution containing the solid content of the composition, the content of the coloring agent contained in the solid content of the composition is calculated based on the calibration curve.

It is noted that 3 g of the solid content of the composition is the same as 3 g of a layer (a negative type photosensitive resin layer or the like) formed of the composition.

<Thermal Crosslinking Compound>

From the viewpoint of the hardness of the cured film to be obtained and the pressure-sensitive adhesiveness of the uncured film to be obtained, the negative type photosensitive resin composition preferably contains a thermal crosslinking compound. In the present disclosure, the thermal crosslinking compound having an ethylenically unsaturated group described later shall be not treated as a polymerizable compound but shall be treated as a thermal crosslinking compound.

Examples of the thermal crosslinking compound include a methylol compound and a blocked isocyanate compound. Among these, from the viewpoint of the hardness of the cured film to be obtained and the pressure-sensitive adhesiveness of the uncured film to be obtained, a blocked isocyanate compound is preferable.

By the way, the blocked isocyanate compound reacts with a hydroxy group and a carboxy group. As a result, for example, in a case where the resin and/or the polymerizable compound has at least one of a hydroxy group or a carboxy group, a film to be formed has a low hydrophilicity, and thus in a case where a film obtained by curing the negative type photosensitive resin layer is used as a protective film, the function thereof tends to be enhanced.

The blocked isocyanate compound refers to a “compound having a structure in which the isocyanate group of isocyanate is protected (so-called masked) by a blocking agent”.

The dissociation temperature of the blocked isocyanate compound is not particularly limited; however, it is preferably 100° C. to 160° C. and more preferably 130° C. to 150° C.

The dissociation temperature of blocked isocyanate means “temperature at an endothermic peak accompanied with a deprotection reaction of blocked isocyanate, in a case where the measurement is carried out by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonate (such as dimethyl malonate, diethyl malonate, di-n-butyl malonate, or di-2-ethylhexyl malonate)] and an oxime compound (a compound having a structure represented by —C(═N—OH)— in the molecule, such as formaldoxime, acetoaldoxime, acetoxime, methyl ethyl ketoxime, or cyclohexanoneoxime).

Among these, the blocking agent having a dissociation temperature of 100° C. to 160° C. is preferably, for example, at least one selected from oxime compounds from the viewpoint of storage stability.

The blocked isocyanate compound preferably has an isocyanurate structure, for example, from the viewpoint of improving the brittleness of the film and improving the adhesion force to a transferred material and the like.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group.

The polymerizable group is not particularly limited, and a known polymerizable group can be used, where a radically polymerizable group is preferable.

Examples of the polymerizable group include an (meth)acryloxy group, an (meth)acrylamide group, an ethylenically unsaturated group such as styryl group, and an epoxy group such as a glycidyl group.

Among them, the polymerizable group is preferably an ethylenically unsaturated group, more preferably an (meth)acryloxy group, and still more preferably an acryloxy group.

A commercially available product can be used as the blocked isocyanate compound.

Examples of the commercially available blocked isocyanate compound include compounds such as Karenz (registered trade name), AOI-BM, Karenz (registered trade name), MOI-BM, Karenz (registered trade name), and MOI-BP (all manufactured by Showa Denko K.K.); and block type DURANATE series (for example, DURANATE (registered trade name)), TPA-B80E, DURANATE (registered trade name), and WT32-B75P, manufactured by Asahi Kasei Chemicals Co., Ltd.).

Further, as the blocked isocyanate compound, a compound having the following structure can also be used.

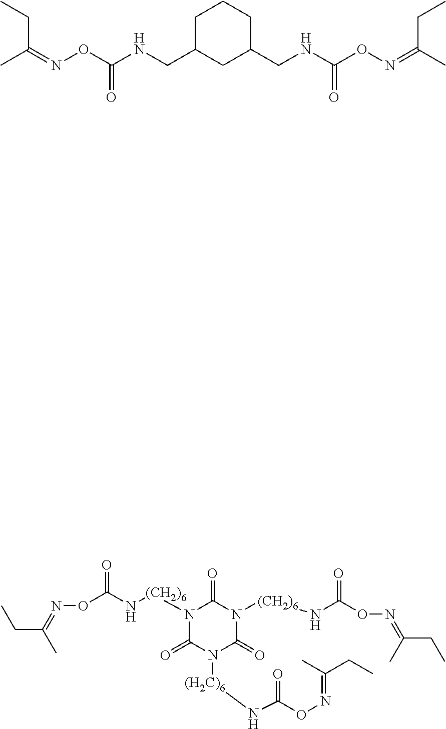

One kind of thermal crosslinking compound may be used alone, or two or more kinds thereof may be used.

In a case where the negative type photosensitive resin composition contains a thermal crosslinking compound, the content of the thermal crosslinking compound is preferably 1% by mass to 50% by mass and more preferably 5% by mass to 30% by mass with respect to the total solid content of the composition.

<Solvent>

It is also preferable that the negative type photosensitive resin composition contains a solvent.

The solvent contained in the negative type photosensitive resin composition is not particularly limited as long as each component (the compound A, the polymer A, and/or the like) other than the solvent can be dissolved or dispersed, and a known solvent can be used.

Examples of the solvent include an alkylene glycol ether solvent, an alkylene glycol ether acetate solvent, an alcohol solvent (methanol, ethanol, or the like), a ketone solvent (acetone, methyl ethyl ketone, or the like), an aromatic hydrocarbon solvent (toluene or the like), an aprotonic polar solvent (N,N-dimethylformamide or the like), a cyclic ether solvent (tetrahydrofuran or the like), an ester solvent (n-propyl acetate or the like), an amide solvent, a lactone solvent, and a mixed solvent containing two or more of these.

In a case of producing a transfer film including a temporary support, a thermoplastic resin layer, an interlayer (a water-soluble resin layer), and a negative type photosensitive resin layer, the negative type photosensitive resin composition preferably contains at least one selected from the group consisting of an alkylene glycol ether solvent and an alkylene glycol ether acetate solvent. Among the above, the solvent is more preferably a mixed solvent containing at least one solvent selected from the group consisting of an alkylene glycol ether solvent and an alkylene glycol ether acetate solvent and at least one solvent selected from the group consisting of a ketone solvent and a cyclic ether solvent, and still more preferably a mixed solvent containing at least three solvents of one solvent selected from the group consisting of an alkylene glycol ether solvent and an alkylene glycol ether acetate solvent, a ketone solvent, and a cyclic ether solvent.

Examples of the alkylene glycol ether solvent include ethylene glycol monoalkyl ether, ethylene glycol dialkyl ether, propylene glycol monoalkyl ether (propylene glycol monomethyl ether acetate or the like), propylene glycol dialkyl ether, diethylene glycol dialkyl ether, dipropylene glycol monoalkyl ether, and dipropylene glycol dialkyl ether.

Examples of the alkylene glycol ether acetate solvent include ethylene glycol monoalkyl ether acetate, propylene glycol monoalkyl ether acetate, diethylene glycol monoalkyl ether acetate, and dipropylene glycol monoalkyl ether acetate.

As the solvent, the solvents described in paragraphs 0092 to 0094 of WO2018/179640A and the solvents described in paragraph 0014 of JP2018-177889A may be used, the contents of which are incorporated in the present specification.

One kind of solvent may be used alone, or two or more kinds thereof may be used.

The content of the solvent is preferably 50 to 1,900 parts by mass, more preferably 100 to 1,200 parts by mass, and still more preferably 100 to 900 parts by mass, with respect to 100 parts by mass of the total solid content of the composition.

<Additive>

The negative type photosensitive resin composition may contain a known additive in addition to the above-described components, as necessary.

Examples of the additive include a radical polymerization inhibitor, a sensitizing agent, a plasticizer, a heterocyclic compound (triazole or the like), benzotriazoles, carboxybenzotriazoles, pyridines (isonicotinamide and the like), a purine base (adenine or the like), and a surfactant.

One kind of each additive may be used alone, or two or more kinds thereof may be used.

The negative type photosensitive resin composition may contain a radical polymerization inhibitor.

Examples of the radical polymerization inhibitor include the thermal polymerization inhibitors described in paragraph 0018 of JP4502784B. Among them, phenothiazine, phenoxazine, or 4-methoxyphenol is preferable. Examples of other radical polymerization inhibitors include naphthylamine, cuprous chloride, a nitrosophenylhydroxyamine aluminum salt, and diphenylnitrosamine. It is preferable to use a nitrosophenylhydroxyamine aluminum salt as a radical polymerization inhibitor so that the sensitivity of the negative type photosensitive resin layer is not impaired.

Examples of the benzotriazoles include 1,2,3-benzotriazole, 1-chloro-1,2,3-benzotriazole, bis(N-2-ethylhexyl)aminomethylene-1,2,3-benzotriazole, bis(N-2-ethylhexyl)aminomethylene-1,2,3-tolyltriazole, and bis(N-2-hydroxyethyl)aminomethylene-1,2,3-benzotriazole.

Examples of the carboxybenzotriazoles include 4-carboxy-1,2,3-benzotriazole, 5-carboxy-1,2,3-benzotriazole, N—(N,N-di-2-ethylhexyl)aminomethylenecarboxybenzotriazole, N—(N,N-di-2-hydroxyethyl)aminomethylenecarboxybenzotriazole, and N—(N,N-di-2-ethylhexyl)aminoethylenecarboxybenzotriazole. As the carboxybenzotriazoles, it is possible to use, for example, a commercially available product such as CBT-1 (product name, JOHOKU CHEMICAL Co., Ltd.).

The total content of the radical polymerization inhibitor, the benzotriazols, and the carboxybenzotriazols is preferably 0.01% to 3% by mass and more preferably 0.05% to 1% by mass in a case where the total solid content mass of the composition is set to 100% by mass. It is preferable to set the above content to 0.01% by mass or more from the viewpoint of imparting storage stability to the composition. On the other hand, it is preferable that the content is 3% by mass or less from the viewpoint of the maintenance of the sensitivity and the suppression of decolorization of the dye.

The negative type photosensitive resin composition may contain a sensitizing agent.

The sensitizing agent is not particularly limited, and a known sensitizing agent, a dye, or a pigment can be used. Examples of the sensitizing agent include a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound (for example, 1,2,4-triazole), a stilbene compound, a triazine compound, a thiophene compound, a naphthalimide compound, a triarylamine compound, and an aminoacridine compound.

One kind of sensitizing agent may be used alone, or two or more kinds thereof may be used.

In a case where the negative type photosensitive resin composition contains a sensitizing agent, the content of the sensitizing agent can be appropriately selected depending on the intended purpose; however, from the viewpoints of improving the sensitivity to the light source and improving the curing rate by balancing the polymerization rate and the chain transfer, it is preferably 0.01% to 5% by mass and more preferably 0.05% to 1% by mass with respect to the total mass of the photosensitive resin layer.

The negative type photosensitive resin composition may contain at least one selected from the group consisting of a plasticizer and a heterocyclic compound.

Examples of the plasticizer and the heterocyclic compound include the compounds described in paragraphs 0097 to 0103 and 0111 to 0118 of WO2018/179640A.

In addition, the negative type photosensitive resin composition may further contain known additives such as metal oxide particles, an antioxidant, a dispersing agent, an acid proliferation agent, a development accelerator, a conductive fiber, an ultraviolet absorbing agent, a thickener, a crosslinking agent, and an organic or inorganic precipitation inhibitor.

The additives contained in the negative type photosensitive resin composition are described in paragraphs 0165 to 0184 of JP2014-085643A, and the content of this publication is incorporated in the present specification.

From the viewpoint of improving reliability and laminating property, the content of water in the negative type photosensitive resin composition is preferably 0.01% to 1.0% by mass and more preferably 0.05% to 0.5% by mass.

<Physical Properties of the Formed Layer and the Like>

The method of applying the negative type photosensitive resin composition is not particularly limited, and the negative type photosensitive resin composition may be applied by a known method. Examples of the coating method include slit coating, spin coating, curtain coating, and inkjet coating.

In addition, the composition layer (the negative type photosensitive resin layer) formed of the negative type photosensitive resin composition may be formed by applying the negative type photosensitive resin composition onto an object to be coated such as a cover film, which will be described later, and carrying out drying.

The layer thickness (the film thickness) of the negative type photosensitive resin layer is generally 0.1 to 300 pm, preferably 0.2 to 100 pm, more preferably 0.5 to 50 pm, still more preferably 0.5 to 15 pm, particularly preferably 0.5 to 10 pm, and most preferably 0.5 to 8 pm. This makes it possible for the developability of the negative type photosensitive resin layer to be improved and makes it possible for the resolution to be improved.

In addition, in one aspect, it is preferably 0.5 to 5 pm, more preferably 0.5 to 4 pm, and still more preferably 0.5 to 3 pm.

In addition, from the viewpoint of excellent adhesiveness, the light transmittance of light having a wavelength of 365 nm in the negative type photosensitive resin layer is preferably 10% or more, more preferably 30% or more, and still more preferably 50% or more. The upper limit thereof is not particularly limited; however, it is preferably 99.9% or less.

(Impurity and the Like)

The negative type photosensitive resin layer formed of the negative type photosensitive resin composition may contain a predetermined amount of impurities.

Specific examples of the impurities include sodium, potassium, magnesium, calcium, iron, manganese, copper, aluminum, titanium, chromium, cobalt, nickel, zinc, tin, halogen, and ions thereof. Among these, a halide ion, a sodium ion, and a potassium ion are easily mixed as impurities, and thus it is preferable to set the content of the impurities to the following content.

The content of impurities in the negative type photosensitive resin layer is preferably 80 ppm or less, more preferably 10 ppm or less, and still more preferably 2 ppm or less in terms of mass. The content of the impurities can be 1 ppb or more or may be 0.1 ppm or more in terms of mass.

Examples of the method of keeping the impurities in the above range include selecting a raw material having a low content of impurities as a raw material for the composition, preventing the impurities from being mixed during the production of the negative type photosensitive resin layer, and washing and removing the impurities. Such a method makes it possible for the amount of impurities to be kept within the above range.

The impurities can be quantified by a known method such as inductively coupled plasma (ICP) emission spectroscopy, atomic absorption spectroscopy, and ion chromatography.

In the negative type photosensitive resin layer, it is preferable that the content of the compound such as benzene, formaldehyde, trichloroethylene, 1,3-butadiene, carbon tetrachloride, chloroform, N,N-dimethylformamide, N,N-dimethylacetamide, or hexane is low. The content of this compound with respect to the total mass of the composition layer is preferably 100 ppm or less, more preferably 20 ppm or less, and still more preferably 4 ppm or less in terms of mass.

The lower limit thereof can be 10 ppb or more or can be 100 ppb or more in terms of mass with respect to the total mass of the negative type photosensitive resin layer. The content of these compounds can be suppressed in the same manner as in the above-described metal as impurities. Further, it can be quantified by a known measuring method.

From the viewpoint of improving reliability and laminating property, the content of water in the negative type photosensitive resin layer is preferably 0.01% to 1.0% by mass and more preferably 0.05% to 0.5% by mass.

[Chemical Amplification Type Photosensitive Resin Composition]

The composition according to the embodiment of the present invention may be a chemical amplification type photosensitive resin composition.

The chemical amplification type photosensitive resin composition may be a chemically amplified positive type photosensitive resin composition or a chemically amplified negative type photosensitive resin composition.

The chemical amplification type photosensitive resin composition contains the compound A and a resin. From the viewpoint of excellent sensitivity, resolution, removability, and the like, the chemical amplification type photosensitive resin composition preferably contains an acid-decomposable resin as a part or the whole of the resin.

The acid-decomposable resin is not limited as long as it is a resin in which a part of the molecular structure can be decomposed under an action of an acid, and examples thereof include a polymer containing a constitutional unit having a group in which an acid group described later is protected by an acid-decomposable group.

Among the above, the chemical amplification type photosensitive resin composition more preferably contains the compound A, a resin containing a constitutional unit having a group in which an acid group is protected by an acid-decomposable group, and a photoacid generator.

That is, in one aspect, it is also preferable that the composition according to the embodiment of the present invention is a resin containing a photoacid generator and having an acid group, where the resin is protected by an acid-decomposable group.

In a case where a photoacid generator such as an onium salt or an oxime sulfonate compound described later is used, an acid that is generated in sensitive response to a radioactive ray (also referred to as an actinic ray) acts as a catalyst in the deprotection reaction in the group in which the acid group in the polymer is protected by an acid-decomposable group. Since the acid generated by the action of one photon quantum contributes to a large number of deprotection reactions, the quantum yield exceeds 1 and becomes a large value, for example, a multiple of 10, and high sensitivity is obtained as a result of so-called chemical amplification. On the other hand, in a case where a quinone diazide compound is used as the photoacid generator that becomes sensitive to the radioactive ray, a carboxy group is generated by a sequential type photochemical reaction; however, the quantum yield thereof is always 1 or less and does not correspond to the chemically amplified type.

The chemical amplification type photosensitive resin layer may contain another polymer in addition to the polymer containing a constitutional unit having a group in which an acid group is protected by an acid-decomposable group. In the following description related to the chemical amplification type photosensitive resin layer, the polymer containing a constitutional unit having a group in which an acid group is protected by an acid-decomposable group and another polymer are collectively referred to as a “polymer component”.

<Polymer Having a Constitutional Unit Having a Group in which Acid Group is Protected by Acid-Decomposable Group: Polymer X (Resin)>

The chemical amplification type photosensitive resin layer preferably contains a polymer (hereinafter, referred to as a “polymer X”) containing a constitutional unit (hereinafter, may be referred to as a “constitutional unit A”) having a group in which an acid group is protected by an acid-decomposable group. The group in which an acid group in the constitutional unit A is protected by an acid-decomposable group is converted into an acid group under the action of an acid generated by exposure. As a result, the solubility of the exposed chemical amplification type photosensitive resin layer in the alkali developer is increased.

The polymer X is preferably an addition polymerization type resin and more preferably a polymer containing a constitutional unit derived from (meth)acrylic acid or an ester thereof. The polymer X may contain a constitutional unit (for example, a constitutional unit derived from styrene, a constitutional unit derived from a vinyl compound, or the like) other than the constitutional unit derived from (meth)acrylic acid or an ester thereof.

(Constitutional Unit Having Group in which Acid Group is Protected by Acid-Decomposable Group: Constitutional Unit A)

The polymer X contains a constitutional unit having a group in which an acid group is protected by an acid-decomposable group.

In the present disclosure, “the group in which an acid group is protected by an acid-decomposable group” refers to a group having a structure in which an acid group is protected by an acid-decomposable group. The group in which an acid group is protected by an acid-decomposable group can be converted into an acid group under an action of an acid.

In the present disclosure, the “acid group” refers to a proton dissociable group having a pKa of 12 or less. As the acid group, a known acid group such as a carboxy group or a phenolic hydroxy group can be applied. The acid group is preferably a carboxy group or a phenolic hydroxy group.

The acid-decomposable group is not limited, and a known acid-decomposable group can be applied. Examples of the acid-decomposable group include an acid-decomposable group that can protect an acid group in a form of acetal (for example, a tetrahydropyranyl group, a tetrahydrofuranyl group, or an ethoxyethyl group), and an acid-decomposable group (for example, a tert-butyl group) that can protect an acid group in a form of an ester.

Examples of the group in which an acid group is protected by an acid-decomposable group include a group that is relatively easily decomposed by an acid (for example, an acetal-based functional group such as an ester group contained in a constitutional unit represented by Formula A3 described later or a tetrahydropyranyl ester group), and a group that is relatively difficult to be decomposed by an acid (for example, a tertiary alkyl ester group such as a tert-butyl ester group or a tertiary alkyl carbonate group such as a tert-butyl carbonate group).

Among the above, the group in which an acid group is protected by an acid-decomposable group is preferably a group having a structure in which a carboxy group or a phenolic hydroxy group is protected in a form of acetal.

From the viewpoint of sensitivity and resolution, the constitutional unit A is preferably at least one constitutional unit selected from the group consisting of a constitutional unit represented by Formula A1, a constitutional unit represented by Formula A2, and a constitutional unit represented by Formula A3, more preferably at least one constitutional unit selected from the group consisting of a constitutional unit represented by Formula A1 and a constitutional unit represented by Formula A3, still more preferably at least one constitutional unit selected from the group consisting of a constitutional unit represented by Formula A1-2 described later and a constitutional unit represented by Formula A3-3 described later. The constitutional unit represented by Formula A1 and the constitutional unit represented by Formula A2 are a constitutional unit having a group in which a phenolic hydroxy group is protected by an acid-decomposable group. The constitutional unit represented by Formula A3 is a constitutional unit having a group in which a carboxy group is protected by an acid-decomposable group.

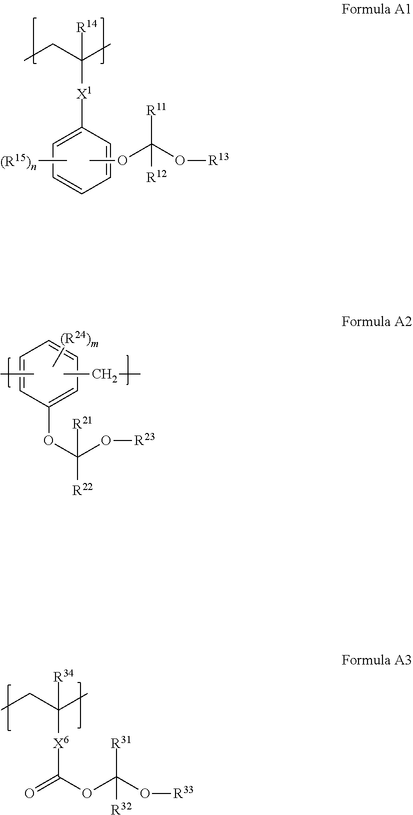

In Formula A1, R¹¹ and R¹² each independently represent a hydrogen atom, an alkyl group, or an aryl group, at least any one of R¹¹ or R¹² is an alkyl group or an aryl group, R¹³ represents an alkyl group or an aryl group, R¹¹ or R¹² may be linked to R¹³ to form a cyclic ether, R¹⁴ represents a hydrogen atom or a methyl group, X¹ represents a single bond or a divalent linking group, R¹⁵ represent a substituent, and n represents an integer of 0 to 4.

In Formula A2, R²¹ and R²² each independently represent a hydrogen atom, an alkyl group, or an aryl group, at least any one of R²¹ or R²² is an alkyl group or an aryl group, R²³ represents an alkyl group or an aryl group, R²¹ or R²² may be linked to R²³ to form a cyclic ether, R²⁴'s each independently represent a hydroxy group, a halogen atom, an alkyl group, an alkoxy group, an alkenyl group, an aryl group, an aralkyl group, an alkoxycarbonyl group, a hydroxyalkyl group, an arylcarbonyl group, an aryloxycarbonyl group, or a cycloalkyl group, and m represents an integer of 0 to 3.

In Formula A3, R³¹ and R³² each independently represent a hydrogen atom, an alkyl group, or an aryl group, at least any one of R³¹ or R³² is an alkyl group or an aryl group, R³³ represents an alkyl group or an aryl group, R³¹ or R³² may be linked to R³³ to form a cyclic ether, R³⁴ represents a hydrogen atom or a methyl group, and X⁰ represents a single bond or a divalent linking group.

One kind of the constitutional unit A contained in the polymer X may be used alone, or two or more kinds thereof may be used.

The content of the constitutional unit A in the polymer X is preferably 15% by mass or more, more preferably 15% to 90% by mass, and still more preferably 15% to 70% by mass, with respect to the total mass of the polymer X.

The content of the constitutional unit A in the polymer X can be checked by the intensity ratio of the peak intensity calculated from the ¹³C-NMR measurement by a conventional method.

(Constitutional Unit Having Acid Group: Constitutional Unit B)

It is also preferable that the polymer X contains a constitutional unit having an acid group (hereinafter, also referred to as a constitutional unit B). In a case where the polymer X contains the constitutional unit B, the sensitivity at the time of formation of a pattern is improved, and the polymer X is easily dissolved in an alkali developer in the development step after the pattern exposure, whereby the development time can be shortened.

The acid group in the constitutional unit B is a proton dissociable group having a pKa of 12 or less. From the viewpoint of improving sensitivity, the upper limit value of the pKa of the acid group is preferably 10 or less and more preferably 6 or less. In addition, the lower limit value of the pKa of the acid group is preferably -5 or more.

Examples of the acid group in the constitutional unit B include a carboxy group, a sulfonamide group, a phosphonic acid group, a sulfonic acid group, a phenolic hydroxy group, and a sulfonylimide group. Among them, the acid group is preferably at least one acid group selected from the group consisting of a carboxy group and a phenolic hydroxy group.

The constitutional unit B can be introduced into the polymer X by a method of copolymerizing a monomer having an acid group or a method of copolymerizing a monomer having an acid anhydride structure and hydrolyzing the acid anhydride. Examples of the monomer having a carboxy group, which is an example of an acid group, include acrylic acid, methacrylic acid, itaconic acid, crotonic acid, maleic acid, fumaric acid, and 4-carboxystyrene. Examples of the monomer having a phenolic hydroxy group, which is an example of the acid group, include p-hydroxystyrene and 4-hydroxyphenylmethacrylate. Examples of the monomer having an acid anhydride structure include maleic acid anhydride.

The constitutional unit B is preferably a constitutional unit derived from a styrene compound having an acid group or a constitutional unit derived from a vinyl compound having an acid group, more preferably a constitutional unit derived from a styrene compound having a phenolic hydroxy group or a constitutional unit derived from a vinyl compound having a carboxy group, still more preferably a constitutional unit derived from a vinyl compound having a carboxy group, and particularly preferably a constitutional unit derived from (meth)acrylic acid.

One kind of the constitutional unit B may be used alone, or two or more kinds thereof may be used.

The content of the constitutional unit B in the polymer X is preferably 0.1% to 20% by mass, more preferably 0.5% to 15% by mass, and particularly preferably 1% to 10% by mass, with respect to the total mass of the polymer X. In a case of adjusting the content of the constitutional unit B in the polymer X within the above-described numerical range, the pattern formation properties are further improved.

The content of the constitutional unit B in the polymer X can be checked by the intensity ratio of the peak intensity calculated from the ¹³C-NMR measurement by a conventional method.

(Another Constitutional Unit: Constitutional Unit C)

The polymer X may contain another constitutional unit (hereinafter, may be referred to as a “constitutional unit C”) in addition to the constitutional unit A and the constitutional unit B described above. Various characteristics of the polymer X can be adjusted by adjusting at least any one of the kind or the content of the constitutional unit C contained in the polymer X. In particular, the glass transition temperature (Tg) of the polymer X can be easily adjusted by properly using the constitutional unit C.

Examples of the monomer that forms the constitutional unit C include styrenes, an (meth)acrylic acid alkyl ester, an (meth)acrylic acid cyclic alkyl ester, an (meth)acrylic acid aryl ester, an (meth)acrylic acid ester having a hindered amine structure, an unsaturated dicarboxylic acid diester, a bicyclic unsaturated compound, a maleimide compound, an unsaturated aromatic compound, a conjugated diene compound, an unsaturated monocarboxylic acid, an unsaturated dicarboxylic acid, an unsaturated dicarboxylic acid anhydride, an unsaturated compound having an aliphatic cyclic skeleton, and another known unsaturated compound.

Examples of the constitutional unit C include a constitutional unit derived from styrene, tert-butoxystyrene, methylstyrene, α-methylstyrene, acetoxystyrene, methoxystyrene, ethoxystyrene, chlorostyrene, methyl vinylbenzoate, ethyl vinylbenzoate, methyl (meth)acrylate, ethyl (meth)acrylate, n-propyl (meth)acrylate, isopropyl (meth)acrylate, 2-hydroxyethyl acrylate, 2-hydroxypropyl (meth)acrylate benzyl (meth)acrylate, isobornyl (meth)acrylate, 1,2,2,6,6-pentamethyl-4-piperidyl (meth)acrylate, acrylonitrile, and a mono(meth)acrylate of ethylene glycol monoacetoaceate. In addition, examples of the constitutional unit C include constitutional units derived from the compounds described in paragraphs 0021 to 0024 of JP2004-264623A.

One kind of the constitutional unit C may be used alone, or two or more kinds thereof may be used.

The content of the constitutional unit C in the polymer X is preferably 80% by mass or less, more preferably 75% by mass or less, still more preferably 60% by mass or less, and particularly preferably 50% by mass or less, with respect to the total mass of the polymer X. The lower limit value of the content of the constitutional unit C in the polymer X may be 0% by mass with respect to all the constitutional units that constitute the polymer X. However, it is preferably 1% by mass or more and more preferably 5% by mass or more. In a case of setting the content of the constitutional unit C in the polymer X within the above-described numerical range, it is possible to further improve the resolution and the adhesiveness.

The polymer X will be exemplified below.

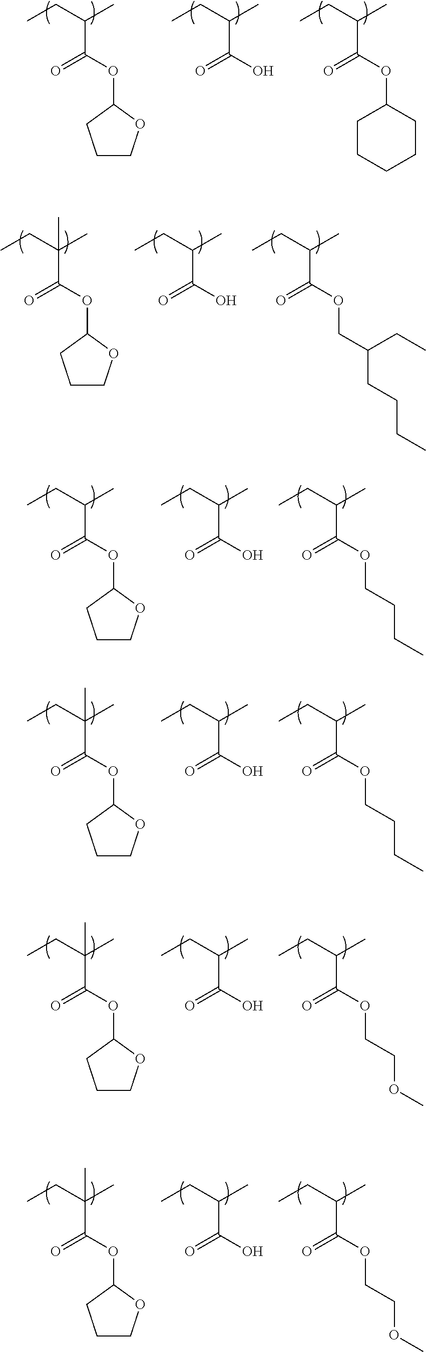

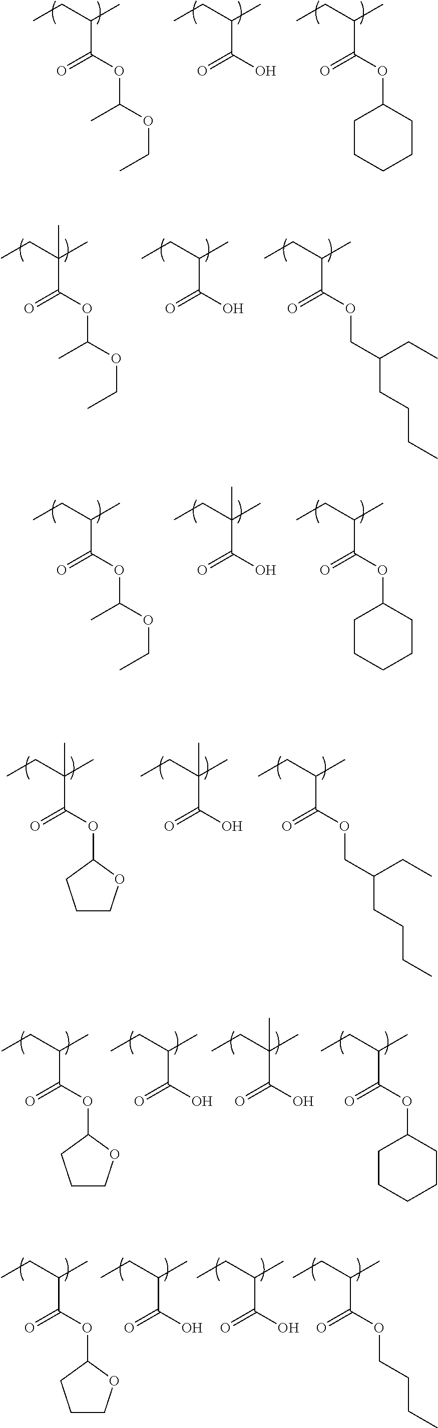

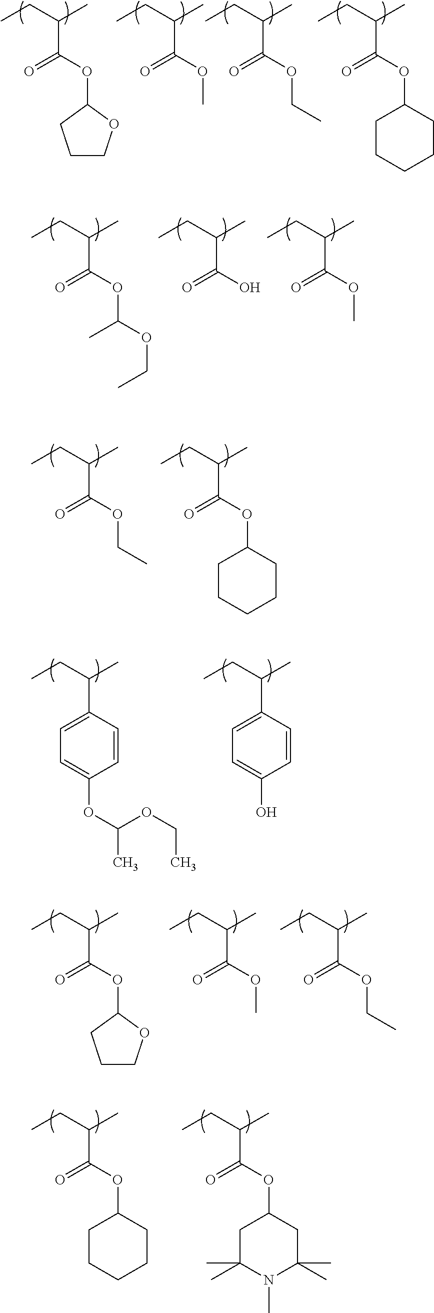

One kind of the polymer X may be used alone, or two or more kinds thereof may be used.

From the viewpoint of exhibiting good adhesiveness to the substrate, the content of the polymer X is preferably 50% to 99.9% by mass and more preferably 70% to 98% by mass with respect to the total solid content of the composition.

<Photoacid Generator>

From the viewpoint of sensitivity and resolution, the chemical amplification type photosensitive resin layer preferably contains a photoacid generator. The photoacid generator is a compound that is capable of generating an acid by being irradiated with radiation such as ultraviolet rays, far ultraviolet rays, X-rays, and/or charged particle beams.

The photoacid generator is preferably a compound which becomes sensitive to an actinic ray having a wavelength of 300 nm or more (preferably 300 nm to 450 nm) and generates an acid; however, the chemical structure thereof is not limited. A photoacid generator which does not directly become sensitive to an actinic ray having a wavelength of 300 nm or more can also be preferably used in combination with a sensitizing agent as long as it is a compound which becomes sensitive to an actinic ray having a wavelength of 300 nm or more and then generates an acid by being used in combination with the sensitizing agent.

The photoacid generator is preferably a photoacid generator that generates an acid having a pKa of 4 or less, more preferably a photoacid generator that generates an acid having a pKa of 3 or less, and particularly preferably a photoacid generator that generates an acid having a pKa of 2 or less. The lower limit value of the pKa of the acid generated from the photoacid generator is not limited, and it is preferably, for example, -10 or more.

Examples of the photoacid generator include an ionic photoacid generator and a nonionic photoacid generator. In addition, from the viewpoint of sensitivity and resolution, the photoacid generator preferably contains at least one compound selected from the group consisting of an onium salt compound and an oxime sulfonate compound, and it preferably contains an oxime sulfonate compound.

Examples of the ionic photoacid generator include onium salt compounds such as diaryliodonium salts and triarylsulfonium salts, and quaternary ammonium salts. Among them, the ionic photoacid generator is preferably an onium salt compound and more preferably diaryliodonium salts and triarylsulfonium salts.

The ionic photoacid generator is also preferably the ionic photoacid generator described in paragraphs 0114 to 0133 of JP2014-085643A.

Examples of the nonionic photoacid generator include trichloromethyl-s-triazines, a diazomethane compound, an imide sulfonate compound, and an oxime sulfonate compound. Among them, the nonionic photoacid generator is preferably an oxime sulfonate compound from the viewpoints of sensitivity, resolution, and adhesiveness. Specific examples of the trichloromethyl-s-triazines and the diazomethane derivative include the compounds described in paragraphs 0083 to 0088 of JP2011-221494A.

The oxime sulfonate compound, that is, the compound having an oxime sulfonate structure is preferably a compound having an oxime sulfonate structure represented by General Formula (B1).

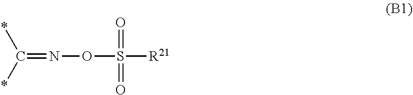

In General Formula (B1), R²¹ represents an alkyl group or an aryl group, and * represents a bonding site to another atom or another group.

Any group of the compound having an oxime sulfonate structure represented by General Formula (B1) may be substituted, and the alkyl group in R²¹ may be linear, may have a branched structure, or may have a ring structure. Acceptable substituents are described below.

The alkyl group as R²¹ is preferably a linear or branched alkyl group having 1 to 10 carbon atoms. The alkyl group in R²¹ may be substituted with an aryl group having 6 to 11 carbon atoms, an alkoxy group having 1 to 10 carbon atoms, a cycloalkyl group (for example, it includes a bridge-type alicyclic group such as a 7,7-dimethyl-2-oxonorbornyl group, and it is preferably a bicycloalkyl group or the like), or a halogen atom.

The aryl group in R²¹ is preferably an aryl group having 6 to 18 carbon atoms and more preferably a phenyl group or a naphthyl group. The aryl group in R²¹ may be substituted with one or more groups selected from the group consisting of an alkyl group having 1 to 4 carbon atoms, an alkoxy group, and a halogen atom.

The compound having an oxime sulfonate structure represented by General Formula (B1) is also preferably the oxime sulfonate compound described in paragraphs 0078 to 0111 of JP2014-085643A.

Examples of the photoacid generator include a photoacid generator described in the description of the photosensitive resin composition described above and a photoacid generator described in the description of the thermoplastic resin composition described later.

One kind of photoacid generator may be used alone, or two or more kinds thereof may be used.

From the viewpoint of sensitivity and resolution, the content of the photoacid generator is preferably 0.1% to 10% by mass and more preferably 0.5% to 5% by mass with respect to the total solid content of the composition.

<Other Components>

It is also preferable that the chemical amplification type photosensitive resin composition contains components other than the compound A, the polymer X, and the photoacid generator.

Examples of the other components include components that do not correspond to the compound A, the polymer X, and the photoacid generator among the components mentioned as components that can be contained in the above-described negative type photosensitive resin composition, among which a solvent and/or benzotriazoles are preferably contained.

The content of the benzotriazoles is, for example, preferably 0.01% to 10% by mass and more preferably 0.1% to 5% by mass with respect to the total solid content of the composition.

The content of the solvent is, for example, preferably 50 to 990 parts by mass and more preferably 300 to 950 parts by mass with respect to 100 parts by mass of the total solid content of the composition.

<Physical Properties of the Formed Layer and the Like>

The method of applying the composition using the chemical amplification type photosensitive resin composition and/or the method of forming the composition layer is not particularly limited and can be carried out, for example, in the same manner as in the method using the negative type photosensitive resin composition.

The layer thickness (the film thickness) of the composition layer (the chemical amplification type photosensitive resin layer) formed of the chemical amplification type photosensitive resin composition is generally 0.1 to 300 pm, preferably 0.2 to 100 pm, more preferably 0.5 to 50 pm, still more preferably 0.5 to 15 pm, particularly preferably 0.5 to 10 pm, and most preferably 0.5 to 8 pm.

[Thermoplastic Resin Composition]

The composition according to the embodiment of the present invention may be a thermoplastic resin composition that is capable of forming a thermoplastic resin layer.

For example, in a transfer film having a temporary support and a photosensitive resin layer (a layer consisting of the negative type photosensitive resin composition described above, a layer consisting of the chemical amplification type photosensitive resin composition, or the like), it is preferable that the thermoplastic resin layer is formed between the temporary support and the photosensitive resin layer.

In a case where the transfer film includes a thermoplastic resin layer between the temporary support and the photosensitive resin layer, the followability to the substrate in the affixing step of the transfer film and the substrate is improved, and the mixing of air bubbles between the substrate and the transfer film is suppressed, whereby the adhesiveness to an adjacent layer (for example, the temporary support) can be improved.

The thermoplastic resin composition as the composition according to the embodiment of the present invention contains the compound A and a resin. The thermoplastic resin composition contains a thermoplastic resin as a part or the whole of the resin.

That is, in one aspect, it is also preferable that in the composition according to the embodiment of the present invention, the resin is a thermoplastic resin.

<Alkali-Soluble Resin (Thermoplastic Resin)>

The thermoplastic resin contained in the thermoplastic resin composition is preferably an alkali-soluble resin.

Examples of the alkali-soluble resin include an acrylic resin, a polystyrene resin, a styrene-acrylic copolymer, a polyurethane resin, polyvinyl alcohol, polyvinyl formal, a polyamide resin, a polyester resin, a polyamide resin, an epoxy resin, a polyacetal resin, a polyhydroxystyrene resin, a polybenzoxazole resin, a polysiloxane resin, polyethyleneimine, polyallylamine, and polyalkylene glycol.

The alkali-soluble resin is preferably an acrylic resin from the viewpoint of developability and adhesiveness to an adjacent layer.

Here, the acrylic resin means a resin having at least one constitutional unit selected from the group consisting of a constitutional unit derived from (meth)acrylic acid, a constitutional unit derived from (meth)acrylic acid ester, and a constitutional unit derived from (meth)acrylic acid amide.

In the acrylic resin, the total content of the constitutional unit derived from (meth)acrylic acid, the constitutional unit derived from (meth)acrylic acid ester, and the constitutional unit derived from (meth)acrylic acid amide is preferably 50% by mass or more with respect to the total mass the acrylic resin.

Among the above, the total content of the constitutional unit derived from (meth)acrylic acid and the constitutional unit derived from (meth)acrylic acid ester is preferably 30% to 100% by mass and more preferably 50% to 100% by mass with respect to the total mass of the acrylic resin.

Further, the alkali-soluble resin is preferably a polymer having an acid group.

Examples of the acid group include a carboxy group, a sulfo group, a phosphoric acid group, and a phosphonic acid group, where a carboxy group is preferable.

From the viewpoint of developability, the alkali-soluble resin is more preferably an alkali-soluble resin having an acid value of 60 mgKOH/g or more and still more preferably a carboxy group-containing acrylic resin having an acid value of 60 mgKOH/g or more.

The upper limit of the acid value of the alkali-soluble resin is not particularly limited; however, it is preferably 300 mgKOH/g or less, more preferably 250 mgKOH/g or less, still more preferably 200 mgKOH/g or less, and particularly preferably 150 mgKOH/g or less.

The carboxy group-containing acrylic resin having an acid value of 60 mgKOH/g or more is not particularly limited and can be appropriately selected from known resins and used.

Examples thereof include an alkali-soluble resin which is the carboxy group-containing acrylic resin having an acid value of 60 mgKOH/g or more among the polymers described in paragraph 0025 of JP2011-095716A, the carboxy group-containing acrylic resin having an acid value of 60 mgKOH/g or more among the polymers described in paragraphs 0033 to 0052 of JP2010-237589A, and the carboxy group-containing acrylic resin having an acid value of 60 mgKOH/g or more among the binder polymers described in paragraphs 0053 to 0068 of JP2016-224162A.

The copolymerization ratio of the constitutional unit having a carboxy group in the above-described carboxy group-containing acrylic resin is preferably 5% to 50% by mass, more preferably 10% to 40% by mass, and still more preferably 12% to 30% by mass, with respect to the total mass of the acrylic resin.

The alkali-soluble resin is particularly preferably an acrylic resin having a constitutional unit derived from (meth) acrylic acid from the viewpoints of developability and adhesiveness to an adjacent layer.

The alkali-soluble resin may have a reactive group. It suffices that the reactive group is any addition-polymerizable group. Examples of the reactive group include an ethylenically unsaturated group; a polycondensable group such as a hydroxy group or a carboxy group; and a polyaddition reactive group such as an epoxy group or a (blocked) isocyanate group.

The weight-average molecular weight (Mw) of the alkali-soluble resin is preferably 1,000 or more, more preferably 10,000 to 100,000, and still more preferably 20,000 to 50,000.

One kind of alkali-soluble resin may be used alone, or two or more kinds thereof may be used.

From the viewpoint of developability and adhesiveness to an adjacent layer, the content of the alkali-soluble resin is preferably 10% to 99% by mass, more preferably 20% to 90% by mass, still more preferably 40% to 80% by mass, and particularly preferably 50% to 70% by mass, with respect to the total solid content of the composition.

<Coloring Agent>

The thermoplastic resin layer preferably contains a coloring agent (hereinafter, simply also referred to as a “coloring agent B”) that has a maximum absorption wavelength of 450 nm or more in a wavelength range of 400 to 780 nm at the time of color development, where the maximum absorption wavelength is changed by an acid, a base, or a radical.

The preferred aspect of the coloring agent B is the same as the preferred aspect of the coloring agent N described above, except for the points described later.

From the viewpoints of the visibility of the exposed portion and the non-exposed portion and the resolution, the coloring agent B is preferably a coloring agent of which the maximum absorption wavelength is changed by an acid or a radical, and more preferably a coloring agent of which the maximum absorption wavelength is changed by an acid.

From the viewpoints of the visibility of the exposed portion and the non-exposed portion and the resolution, the thermoplastic layer preferably contains both a coloring agent of which the maximum absorption wavelength is changed by an acid as the coloring agent B and a compound that generates an acid due to light described later.

One kind of the coloring agent B may be used alone, or two or more kinds thereof may be used.

From the viewpoint of visibility of the exposed portion and the non-exposed portion, the content of the coloring agent B is preferably 0.2% by mass or more, more preferably 0.2% to 6% by mass, still more preferably 0.2% to 5% by mass, and particularly preferably 0.25% to 3.0% by mass, with respect to the total solid content of the composition.

Here, the content of the coloring agent B means the content of the coloring agent in a case where the whole coloring agent B contained in the thermoplastic resin layer is in a colored state. Hereinafter, a method of quantifying the content of the coloring agent B will be described by taking a coloring agent that develops color by a radical as an example.

0.001 g and 0.01 g of a coloring agent are each dissolved in 100 mL of methyl ethyl ketone to prepare a solution. A photoradical polymerization initiator Irgacure OXE01 (product name, BASF Japan Ltd.) is added to each of the obtained solutions, and radicals are generated by the irradiation with light of 365 nm to bring the whole coloring agent into a colored state. Then, in the atmospheric air, the absorbance of each solution having a liquid temperature of 25° C. is measured using a spectrophotometer (UV3100, manufactured by Shimadzu Corporation), and a calibration curve is created.

Next, the absorbance of the solution in which the whole coloring agent has been caused to develop a color is measured by the same method as the above except that 0.1 g of the solid content of the composition is dissolved in methyl ethyl ketone instead of the coloring agent. From the obtained absorbance of the solution containing the solid content of the composition, the amount of the coloring agent contained in the solid content of the composition is calculated based on the calibration curve.

It is noted that 3 g of the solid content of the composition is the same as 3 g of a layer (a thermoplastic resin layer or the like) formed of the composition.

<Compound that Generates Acid, Base, or Radical Due to Light>

The thermoplastic resin composition may contain a compound that generates an acid, a base, or a radical due to light (hereinafter, also simply referred to as a “compound C”).

The compound C is preferably a compound that generates an acid, a base, or a radical by receiving an actinic ray such as an ultraviolet ray or a visible ray.

As the compound C, a known photoacid generator, a known photobase generator, and a known photoradical polymerization initiator (photoradical generator) can be used. Among the above, a photoacid generator is preferable.

(Photoacid Generator)

From the viewpoint of resolution, the thermoplastic resin composition preferably contains a photoacid generator.

Examples of the photoacid generator include a photocationic polymerization initiator which may be contained in the above-described negative type photosensitive resin composition, and the same applies to the preferred aspect thereof except for the points described below.

From the viewpoints of sensitivity and resolution, the photoacid generator preferably contains at least one compound selected from the group consisting of an onium salt compound and an oxime sulfonate compound, and from the viewpoints of sensitivity, resolution, and adhesiveness, it more preferably contains an oxime sulfonate compound.

Further, the photoacid generator is preferably a photoacid generator having the following structure.

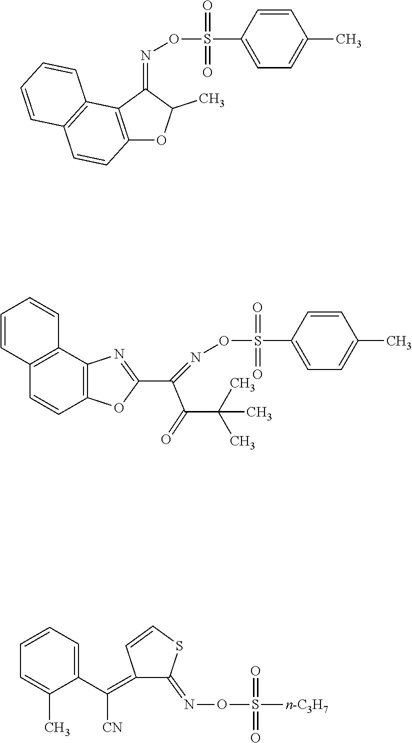

(Photoradical Polymerization Initiator)

The thermoplastic resin composition may contain a photoradical polymerization initiator.

Examples of the photoradical polymerization initiator include a photoradical polymerization initiator which may be contained in the above-described negative type photosensitive resin composition, and the same applies to the preferred aspect thereof.

(Photobase Generator)

The thermoplastic resin composition may contain a photobase generator.

The photobase generator is not particularly limited as long as it is a known photobase generator, and examples thereof include 2-nitrobenzylcyclohexylcarbamate, triphenyl methanol, O-carbamoylhydroxylamide, 0-carbamoyloxime, [[(2,6-dinitrobenzyl)oxy]carbonyl]cyclohexylamine, bis[[(2-nitrobenzyl)oxy]carbonyl]hexane-1,6-diamine, 4-(methylthiobenzoyl)-1-methyl-1-morpholinoethane, (4-morpholinobenzoyl)-1-benzyl-1-dimethylaminopropane, N-(2-nitrobenzyloxycarbonyl)pyrrolidine, hexaammine cobalt (III) tris(triphenylmethylborate), 2-benzyl-2-dimethylamino-1-(4-morpholinophenyl)-butanone, 2,6-dimethyl-3,5-diacetyl-4-(2-nitrophenyl)-1,4-dihydropyridine, and 2,6-dimethyl-3,5-diacetyl-4-(2,4-dinitrophenyl)-1,4-dihydropyridine.

One kind of the compound C may be used alone, or two or more kinds thereof may be used.

From the viewpoints of the visibility of the exposed portion and the non-exposed portion and the resolution, the content of the compound C is preferably 0.1% to 10% by mass and more preferably 0.5% to 5% by mass with respect to the total solid content of the composition.

<Plasticizer>

The thermoplastic resin composition preferably contains a plasticizer from the viewpoints of the resolution of the formed composition layer (the thermoplastic resin layer), the adhesiveness to an adjacent layer, and the developability.

The plasticizer preferably has a molecular weight (a weight-average molecular weight in a case where the plasticizer is an oligomer or a polymer and has a molecular weight distribution) smaller than that of the alkali-soluble resin. The molecular weight (the weight-average molecular weight) of the plasticizer is preferably 200 to 2,000.

The plasticizer is not particularly limited as long as it is a compound that is compatible with an alkali-soluble resin and exhibits plasticity. However, from the viewpoint of imparting plasticity, the plasticizer preferably has an alkyleneoxy group in the molecule, and it is more preferably a polyalkylene glycol compound. The alkyleneoxy group contained in the plasticizer more preferably has a polyethyleneoxy structure or a polypropyleneoxy structure.

In addition, the plasticizer preferably contains an (meth)acrylate compound from the viewpoints of resolution and storage stability. From the viewpoint of compatibility, resolution, and adhesiveness to an adjacent layer, it is more preferable that the alkali-soluble resin is an acrylic resin and the plasticizer contains an (meth)acrylate compound.

Examples of the (meth)acrylate compound that is used as the plasticizer include the (meth)acrylate compound described as the polymerizable compound contained in the negative type photosensitive resin composition described above.

In a transfer film, in a case where the thermoplastic resin layer and the negative type photosensitive resin layer are laminated in direct contact with each other, it is preferable that both the thermoplastic resin layer and the photosensitive resin layer contain the same (meth)acrylate compound. This is due to the reason that in a case where the thermoplastic resin layer and the negative type photosensitive resin layer each contain the same (meth)acrylate compound, the diffusion of components between the layers is suppressed and the storage stability is improved.

In a case where the thermoplastic resin composition contains an (meth)acrylate compound as a plasticizer, it is preferable that the (meth)acrylate compound does not polymerize even in the exposed portion after exposure from the viewpoint of adhesiveness to a layer adjacent to the thermoplastic resin layer.

In addition, the (meth)acrylate compound that is used as a plasticizer is preferably an (meth)acrylate compound having two or more an (meth)acryloyl groups in one molecule from the viewpoints of the resolution of the thermoplastic resin layer, the adhesiveness to an adjacent layer, and the developability.

Further, the (meth)acrylate compound that is used as a plasticizer is also preferably an (meth)acrylate compound having an acid group or a urethane (meth)acrylate compound.

One kind of plasticizer may be used alone, or two or more kinds thereof may be used.

From the viewpoints of the resolution of the thermoplastic resin layer, the adhesiveness to an adjacent layer, and the developability, the content of the plasticizer is preferably 1% to 70% by mass, more preferably 10% to 60% by mass, and still more preferably 20% to 50% by mass, with respect to the total solid content of the composition.

<Sensitizing Agent>

The thermoplastic resin composition may contain a sensitizing agent.

The sensitizing agent is not particularly limited, and examples thereof include a sensitizing agent which may be contained in the negative type photosensitive resin layer described above.

One kind of sensitizing agent may be used alone, or two or more kinds thereof may be used.

The content of the sensitizing agent can be appropriately selected depending on the intended purpose. However, it is preferably 0.01% to 5% by mass and more preferably 0.05% to 1% by mass with respect to the total solid content of the composition from the viewpoints of the improvement of the sensitivity to the light source and the visibility of the exposed portion and the non-exposed portion.

<Solvent>

The thermoplastic resin composition may contain a solvent.

The solvent is not particularly limited, and examples thereof include a solvent which may be contained in the negative type photosensitive resin layer described above.

It is also preferable that the thermoplastic resin composition contains at least one solvent selected from the group consisting of an alkylene glycol ether and an alkylene glycol ether acetate.

The content of the solvent is preferably 50 to 1,900 parts by mass and more preferably 100 to 900 parts by mass with respect to 100 parts by mass of the total solid content of the composition.

<Additive and the Like>

The thermoplastic resin composition may contain a known additive in addition to the above-described components, as necessary.

In addition, the thermoplastic resin layer is described in paragraphs 0189 to 0193 of JP2014-085643A, and the content described in this publication is incorporated in the present specification.

<Physical Properties of the Formed Layer and the Like>

The layer thickness of the layer (the thermoplastic resin layer) formed of the thermoplastic resin composition is not particularly limited; however, it is preferably 1 pm or more and more preferably 2 pm or more from the viewpoint of adhesiveness to an adjacent layer. The upper limit is not particularly limited. However, it is preferably 20 pm or less, more preferably 10 pm or less, and still more preferably 8 pm or less from the viewpoints of developability and resolution.

The method of forming the thermoplastic resin layer is not particularly limited as long as it is a method capable of forming a layer containing the above components.

Examples thereof include a method of applying the thermoplastic resin composition onto the surface of the temporary support or the like, and drying the coating film of the thermoplastic resin composition to form the thermoplastic resin layer.

In addition, the thermoplastic resin layer may be formed on the surface of an interlayer after forming the photosensitive resin layer and the interlayer on the cover film described later.

[Water-Soluble Resin Composition]

The composition according to the embodiment of the present invention may be a water-soluble resin composition.

For example, in a transfer film having a thermoplastic resin layer and a negative type photosensitive resin layer, the water-soluble resin composition can be used for forming an interlayer that can be present between the thermoplastic resin layer and the negative type photosensitive resin layer.

In a case where an interlayer is provided, it is possible to suppress the mixing of components in a case where a plurality of layers are coated and in a case of storage after the coating.

Examples of the interlayer include the oxygen blocking layer having an oxygen blocking function, which is described as a “separation layer” in JP1993-072724A (JP-H5-072724A). It is preferable that the interlayer is an oxygen blocking layer since the sensitivity at the time of exposure is improved, the time load of the exposure machine is reduced, and the productivity is improved.

The oxygen blocking layer that is used as the interlayer may be appropriately selected from known layers described in the above-described publications. Among them, it is preferably an oxygen blocking layer that exhibits low oxygen permeability and is dispersed or dissolved in water or an alkaline aqueous solution (an aqueous solution of 1% by mass sodium carbonate at 22° C.).

The water-soluble resin composition as the composition according to the embodiment of the present invention contains the compound A and a resin. The water-soluble resin composition contains a water-soluble resin as a part or the whole of the resin.

That is, in one aspect, it is also preferable that in the composition according to the embodiment of the present invention, the resin is a water-soluble resin.

<Water-Soluble Resin>

Examples of the resin capable of being used as the water-soluble resin include resins such as a polyvinyl alcohol-based resin, a polyvinyl pyrrolidone-based resin, a cellulose-based resin, an acrylamide-based resin, a polyethylene oxide-based resin, gelatin, a vinyl ether-based resin, a polyamide resin, and a copolymer thereof.

In a case where the water-soluble resin layer is used as the interlayer, it is preferably a resin different from the resin contained in the adjacent layer (for example, the polymer A contained in the negative type photosensitive resin layer and/or the thermoplastic resin (the alkali-soluble resin) contained in the thermoplastic resin layer from the viewpoint of suppressing the mixing of components between a plurality of layers.

From the viewpoints of oxygen blocking properties and suppressing mixing of components in a case of coating a plurality of layers and in a case of storing after coating, the water-soluble resin preferably contains polyvinyl alcohol and more preferably contains both polyvinyl alcohol and polyvinyl pyrrolidone.

One kind of water-soluble resin may be used alone, or two or more kinds thereof may be used.

The content of the water-soluble resin is not particularly limited. However, from the viewpoints of oxygen blocking properties and suppressing mixing of components in a case of coating a plurality of layers and in a case of storing after coating, it is preferably 50% by mass or more and less than 100% by mass, more preferably 70% by mass or more and less than 100% by mass, still more preferably 80% by mass or more and less than 100% by mass, and particularly preferably 90% by mass or more and less than 100% by mass, with respect to the total solid content of the water-soluble resin composition.

<Solvent>

It is also preferable that the water-soluble resin composition contains a solvent.

The solvent contained in the water-soluble resin composition is not particularly limited as long as the water-soluble resin is capable of being dissolved or dispersed, and the solvent is preferably at least one selected from the group consisting of water and a water-miscible organic solvent, and it is more preferably water or a mixed solvent of water and a water-miscible organic solvent.

Examples of the water-miscible organic solvent include alcohol having 1 to 3 carbon atoms, acetone, ethylene glycol, and glycerin, where alcohol having 1 to 3 carbon atoms is preferable, and methanol or ethanol is more preferable.

The content of the solvent is preferably 50 to 2,500 parts by mass, more preferably 50 to 1,900 parts by mass, still more preferably 100 to 900 parts by mass, with respect to 100 parts by mass of the total solid content of the composition.

<Physical Properties of the Formed Layer and the Like>

The method of applying the composition using the water-soluble resin composition and/or the method of forming the composition layer is not particularly limited and can be carried out, for example, in the same manner as in the method using the negative type photosensitive resin composition.

A method of forming a water-soluble resin layer (a composition layer formed of the water-soluble resin layer) as the interlayer is not particularly limited. Examples thereof include a method of forming a water-soluble resin layer by applying the water-soluble resin composition onto the surface of the thermoplastic resin layer or the photosensitive resin layer and drying the coating film of the water-soluble resin composition.

The layer thickness of the water-soluble resin layer is not particularly limited; however, it is preferably 0.1 to 5 pm and more preferably 0.5 to 3 pm.

This is due to the reason that in a case where the thickness of the water-soluble resin layer is within the above range, it is possible to suppress the mixing of components in a case of coating a plurality of layers and in a case of storing after the coating, without reducing the oxygen blocking properties, and it is possible to suppress an increase in the removal time of the water-soluble resin layer in a case of development.

[Composition Containing Specific Material]

In addition to the compound A and the resin, the composition according to the embodiment of the present invention may be a composition containing at least one material (hereinafter, also referred to as a “specific material”) selected from the group consisting of a metal oxide, a compound having a triazine ring, and a compound having a fluorene skeleton.

The specific material is a material suitable for adjusting the refractive index of the composition layer, and a refractive index adjusting layer can be formed by using a composition containing such a specific material.

The refractive index adjusting layer is preferably present on the upper side (on a side far from a temporary support) of the photosensitive composition layer (a layer consisting of the negative type photosensitive resin composition described above, a layer consisting of the chemical amplification type photosensitive resin composition, or the like).

<Specific Material>

The kind of metal oxide is not particularly limited, and examples of the metal oxide include known metal oxides. The metal of the metal oxide includes semimetals such as B, Si, Ge, As, Sb, and Te.

Examples of the metal oxide include zirconium oxide, titanium oxide, tin oxide, zinc oxide, indium tin oxide, indium oxide, aluminum oxide, and yttrium oxide.

Among these, the metal oxide is preferably, for example, at least one selected from the group consisting of zirconium oxide and titanium oxide from the viewpoint of easily adjusting the refractive index.

The metal oxide preferably has a particle shape.

The average primary particle diameter of the metal oxide particles is, for example, preferably 1 to 200 nm and more preferably 3 to 80 nm from the viewpoint of the transparency of the cured film.

The average primary particle diameter of the particles is calculated by measuring the particle diameters of 200 particles randomly selected using an electron microscope and arithmetically averaging the measurement results. It is noted that in a case where the shape of the particle is not spherical, the longest side of the particle is regarded as the particle diameter.

Examples of the commercially available product of the metal oxide particle include baked zirconium oxide particle (manufactured by CIK NanoTek Corporation, product name: ZRPGM15WT %-F04), baked zirconium oxide particle (manufactured by CIK NanoTek Corporation, product name: ZRPGM15WT %-F74), baked zirconium oxide particle (manufactured by CIK NanoTek Corporation, product name: ZRPGM15WT %-F75), baked zirconium oxide particle (manufactured by CIK NanoTek Corporation, product name: ZRPGM15WT %-F76), zirconium oxide particle (NanoUse OZ-S30M, manufactured by Nissan Chemical Industries, Ltd.), and zirconium oxide particles (NanoUse OZ-S30K, manufactured by Nissan Chemical Industries, Ltd.).

Examples of the compound having a triazine ring include a polymer having a triazine ring in the structural unit, where a compound having a structural unit represented by General Formula (X) is included.

It is preferable that the polymer having a triazine ring in the structural unit is different from the resin that should be contained in the composition according to the embodiment of the present invention.

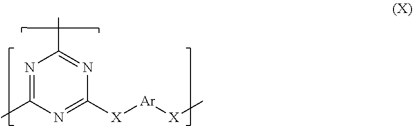

In the formula, Ar represents a divalent group including at least one selected from an aromatic ring (having, for example, 6 to 20 carbon atoms) or a heterocyclic ring (having, for example, 5 to 20 carbon atoms).

X's each independently represent NR¹. R¹'s each independently represent a hydrogen atom, an alkyl group (having, for example, 1 to 20 carbon atoms), an alkoxy group (having, for example, 1 to 20 carbon atoms), an aryl group (having, for example, 6 to 20 carbon atoms), or an aralkyl group (having, for example, 7 to 20 carbon atoms). A plurality of X's may be the same or different from each other.

Specifically, it is preferably a hyperbranched polymer having a triazine ring, and it is commercially available, for example, as HYPERTECH series (product name, manufactured by Nissan Chemical Industries, Ltd.).

The compound having a fluorene skeleton is preferably a compound having a 9,9-bis[4-2-(meth)acryloyloxyethoxyphenyl]fluorene skeleton. The above compound may be modified with (poly)oxyethylene or (poly)oxypropylene. These are commercially available, for example, as EA-0200 (product name, manufactured by Osaka Gas Chemicals Co., Ltd.). Further, epoxy modification can be carried out with epoxy acrylate. These are commercially available, for example, as GA5000 or EG200 (product name, manufactured by Osaka Gas Chemicals Co., Ltd.).

One kind of the specific material may be used alone, or two or more kinds thereof may be used.

The content of the specific material in the refractive index adjusting layer is preferably 50% by mass or more, more preferably 60% by mass or more, and particularly preferably 70% by mass or more, with respect to the total mass of the refractive index adjusting layer. The upper limit thereof is not particularly limited; however, it is preferably 95% by mass or less and more preferably 90% by mass or less.

<Alkali-Soluble Resin>

The resin contained in the composition containing the specific material is preferably an alkali-soluble resin.

As the alkali-soluble resin, the above-described alkali-soluble resin (the alkali-soluble resin described in the description of the thermoplastic resin composition, the polymer A described in the description of the negative type photosensitive resin composition, or the like) can also be used.

In addition, it is also preferable that the alkali-soluble resin contained in the composition containing the specific material is a resin (a water-soluble resin) having solubility in an aqueous solvent (preferably water or a mixed solvent of a lower alcohol (methanol) having 1 to 3 carbon atoms and water).

It is also preferable that the alkali-soluble resin contained in the composition containing the specific material is a copolymer resin of (meth)acrylic acid/vinyl compound. The copolymer resin is more preferably a copolymer resin of (meth)acrylic acid/allyl (meth)acrylate.

One kind of alkali-soluble resin may be used alone, or two or more kinds thereof may be used.

The content of the alkali-soluble resin is preferably 1% to 50% by mass, more preferably 1% to 40% by mass, still more preferably 5% to 30% by mass, and particularly preferably 5% to 20% by mass, with respect to the total solid content of the composition.

<Metal Oxidation Inhibitor>

In addition, the composition containing the specific material preferably contains a metal oxidation inhibitor.

In a case where the refractive index adjusting layer formed of the composition containing the specific material contains a metal oxidation inhibitor, it is possible to suppress the oxidation of the metal in contact with the refractive index adjusting layer.

The metal oxidation inhibitor is preferably, for example, a compound having an aromatic ring containing a nitrogen atom in the molecule. Examples of the metal oxidation inhibitor include imidazoles, benzimidazoles, tetrazoles, mercaptothiadiazoles, benzotriazoles, pyridines (isonicotinamide and the like), and purine bases (adenine and the like).

As the benzotriazoles, it is possible to use, for example, the benzotriazoles described in the description of the negative type photosensitive composition.

The content of the metal oxidation inhibitor is preferably 0.01% to 10% by mass and more preferably 0.1% to 5% by mass with respect to the total solid content of the composition.

<Solvent>

It is also preferable that the composition containing the specific material contains a solvent.

Examples of the solvent contained in the composition containing the specific material include the same solvent as the solvent contained in the water-soluble resin composition.

The content of the solvent is preferably 50 to 19,000 parts by mass and more preferably 1,000 to 9,000 parts by mass with respect to 100 parts by mass of the total solid content of the composition.

<Other Components>

It is also preferable that the composition containing the specific material contains components other than the compound A, the resin having an acid group, the specific material, the metal oxidation inhibitor, and the solvent.

Examples of the other components include components that do not correspond to the compound A, the resin having an acid group, the specific material, the metal oxidation inhibitor, and the solvent among the components mentioned as components that can be contained in the negative type photosensitive resin composition described above. Among them, a polymerizable compound is preferably contained.

The content of the polymerizable compound is, for example, preferably 0.01% to 10% by mass and more preferably 0.1% to 5% by mass with respect to the total solid content of the composition. The polymerizable compound contained in the composition containing the specific material is preferably a polymerizable compound having an acid group.

Examples of the other components also include amino alcohol (N-methyldiethanolamine, monoisopropanolamine, and the like). The amino alcohol is preferably a compound having one or more (for example, 1 to 5) primary alcohol groups and one or more (for example, 1 to 5) primary to tertiary amino groups. The content of the amino alcohol is, for example, preferably 0.01% to 10% by mass and more preferably 0.1% to 5% by mass with respect to the total solid content of the composition.

<Physical Properties of the Formed Layer and the Like>

The method of applying the composition using a composition containing the specific material and/or the method of forming the composition layer is not particularly limited and can be carried out, for example, in the same manner as in the method using the negative type photosensitive resin composition.

The position of the layer (the refractive index adjusting layer) formed of the composition containing the specific material is not particularly limited; however, it is preferably disposed in contact with the photosensitive resin layer (the negative type photosensitive resin layer or the like). Among the above, it is preferable that a transfer film having the layer (the refractive index adjusting layer) formed of the composition containing the specific material has the temporary support, the photosensitive resin layer, and the refractive index adjusting layer in this order.

In a case where the transfer film further includes a cover film described later, it is preferable to have the temporary support, the photosensitive resin layer, the refractive index adjusting layer, and the cover film in this order.

The refractive index of the refractive index adjusting layer is preferably 1.60 or more and more preferably 1.63 or more.

The upper limit of the refractive index of the refractive index adjusting layer is preferably 2.10 or less and more preferably 1.85 or less.

The upper limit of the thickness of the refractive index adjusting layer is preferably 500 nm or less, more preferably 110 nm or less, and still more preferably 100 nm or less. The lower limit of the thickness is, for example, 20 nm or more.

[Coloration Resin Composition]

The composition according to the embodiment of the present invention may be used as a coloration resin composition.

In recent years, a liquid crystal display window included in an electronic device may be attached with a cover glass having a black frame-shaped light shielding layer formed on the peripheral portion of the back surface of a transparent glass substrate or the like in order to protect the liquid crystal display window. A coloring composition can be used for forming such a light shielding layer.

The coloration resin composition is a composition containing a pigment.

That is, the composition according to the embodiment of the present invention may be a composition that further contains a pigment in addition to the compound A and the resin.

<Pigment>

The pigment contained in the coloration resin composition may be appropriately selected depending on the desired color tone, and it can be selected from a black pigment, a white pigment, and chromatic pigments other than black and white. Among them, in a case of forming a black pattern, a black pigment is suitably selected as the pigment.

As the black pigment, a known black pigment (an organic pigment, an inorganic pigment, or the like) can be appropriately selected as long as the effect of the present disclosure is not impaired. Among them, from the viewpoint of optical density, suitable examples of the black pigment include carbon black, titanium oxide, titanium carbide, iron oxide, and graphite, where carbon black is particularly preferable. From the viewpoint of surface resistance, the carbon black is preferably a carbon black in which at least a part of the surface is coated with a resin.

The black pigment (preferably carbon black) is preferably used in a form of a pigment dispersion liquid.

The dispersion liquid may be a dispersion liquid prepared by adding a mixture obtained by mixing in advance a black pigment and a pigment dispersing agent to an organic solvent (or a vehicle) and dispersing it with a disperser. The pigment dispersing agent may be selected depending on the pigment and the solvent, and for example, a commercially available dispersing agent can be used. It is noted that the vehicle refers to a medium portion which disperses a pigment in a case where the pigment is made to be a pigment dispersion liquid, where the vehicle is liquid and contains a binder component that holds the black pigment in a dispersed state and a solvent component (an organic solvent) that dissolves and dilutes the binder component.

The disperser is not particularly limited, and examples thereof include known dispersers such as a kneader, a roll mill, an attritor, a super mill, a dissolver, a homogenization mixer, and a sand mill. Further, fine pulverization may be carried out by mechanical grinding using frictional force. Regarding the disperser and fine pulverization, the description in “Encyclopedia of Pigments” (Kunizo Asakura, First Edition, Asakura Publishing Co., Ltd., 2000, 438, 310) can be referred to.

From the viewpoint of dispersion stability, the particle diameter of the black pigment is preferably 0.001 to 0.1 pm and more preferably 0.01 to 0.08 pm in terms of number average particle diameter.

Here, the particle diameter refers to a diameter of a circle in a case where the area of the pigment particles is determined from the photographic image of the pigment particles captured with an electronic microscope and a circle having the same area as the area of the pigment particles is assumed, and the number average particle diameter is an average value obtained by determining the above particle diameter for any 100 particles and averaging the determined diameters of the 100 particles.

As the pigment other than the black pigment, the white pigments described in paragraphs 0015 and 0114 of JP2005-007765A can be used as the white pigment. Specifically, among the white pigments, the inorganic pigment is preferably titanium oxide, zinc oxide, lithopone, light calcium carbonate, white carbon, aluminum oxide, aluminum hydroxide, or barium sulfate, more preferably titanium oxide or zinc oxide, and still more preferably titanium oxide. The inorganic pigment is preferably a rutile-type or anatase-type titanium oxide, and particularly preferably a rutile-type titanium oxide.

Further, the surface of titanium oxide may be subjected to a silica treatment, an alumina treatment, a titania treatment, a zirconia treatment, or an organic substance treatment, or may be subjected to two or more treatments. As a result, the catalytic activity of titanium oxide is suppressed, and thus heat resistance, light resistance, and the like are improved.

From the viewpoint of reducing the thickness of the photosensitive resin layer after heating, the surface treatment of the surface of titanium oxide is preferably at least one of an alumina treatment or a zirconia treatment, and particularly preferably both alumina treatment and zirconia treatment.

In addition, from the viewpoint of transferability, it is also preferable that the coloration resin composition further contains a chromatic pigment other than the black pigment and the white pigment. In a case where a chromatic pigment is contained, it is desirable that the chromatic pigment is well dispersed in the coloration resin layer, and from such a viewpoint, the particle diameter is preferably 0.1 pm or less and more preferably 0.08 pm or less.

Examples of the chromatic pigment include Victoria pure blue BO (Color Index (hereinafter C.I.) 42595), Auramine (C.I. 41000), Fat black HB (C.I. 26150), Monolite yellow GT (C.I. Pigment yellow 12), Permanent yellow GR (C.I. Pigment yellow 17), Permanent yellow HR (C.I. Pigment yellow 83), Permanent carmine FBB (C.I. Pigment red 146), Hoster balm red ESB (C.I. Pigment violet 19), Permanent ruby FBH (C.I. Pigment red 11), Pastel pink B supra (C.I. Pigment red 81), Monastral first blue (C.I. Pigment blue 15), Monolite first black B (C.I. Pigment black 1), and Carbon, as well as C.I. Pigment red 97, C.I. Pigment red 122, C.I. Pigment red 149, C.I. Pigment red 168, C.I. Pigment red 177, C.I. Pigment red 180, C.I. Pigment red 192, C.I. Pigment red 215, C.I. Pigment Green 7, C.I. Pigment blue 15:1, C.I. Pigment blue 15:4, C.I. Pigment blue 22, C.I. Pigment blue 60, C.I. Pigment blue 64, and C.I. Pigment violet 23. Among them, C.I. Pigment red 177 is preferable.

The content of the pigment is preferably more than 3% by mass and 40% by mass or less, more preferably more than 3% by mass and 35% by mass or less, still more preferably more than 5% by mass and 35% by mass or less, and particularly preferably 10% by mass or more and 35% by mass or less, with respect to the total solid content of the composition.

In a case where pigments (a white pigment and a chromatic pigment) other than the black pigment are contained, the content thereof is preferably 30% by mass or less, preferably 1% by mass to 20% by mass, and still more preferably 3% by mass to 15% by mass, with respect to the black pigment.

A pigment may be added to each of the above-described compositions to obtain a coloration resin composition.

For example, as described above, a composition obtained by adding a pigment (or a pigment dispersion liquid) to the above-described negative type photosensitive resin composition can be used as the coloration resin composition. That is, the negative type photosensitive resin composition described above may be used as a negative type photosensitive resin composition which is a coloration resin composition.

Similarly, each of the above-described composition layers may be used as a coloration resin layer to which a pigment has been added.

For example, the negative type photosensitive resin layer described above may be a coloration resin layer containing a pigment, as described above. That is, the negative type photosensitive resin layer described above may be a negative type photosensitive resin layer that is a coloration resin layer.

<Physical Properties of the Formed Layer and the Like>

The method of applying the composition using the coloration resin composition and/or the method of forming the composition layer is not particularly limited and can be carried out, for example, in the same manner as in the method using the negative type photosensitive resin composition.

The layer thickness (the film thickness) of the composition layer (the coloration resin layer) formed of the coloration resin composition is generally 0.1 to 300 pm, preferably 0.2 to 100 pm, more preferably 0.5 to 50 pm, still more preferably 0.5 to 15 pm, particularly preferably 0.5 to 10 pm, and most preferably 0.5 to 8 pm.

[Transfer Film]

The present invention also relates to a transfer film.

The transfer film according to the embodiment of the present invention is a transfer film having a temporary support and one or more composition layers (for example, 1 to 5 layers), where at least one layer of the composition layers is a layer formed of the composition according to the embodiment of the present invention (the composition layer).

In the transfer film, the temporary support and the one or more composition layers may be directly laminated without another layer being interposed therebetween or may be laminated with another layer being interposed therebetween. In addition, another layer may be laminated on a surface of the one or more composition layers on a side opposite to the surface facing the temporary support. Another layer may be present between the one or more composition layers.

The composition layer is a layer containing a resin, and it may be a layer (a composition layer) formed of the composition according to the embodiment of the present invention or may be a layer (a composition layer) formed of a composition (“a composition which is not allowed to contain the compound A” which will be described later) other than the present invention which does not correspond to the composition according to the embodiment of the present invention.

Hereinafter, the layer (the composition layer) formed of the composition according to the embodiment of the present invention is also referred to as “the composition layer according to the embodiment of the present invention”.

In addition, the layer (the composition layer) formed of a composition (“a composition which is not allowed to contain the compound A” which will be described later) other than the present invention which does not correspond to the composition according to the embodiment of the present invention is also referred to as “the composition layer other than the present invention”.

In the transfer film, it suffices that at least one layer of the one or more composition layers (for example, 1 to 5 layers) is the composition according to the embodiment of the present invention, half or more of the layers may be the composition layer according to the embodiment of the present invention, and all the layers may be the composition layer according to the embodiment of the present invention.

The composition layer according to the embodiment of the present invention is, for example, a layer consisting of only the solid content in the above-described composition according to the embodiment of the present invention. More specifically, the composition layer according to the embodiment of the present invention is the layer consisting of only the solid content, for example, in the negative type photosensitive resin composition described above, the chemical amplification type photosensitive resin composition, the thermoplastic resin composition, the water-soluble resin composition, the composition containing the specific material, and/or the coloration resin composition (the negative type photosensitive resin layer, the chemical amplification type photosensitive resin layer, the thermoplastic resin layer, the water-soluble resin layer, the refractive index adjusting layer, and/or the coloration resin layer).

It is noted that “consisting of only the solid content” referred to herein means that substantially, only the solid content is contained, and the solid content is preferably 95% to 100% by mass, more preferably, 99% to 100% by mass, and still more preferably 99.5% to 100% by mass, with respect to the total mass of the composition layer.

For example, in the negative type photosensitive resin composition described above, the chemical amplification type photosensitive resin composition, the thermoplastic resin composition, the water-soluble resin composition, the composition containing the specific material, and/or the coloration resin composition, the composition layer other than the present invention is a composition layer formed of the composition which is not allowed to contain the compound A. Such a composition layer is preferably a layer consisting of only the solid content in “the composition which is not allowed to contain the compound A” described above. In addition, examples of “the composition which is not allowed to contain the compound A” described above include a composition obtained by simply removing the compound A from the composition according to the embodiment of the present invention and a composition obtained by replacing the compound A in the composition according to the embodiment of the present invention with a surfactant which does not correspond to the compound A.

Hereinafter, the negative type photosensitive resin composition which is the composition according to the embodiment of the present invention and the composition which is not allowed to contain the compound A are distinguished from each other, and they are also referred to separately as the negative type photosensitive resin composition according to the embodiment of the present invention and the negative type photosensitive resin composition other than the present invention, respectively. The same applies to the compositions of other types.

In addition, the layer formed of the negative type photosensitive resin composition according to the embodiment of the present invention and the layer formed of the negative type photosensitive resin composition other than the present invention are distinguished from each other, and they are also referred to separately as the negative type photosensitive resin layer according to the embodiment of the present invention and the negative type photosensitive resin composition other than the present invention, respectively. The same applies to the composition layers of other types.

It is also preferable that the transfer film according to the embodiment of the present invention contains at least one layer of the negative type photosensitive resin layer (the negative type photosensitive resin layer according to the embodiment of the present invention or a negative type photosensitive resin layer other than the present invention) or the chemical amplification type photosensitive resin layer (the chemical amplification type photosensitive resin layer according to the embodiment of the present invention or a chemical amplification type photosensitive resin layer other than the present invention). The negative type photosensitive resin layer and the chemical amplification type photosensitive resin layer may be a coloration resin layer.

That is, at least one layer of the composition layers (the one or more composition layers) included in the transfer film according to the embodiment of the present invention is preferably a negative type photosensitive resin layer (the negative type photosensitive resin layer according to the embodiment of the present invention or a negative type photosensitive resin layer other than the present invention) or a chemical amplification type photosensitive resin layer (the chemical amplification type photosensitive resin layer according to the embodiment of the present invention or a chemical amplification type photosensitive resin layer other than the present invention).

[Temporary Support]

The transfer film according to the embodiment of the present invention has a temporary support.

The temporary support is a support that supports the composition layer or the laminate including the composition layer, and it is a peelable support.

The temporary support preferably has light transmittance from the viewpoint that exposure through a temporary support is possible in a case where the composition layer is subjected to pattern exposure. In addition, in this specification, “having light transmittance” means that the light transmittance at the wavelength used for pattern exposure is 50% or more.

From the viewpoint of improving exposure sensitivity, the temporary support preferably has a light transmittance of 60% or more and more preferably 70% or more at the wavelength (more preferably 365 nm) used for pattern exposure.

The light transmittance of the layer included in the transfer film is a rate of the intensity of the emitted light that has emitted and passed through a layer with respect to the intensity of the incident light in a case where the light is incident in a direction perpendicular to the main surface of the layer (the thickness direction), and it is measured by using MCPD Series manufactured by Otsuka Electronics Co., Ltd.

Examples of the material that constitutes the temporary support include a glass substrate, a resin film, and paper, and a resin film is preferable from the viewpoints of hardness, flexibility, and light transmittance.

Examples of the resin film include a polyethylene terephthalate (PET) film, a cellulose triacetate film, a polystyrene film, and a polycarbonate film. Among them, a PET film is preferable, and a biaxially stretched PET film is more preferable.

The thickness (the layer thickness) of the temporary support is not particularly limited, and it may be selected depending on the material from the viewpoints of the hardness as a support, the flexibility required for affixing to a substrate for forming a circuit wire, and the light transmittance required in the first exposure step.

The thickness of the temporary support is preferably 5 to 100 pm, more preferably 10 to 50 μm, still more preferably 10 to 20 μm, and particularly preferably 10 to 16 pm, from the viewpoints of ease of handling and general-purpose property.

In addition, it is preferable that the film to be used as the temporary support does not have deformation such as wrinkles, scratches, and defects.

From the viewpoint of pattern forming properties during pattern exposure through the temporary support and transparency of the temporary support, it is preferable that the number of fine particles, foreign substances, defects, and precipitates included in the temporary support is small. The number of fine particles having a diameter of 1 pm or more, foreign substances, and defects is preferably 50 pieces/10 mm² or less, more preferably 10 pieces/10 mm² or less, still more preferably 3 pieces/10 mm² or less, and particularly preferably 0 pieces/10 mm².

Preferred aspects of the temporary support are described in, for example, paragraph 0017 and paragraph 0018 of JP2014-085643A, paragraphs 0019 to 0026 of JP2016-27363A, paragraphs 0041 to 0057 of WO2012/081680A1, paragraphs 0029 to 0040 of WO2018/179370A1, and paragraph 0012 to paragraph 0032 of JP2019-101405A, the contents of these publications are incorporated in the present specification.

[Cover Film]

The transfer film preferably has a cover film that is in contact with a surface of the composition layer (the above-described one or more composition layers) that does not face the temporary support.

Hereinafter, in the present specification, a surface of the composition layer facing the temporary support is also referred to as a “first surface”, and a surface on a side opposite to the first surface is also referred to as a “second surface”.

Examples of the material that constitutes the cover film include a resin film and paper, where a resin film is preferable from the viewpoints of hardness and flexibility.

Examples of the resin film include a polyethylene film, a polypropylene film, a polyethylene terephthalate film, a cellulose triacetate film, a polystyrene film, and a polycarbonate film. Among them, a polyethylene film, a polypropylene film, or a polyethylene terephthalate film is preferable.

The thickness (the layer thickness) of the cover film is not particularly limited; however, it is preferably 5 to 100 pm and more preferably 10 to 50 μm.

In addition, the arithmetic average roughness Ra value of the surface of the cover film in contact with the composition layer (hereinafter, also simply referred to as “the surface of the cover film”) is preferably 0.3 pm or less, more preferably 0.1 pm or less, and still more preferably 0.05 pm or less since the resolution is more excellent. This is conceived to be because in a case where the Ra value on the surface of the cover film is in the above range, the uniformity of the layer thickness of the resin pattern to be formed is improved.

The lower limit of the Ra value of the surface of the cover film is not particularly limited; however, it is preferably 0.001 pm or more.

The Ra value of the surface of the cover film is measured by the following method.

Using a three-dimensional optical profiler (New View7300, manufactured by Zygo Corporation), the surface of the cover film is measured under the following conditions to obtain a surface profile of the optical film.

As the measurement and analysis software, Microscope Application of MetroPro ver. 8.3.2 is used. Next, the Surface Map screen is displayed with the above analysis software, and the histogram data is obtained in the Surface Map screen. From the obtained histogram data, the arithmetic average roughness is calculated, and the Ra value of the surface of the cover film is obtained.

In a case where the cover film is affixed to the transfer film, the cover film may be peeled from the transfer film to measure the Ra value of the surface on which the peeling has been carried out.

[Manufacturing Method for Transfer Film]

The manufacturing method for the transfer film according to the embodiment of the present invention is not particularly limited, and a known manufacturing method, for example, a known method of forming each layer can be used.

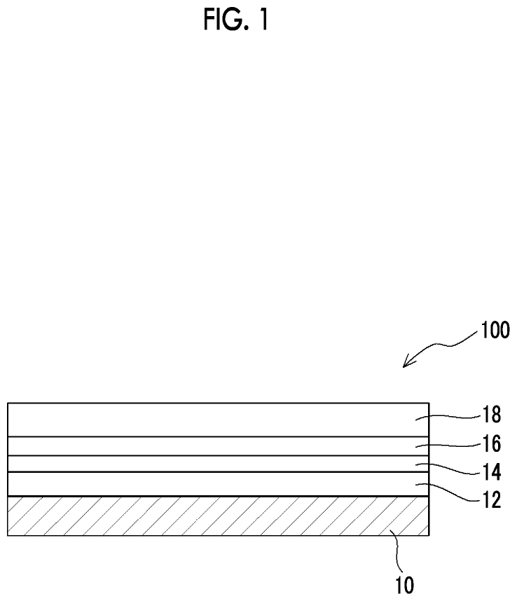

Hereinafter, a manufacturing method for a transfer film according to the embodiment of the present invention will be described with reference to FIG. 1. However, the transfer film according to the embodiment of the present invention is not limited to that having the configuration illustrated in FIG. 1.

FIG. 1 is a schematic view illustrating an example of a configuration of the transfer film according to the embodiment of the present invention. A transfer film 100 illustrated in FIG. 1 has a configuration in which a temporary support 10, a thermoplastic resin layer 12, a water-soluble resin layer (an interlayer) 14, a negative type photosensitive resin layer 16, and a cover film 18 are laminated in this order.

Examples of the manufacturing method for the transfer film 100 include a method including a step of applying the thermoplastic resin composition according to the embodiment of the present invention onto the surface of the temporary support 10 and then drying the coating film of the thermoplastic resin composition according to the embodiment of the present invention to form the thermoplastic resin layer 12, a step of applying the water-soluble resin composition according to the embodiment of the present invention onto the surface of the thermoplastic resin layer 12 and then drying the coating film of the water-soluble resin composition according to the embodiment of the present invention to form the water-soluble resin layer 14, and a step of applying the negative type photosensitive resin composition according to the embodiment of the present invention onto the surface of the water-soluble resin layer 14 and then drying the coating film of the negative type photosensitive resin composition according to the embodiment of the present invention to form the negative type photosensitive resin layer 16.

The cover film 18 is subjected to pressure bonding to the negative type photosensitive resin layer 16 of the laminate manufactured by the manufacturing method described above, whereby the transfer film 100 is manufactured.

It is preferable that the manufacturing method for a transfer film according to the embodiment of the present invention includes a step of providing a cover film 18 to be in contact with a second surface of a photosensitive resin layer 16, whereby a transfer film 100 including a temporary support 10, a thermoplastic resin layer 12, a water-soluble resin layer 14, a photosensitive resin layer 16, and a cover film 18 is manufactured.

After manufacturing the transfer film 100 according to the above-described manufacturing method, the transfer film 100 may be wound backward to produce and store the transfer film having a form of a roll. The transfer film having a roll form can be provided as it is in the affixing step to a substrate by the roll-to-roll method described later.

In the above-described manufacturing method, although the compositions of the present invention were used as the thermoplastic resin composition, the water-soluble resin composition, and the negative type photosensitive resin composition, it suffices that at least one of these is the composition according to the embodiment of the present invention, where one or two thereof may be compositions other than the present invention (a thermoplastic resin composition other than the present invention, a water-soluble resin composition other than the present invention, and/or a negative type photosensitive resin composition other than the present invention).

Similarly, in the transfer film 100, it suffices that at least one of the thermoplastic resin layer 12, the water-soluble resin layer (the interlayer) 14, or the negative type photosensitive resin layer 16 is the composition layer according to the embodiment of the present invention, where one or two thereof may be the composition layers other than the present invention.

The configurations of the transfer film are exemplified below.

In each of the following configurations, one or more layers (the cover film and the like) may be removed or a layer may be further added between any layers, as desired.

(1) “Temporary support/thermoplastic resin layer/water-soluble resin layer (interlayer)/negative type photosensitive resin layer/cover film”

(2) “Temporary support/chemical amplification type photosensitive resin layer/cover film”

(3) “Temporary support/negative type photosensitive resin layer/refractive index adjusting layer/cover film”

(4) “Temporary support/negative type photosensitive resin layer/cover film”

In the composition layers (layers other than the temporary support and the cover film) that constitute the transfer film having each of the above-described configurations, at least one layer is the composition layer according to the embodiment of the present invention.

In each of the above configurations, it is also preferable that the negative type photosensitive resin layer and/or the chemical amplification type photosensitive resin layer is a coloration resin layer.

[Manufacturing Method for Laminate and Manufacturing Method for Circuit Wire]

The present invention also relates to a manufacturing method for a laminate.

The manufacturing method for a laminate is not particularly limited as long as it is a manufacturing method for a laminate using the transfer film described above.

The manufacturing method for a laminate preferably includes an affixing step of bringing a substrate (preferably a substrate having conductivity) into contact with a surface (a surface of a composition layer) on a side opposite to a temporary support included in a transfer film and affixing the transfer film to the substrate (preferably the substrate having conductivity) to obtain a transfer film-attached substrate (hereinafter, also referred to as the “affixing step”), an exposure step of subjecting the composition layer to pattern exposure (hereinafter, also referred to as the “exposure step”), a development step of developing the exposed composition layer to form a resin pattern (hereinafter, also referred to the “development step”), and a peeling step of peeling the temporary support from the transfer film-attached substrate, between the affixing step and the exposure step or between the exposure step and the development step (hereinafter, also referred to as the “peeling step”).

It is noted that the composition layer that is subjected to pattern exposure may consist of one layer alone or may consist of two or more layers, where at least one layer constituting the composition layer is the composition layer according to the embodiment of the present invention.

In addition, in the above-described composition layer that is subjected to pattern exposure, it is preferable that the transfer film according to the embodiment of the present invention contains at least one layer of the negative type photosensitive resin layer (the negative type photosensitive resin layer according to the embodiment of the present invention or a negative type photosensitive resin layer other than the present invention) or the chemical amplification type photosensitive resin layer (the chemical amplification type photosensitive resin layer according to the embodiment of the present invention or a chemical amplification type photosensitive resin layer other than the present invention). The negative type photosensitive resin layer and the chemical amplification type photosensitive resin layer may be a coloration resin layer.

The manufacturing method for a circuit wire is not particularly limited as long as it is a manufacturing method for a circuit wire using the transfer film described above.

In a laminate in which a substrate, a conductive layer (a conductive layer included in the substrate), and a resin pattern manufactured by using the above-described transfer film are laminated in this order, the manufacturing method for a circuit wire is preferably a method including a step (hereinafter, also referred to as an “etching step”) of subjecting the conductive layer present in a region where the resin pattern is not disposed to an etching treatment.

That is, the manufacturing method for a circuit wire is preferably a method including an affixing step of bringing a substrate having a conductive layer into contact with a surface (a composition layer) on a side opposite to a temporary support included in a transfer film and affixing the transfer film to the substrate having the conductive layer to obtain a transfer film-attached substrate (hereinafter, also referred to as the “affixing step”), an exposure step of subjecting the composition layer to pattern exposure (hereinafter, also referred to as the “exposure step”), a development step of developing the exposed composition layer to form a resin pattern (hereinafter, also referred to the “development step”), a step of subjecting the conductive layer present in a region where the resin pattern is not disposed to an etching treatment (hereinafter, also referred to as the “etching step”), and a peeling step of peeling the temporary support from the transfer film-attached substrate, between the affixing step and the exposure step or between the exposure step and the development step (hereinafter, also referred to as the “peeling step”).

The same as described above applies to the preferred form of the composition layer that is subjected to pattern exposure.

Hereinafter, each step included in the manufacturing method for a laminate and the manufacturing method for a circuit wire will be described. However, unless otherwise specified, the content of the description for each step included in the manufacturing method for a laminate shall also apply to the manufacturing method for a circuit wire.

[Affixing Step]

The manufacturing method for a laminate preferably includes an affixing step.

In the affixing step, it is preferable that a substrate (a conductive layer in a case where a conductive layer is provided on the surface of the substrate) is brought into contact with the surface of the transfer film on a side opposite to the temporary support, and the transfer film is subjected to pressure bonding to the substrate. Since the above aspect improves the adhesiveness between the composition layer and the substrate, it can be suitably used as an etching resist in a case where a conductive layer is etched by using a resin pattern on which a pattern is formed after the exposure and the development.

In a case where the transfer film includes a cover film, the cover film may be removed from the surface of the transfer film and then affixed.

The method of subjecting the substrate to pressure bonding to the transfer film is not particularly limited, and a known transfer method or a laminating method can be used.

The affixing of the transfer film to the substrate is preferably carried out by superposing the substrate on a surface of the transfer film on a side opposite to the temporary support and then applying pressure using a means such as a roll and carrying out heating. For affixing, it is possible to use a known laminator such as a laminator, a vacuum laminator, or an auto-cut laminator capable of further improving productivity.

The manufacturing method for a laminate including the affixing step and the manufacturing method for a circuit wire are preferably carried out according to a roll-to-roll method.

The roll-to-roll method refers to a method that includes, in a case of using a substrate capable of being wound backward and wound forward as the substrate, a step (also referred to as a “forward winding step”) of winding forward the substrate or a structure body including the substrate before any one of the steps included in the manufacturing method for a laminate or the manufacturing method for a circuit wire and a step (also referred to as a “backward winding step”) of winding backward the substrate or the structure body including the substrate after any one of the above steps, and at least any one of the steps (preferably all steps or all steps other than the heating step) is carried out while transporting the substrate or the structure body including the substrate.

The forward winding method in the forward winding step and the backward winding method in the backward winding step are not particularly limited, and known methods may be used in the manufacturing method to which the roll-to-roll method is applied.

<Substrate>

As the substrate used for forming the resin pattern using the transfer film according to the embodiment of the present invention, a known substrate may be used; however, a substrate having a conductive layer is preferable, and it is more preferable to have a conductive layer on the surface of the substrate.

The substrate may have any layer other than the conductive layer, as necessary.

Examples of the base material that constitutes the substrate include glass, silicon, and a film.

The base material that constitutes the substrate is preferably transparent. In the present specification, “transparent” means that the transmittance of light having a wavelength of 400 to 700 nm is 80% or more.

In addition, the refractive index of the base material that constitutes the substrate is preferably 1.50 to 1.52.

Examples of the transparent glass base material include reinforced glass represented by Gorilla Glass manufactured by Corning Incorporated. Further, as the transparent glass base material, the materials used in JP2010-086684A, JP2010-152809A, and JP2010-257492A can be used.

In a case where a film base material is used as the base material, it is preferable to use a film base material having low optical distortion and/or high transparency. Examples of such a film base material include polyethylene terephthalate (PET), polyethylene naphthalate, polycarbonate, triacetyl cellulose, and a cycloolefin polymer.

The base material of the substrate is preferably a film base material in a case of being manufactured by a roll-to-roll method. Further, in a case where a circuit wire for a touch panel is manufactured by a roll-to-roll method, it is preferable that the base material is a sheet-shaped resin composition.

Examples of the conductive layer included in the substrate include a conductive layer that is used for a general circuit wire and a touch panel wire.

From the viewpoint of conductivity and thin wire forming properties, the conductive layer is preferably at least one layer selected from the group consisting of a metal layer, a conductive metal oxide layer, a graphene layer, a carbon nanotube layer, and a conductive polymer layer, more preferably a metal layer, and still more preferably a copper layer or a silver layer.

The substrate may have one conductive layer alone or may have two or more conductive layers. In a case of having two or more conductive layers, it is preferable to have conductive layers made of different materials.

Examples of the material of the conductive layer include a metal and a conductive metal oxide.

Examples of the metal include Al, Zn, Cu, Fe, Ni, Cr, Mo, Ag, and Au.

Examples of the conductive metal oxide include indium tin oxide (ITO), indium zinc oxide (IZO), and SiO₂.

In the present specification, “conductivity” means that the volume resistivity is less than 1×10⁶ Ωcm. The volume resistivity of the conductive metal oxide is preferably less than 1×10⁴ Ωcm.

In a case where a resin pattern is manufactured using a substrate having a plurality of conductive layers, it is preferable that at least one conductive layer among the plurality of conductive layers contains a conductive metal oxide.

The conductive layer is preferably an electrode pattern corresponding to a sensor of a visible part that is used in a capacitance type touch panel or a wire of a peripheral lead-out part.

[Exposure Step]

The manufacturing method for a laminate preferably includes, after the affixing step, a step (an exposure step) of subjecting the composition layer to pattern exposure.

The detailed arrangement and the specific size of the pattern in the pattern exposure are not particularly limited. At least a part of the pattern (preferably, a portion of the electrode pattern and/or lead-out wire of the touch panel) preferably contains a thin wire having a width of 20 pm or less and more preferably contains a thin wire having a width of 10 pm or less so that the display quality of the display device (for example, a touch panel) including an input device having a circuit wire manufactured according to the manufacturing method for a circuit wire improved and the area occupied by the lead-out wire is reduced.

The light source that is used for exposure can be appropriately selected and used as long as it is a light source that emits light having a wavelength (for example, 365 nm or 405 nm) with which the photosensitive resin layer can be exposed. Specific examples thereof include an ultra-high pressure mercury lamp, a high pressure mercury lamp, a metal halide lamp, and a light emitting diode (LED).

The exposure amount is preferably 5 to 200 mJ/cm² and more preferably 10 to 100 mJ/cm².

[Peeling Step]

The peeling step is a step of peeling the temporary support from the photosensitive composition layer-attached substrate between the affixing step and the exposure step, or between the exposure step and the developing step development step later.

The peeling method is not particularly limited, and a mechanism similar to the cover film peeling mechanism described in paragraphs [0161] and [0162] of JP2010-072589A can be used.

As a result, in the exposure step, the pattern exposure may be carried out after the temporary support is peeled off from the composition layer, or the pattern exposure may be carried out through the temporary support before the temporary support is peeled off, and then the temporary support may be peeled off. In a case where the temporary support is peeled off before exposure, the mask may be exposed in a state of being brought into contact with the composition layer or may be exposed in a state of being in close proximity without being brought into contact with the composition layer. In a case where the temporary support is exposed without peeling, the mask may be exposed in a state of being brought into contact with the temporary support or may be exposed in a state of being in close proximity without being brought into contact with the temporary support. In order to prevent mask contamination due to contact between the composition layer and the mask and to avoid the influence of foreign substances adhered to the mask on the exposure, it is preferable to carry out pattern exposure without peeling off the temporary support. The exposure method can be carried out by appropriately selecting and using a contact exposure method in a case of contact exposure, and in a case of a non-contact exposure method, a proximity exposure method, a lens-based and mirror-based projection exposure method, and a direct exposure method using an exposure laser or the like. In a case of the lens-based or mirror-based projection exposure, an exposure machine having a proper numerical aperture (NA) of a lens in response to the required resolving power and the focal depth can be used. In a case of the direct exposure method, drawing may be carried out directly on the photosensitive layer, or reduced projection exposure may be carried out on the photosensitive layer through a lens. Further, the exposure may be carried out not only in the atmospheric air but also under reduced pressure or vacuum, or the exposure may be carried out by interposing a liquid such as water between the light source and the photosensitive layer.

[Development Step]

The manufacturing method for a laminate preferably includes, after the exposure step, a step (a development step) of developing the exposed composition layer to form a resin pattern.

In a case where the composition layer includes a negative type photosensitive resin layer (the negative type photosensitive resin layer according to the embodiment of the present invention or a negative type photosensitive resin layer other than the present invention), the composition layer undergoes a curing reaction according to the exposed pattern to form a cured film (a patterned cured film), and only the non-exposed portion of the composition layer can be removed with a developer (an alkali developer or the like).

In a case where the composition layer includes a chemical amplification type photosensitive resin layer (the chemical amplification type photosensitive resin layer according to the embodiment of the present invention or a chemical amplification type photosensitive resin layer other than the present invention), the solubility of the chemical amplification type photosensitive resin layer of the exposure changes according to the exposed pattern. Specifically, since the polarity and the alkali solubility increase in the exposed portion, it is possible to carry out the removal of only the exposed portion of the composition layer (the positive type development) by applying the alkali developer, or it is possible to carry out the removal of only the non-exposed portion of the composition layer (the negative type development) by applying an organic developer.

In a case where the transfer film has, together with the negative type photosensitive resin layer or the chemical amplification type photosensitive resin layer, a composition layer different from these, only a portion similar to the portion of the different composition layer, which is removed in the negative type photosensitive resin layer or chemical amplification type photosensitive resin layer, may be removed, or an entire portion thereof including a portion other than the portion removed in the negative type photosensitive resin layer or chemical amplification type photosensitive resin layer may be removed.

For example, in a case where the transfer film has the thermoplastic resin layer and/or the water-soluble resin layer together with the negative type photosensitive resin layer, only the thermoplastic resin layer and/or the water-soluble resin layer of the non-exposed portion may be removed in the development step together with the negative type photosensitive resin layer of the non-exposed portion. In addition, in the development step, the thermoplastic resin layer and/or the water-soluble resin layer in both regions of the exposed portion and the non-exposed portion may be removed in a form of being dissolved or dispersed in the developer.

In the resin pattern obtained after the development, a part or the whole thereof may be the composition layer according to the embodiment of the present invention or a layer that is obtained by subjecting the composition according to the embodiment of the present invention to a change such as a curing reaction. For example, in a case where the composition layer of the transfer film includes the negative type photosensitive resin layer according to the embodiment of the present invention, a part or the whole of the resin pattern is a material obtained by subjecting the negative type photosensitive resin layer according to the embodiment of the present invention to a curing reaction.

In addition, in the resin pattern obtained after the development, the composition layer according to the embodiment of the present invention or a layer that is obtained by subjecting the composition according to the embodiment of the present invention to a change such as a curing reaction may not be included. That is, the resin pattern obtained after the development may consist of only a composition layer other than the present invention and/or a layer that is obtained by subjecting the composition other than the present invention to a change such as a curing reaction.

Development of the exposed composition layer in the development step can be carried out using a developer.

The developer may be appropriately selected depending on the properties of the composition layer included in the transfer film and the type of development, and examples thereof include an alkali developer and an organic developer.

As the alkali developer, it is possible to use, for example, a known developer such as the developer described in JP1993-072724A (JP-H5-072724A).

The alkali developer is preferably an alkaline aqueous solution-based developer containing a compound having pKa=7 to 13 at a concentration of 0.05 to 5 mol/L (liter). The alkali developer may contain a water-soluble organic solvent and/or a surfactant. The alkali developer is also preferably the developer described in paragraph 0194 of WO2015/093271A. The content of the organic solvent in the alkali developer is preferably 0% by mass or more and less than 90% by mass with respect to the total mass of the developer.

As the organic developer, it is possible to use a developer containing one or more kinds of solvents among polar solvents of a ketone-based solvent, an ester-based solvent, an alcohol-based solvent, an amide-based solvent, and an ether-based solvent, and hydrocarbon-based solvents. The content of the organic solvent in the organic developer is preferably 90% to 100% by mass and more preferably 95% to 100% by mass with respect to the total mass of the developer.

The development method is not particularly limited, and it may be any of puddle development, shower development, shower, and spin development, and dip development. The shower development is a development treatment of removing the non-exposed portion by spraying a developer onto the photosensitive resin layer after exposure with a shower.

After the development step, it is preferable to spray a cleaning agent with a shower to remove the development residue while rubbing it with a brush.

The liquid temperature of the developer is not particularly limited; however, it is preferably 20° C. to 40° C.

[Etching Step]

In a laminate in which a substrate, a conductive layer (a conductive layer included in the substrate), and a resin pattern (more preferably, a resin pattern manufactured according to the manufacturing method including the affixing step, the exposure step, and the development step) are laminated in this order, the manufacturing method for a circuit wire preferably contains a step (an “etching step”) of subjecting the conductive layer present in a region where the resin pattern is not disposed to an etching treatment.

In the etching step, the resin pattern formed from the photosensitive resin layer is used as an etching resist to carry out an etching treatment of the conductive layer.

As the method of etching treatment, a known method can be applied, and examples thereof include the methods described in paragraphs 0209 to 0210 of JP2017-120435A and paragraphs 0048 to 0054 of JP2010-152155A, a wet etching method in which immersion in an etchant is carried out, and a dry etching method such as plasma etching.

As the etchant that is used for wet etching, an acidic or alkaline etchant may be appropriately selected according to the etching target.

Examples of the acidic etchant include an aqueous solution of an acidic component alone selected from hydrochloric acid, sulfuric acid, nitric acid, acetic acid, hydrofluoric acid, oxalic acid, and phosphoric acid, and a mixed aqueous solution of an acidic component with a salt selected from iron (III) chloride, ammonium fluoride, or potassium permanganate. The acidic component may be a component in which a plurality of acidic components are combined.

Examples of the alkaline etchant include an aqueous solution of an alkaline component alone selected from sodium hydroxide, potassium hydroxide, ammonia, an organic amine, and a salt of an organic amine (tetramethylammonium hydroxide or the like), and a mixed aqueous solution of an alkaline component with a salt (potassium permanganate or the like). The alkaline component may be a component in which a plurality of alkaline components are combined.

[Removal Step]

In the manufacturing method for a circuit wire, it is preferable to carry out a step (a removal step) of removing the remaining resin pattern.

The removal step is not particularly limited and can be carried out as necessary; however, it is preferably carried out after the etching step.

The method of removing the remaining resin pattern is not particularly limited; however, examples thereof include a method of carrying out removal by a chemical treatment, and a method of carrying out removal with a removing liquid is preferable.

Examples of the method of removing the photosensitive resin layer include a method in which a substrate having the remaining resin pattern is immersed in a removing liquid under stirring, having a liquid temperature of preferably 30° C. to 80° C. and more preferably 50° C. to 80° C. for 1 to 30 minutes.

Examples of the removing liquid include a removing liquid in which an inorganic alkaline component or an organic alkaline component is dissolved in water, dimethyl sulfoxide, N-methylpyrrolidone, or a mixed solution thereof. Examples of the inorganic alkaline component include sodium hydroxide and potassium hydroxide. Examples of the organic alkaline component include a primary amine compound, a secondary amine compound, a tertiary amine compound, and a quaternary ammonium salt compound.

Further, a removing liquid may be used and then removed by a known method such as a spray method, a shower method, or a puddle method.

[Other Steps]

The manufacturing method for a circuit wire may include any steps (other steps) other than the above-described steps. Examples thereof include the following steps, which are not limited to these steps.

Further, examples of the exposure step, the development step, and the other steps, which are applicable to the manufacturing method for a circuit wire, include the steps described in paragraphs 0035 to 0051 of JP2006-023696A.

<Cover Film Peeling Step>

In a case where the transfer film includes a cover film, the manufacturing method for a laminate preferably includes a step of peeling the cover film from the transfer film. The method of peeling the cover film is not limited, and a known method can be applied.

<Step of Reducing Visible Light Reflectivity>

The manufacturing method for a circuit wire may include a step of carrying out a treatment of reducing the visible light reflectivity of a part or all of a plurality of conductive layers included in the base material.

Examples of the treatment of reducing the visible light reflectivity include an oxidation treatment. In a case where the base material has a conductive layer containing copper, the visible light reflectivity of the conductive layer can be reduced by subjecting copper to the oxidation treatment to obtain copper oxide and then blackening the conductive layer.

The treatment of reducing the visible light reflectivity is described in paragraphs 0017 to 0025 of JP2014-150118A and paragraph 0041, paragraph 0042, paragraph 0048, and paragraph 0058 of JP2013-206315A, and the contents described in these publications are incorporated in the present specification.

<Step of Forming Insulating Film and Step of Forming New Conductive Layer on Surface of Insulating Film>

The manufacturing method for a circuit wire preferably includes a step of forming an insulating film on the surface of the circuit wire and a step of forming a new conductive layer on the surface of the insulating film.

These steps make it possible to form a second electrode pattern insulated from the first electrode pattern.

The step of forming an insulating film is not particularly limited, and examples thereof include a known method of forming a permanent film. Further, an insulating film having a desired pattern may be formed by photolithography using a photosensitive material having an insulating property.

The step of forming a new conductive layer on the insulating film is not particularly limited, and a new conductive layer having a desired pattern may be formed by, for example, photolithography using a photosensitive material having conductivity.

In the manufacturing method for a circuit wire, it is also preferable that a substrate having a plurality of conductive layers on both surfaces of the base material is used, and a conductive pattern is formed sequentially or simultaneously on the conductive layers formed on both surfaces of the base material. With such a configuration, it is possible to form a circuit wire for a touch panel in which the first conductive pattern is formed on one surface of the base material and the second conductive pattern is formed on the other surface thereof. It is also preferable to form a circuit wire for a touch panel, having such a configuration, from both surfaces of the base material in a roll-to-roll manner.

[Use Application of Circuit Wire]

The circuit wire manufactured by the manufacturing method for a circuit wire can be applied to various devices. Examples of the device including the circuit wire manufactured by the above-described manufacturing method include an input device, where a touch panel is preferable, and a capacitance type touch panel is more preferable. In addition, the input device can be applied to display devices such as an organic EL display device and a liquid crystal display device.

[Manufacturing Method for Electronic Device]

The present invention also relates to a manufacturing method for an electronic device.

The manufacturing method for an electronic device is preferably a manufacturing method for an electronic device using the transfer film described above.

Among the above, the manufacturing method for an electronic device preferably includes the above-described manufacturing method for a laminate.

Examples of the electronic device include an input device, where a touch panel is preferable. Further, the input device can be applied to display devices such as an organic electroluminescence display device and a liquid crystal display device.

In a laminate in which a substrate, a conductive layer (a conductive layer included in the substrate), and a resin pattern manufactured by using the above-described transfer film are laminated in this order, the manufacturing method for a touch panel is also preferably a method including a step (hereinafter, also referred to as an “etching step”) of subjecting the conductive layer present in a region where the resin pattern is not disposed to an etching treatment to form a wire for a touch panel, and it is more preferably a method using a resin pattern that is manufactured by a manufacturing method including the affixing step, the exposure step, and the development step.

The specific aspect of each step in the manufacturing method for a touch panel including a step of forming a wire for a touch panel and the embodiment associated with the order for carrying out respective steps are as described in the above-described “manufacturing method for a circuit wire”, and the same applies to the preferred aspect thereof.

In addition, the manufacturing method for a touch panel including a step of forming a wire for a touch panel may include any steps (other steps) other than those described above.

As the method for forming a wire for a touch panel, the method described in FIG. 1 of WO2016/190405A can also be referred to.

A touch panel having at least a wire for a touch panel is manufactured by the above-described manufacturing method for a touch panel. The touch panel preferably has a transparent substrate, electrodes, and an insulating layer or protective layer.

Examples of the detection method for the touch panel include known methods such as a resistive membrane method, a capacitance method, an ultrasonic method, an electromagnetic induction method, and an optical method. Among the above, a capacitance method is preferable.

Examples of the touch panel include a so-called in-cell type (for example, those shown in FIG. 5, FIG. 6, FIG. 7, and FIG. 8 of JP2012-517051A), a so-called on-cell type (for example, one described in FIG. 19 of JP2013-168125A and those described in FIG. 1 and FIG. 5 of JP2012-89102A), an one glass solution (OGS) type, a touch-on-lens (TOL) type (for example, one described in FIG. 2 of JP2013-54727A), various out-cell types (so-called GG, G1-G2, GFF, GF2, GF1, GiF, and the like), and other configurations (for example, those described in FIG. 6 of JP2013-164871A).

Examples of the touch panel include those described in paragraph 0229 of JP2017-120345A.

In the manufacturing method for an electronic device using a transfer film, it is also preferable that an electronic device to be manufactured includes a resin pattern as a cured film (in particular, in a case where the transfer film includes a negative type photosensitive composition layer).

Such a cured film having a resin pattern can be used as a protective film (a permanent film) that covers a part or the whole of an electrode or the like included in an electronic device (a touch panel or the like). In a case of disposing the cured film of the resin pattern on the electrode or the like as a protective film (a permanent film), it is possible to prevent problems such as metal corrosion, an increase in the electrical resistance between the electrode and the driving circuit, and disconnection.

### EXAMPLES

Hereinbelow, the present invention will be described in more detail with reference to Examples. The materials, the using amounts of materials, the proportions, the treatment details, the treatment procedure, and the like shown in Examples below may be appropriately modified as long as the modifications do not depart from the spirit of the present invention. Accordingly, the scope of the present invention shall not be restrictively interpreted by Examples shown below.

In the following Examples, unless otherwise specified, “parts” and “%” mean “parts by mass” and “% by mass”, respectively.

[[Test of Composition]]

[Synthesis of compound A]

[Synthesis of monomer]

### Synthesis Example a1

2-hydroxyethyl acrylate (209.0 g, 1.8 mol), triethylamine (218.6 g, 2.16 mol), and acetonitrile (1000 g) were placed in a three-neck flask (3 L) equipped with a dropping funnel to prepare a solution. A hexafluoropropene trimer (973.0 g, 2.16 mol) was placed in the dropping funnel and gradually added dropwise with stirring to the solution in the inside of the flask over 60 minutes. After completion of the dropwise addition, the solution was further stirred for 3 hours at room temperature.

1N hydrochloric acid (2,200 g) was added to the reaction mixture (the above solution) to terminate the reaction. Next, the reaction mixture was transferred into a 5 L beaker, and then a washing treatment using 1 L of water was carried out three times. The solution after the washing treatment was dehydrated under reduced pressure to obtain 904.0 g of a compound represented by Formula (a-1) (also referred to as a “fluorinated acrylate (a-1)”).

In Formula (a-1), there are both a case where Rfₐ is a group represented by Formula (a1) and a case where Rfₐ is a group represented by Formula (a2).

That is, the fluorinated acrylate (a-1) is a mixture of a compound represented by Formula (a-1) in which Rfₐ is a group represented by Formula (a1) and a compound represented by Formula (a-1) in which Rfₐ is a group represented by Formula (a2).

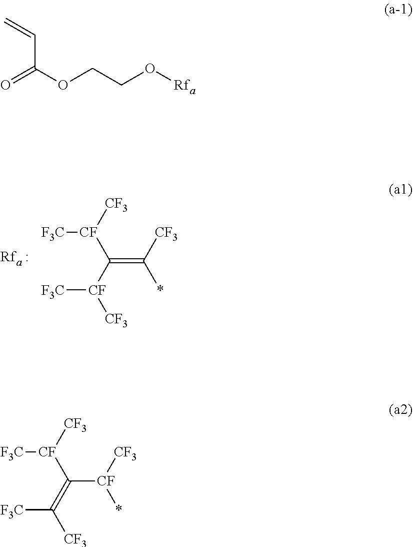

### Synthesis Example b1

2-(acryloyloxy)ethylisocyanate (69.72 g, 0.6 mol), Neostan U-600 (manufactured by Nitto Kasei Co., Ltd.) (0.957 g), and ethyl acetate (100 g) were mixed and stirred in a three-neck flask (1 L) equipped with a dropping funnel, and the internal temperature was adjusted to 0° C. to 5° C. CHEMINOX PO-3-OH (manufactured by UNIMATEC Co., Ltd.) (303.72 g, 0.63 mol) was placed in a dropping funnel and gradually added dropwise with stirring to the solution in the inside of the flask over 60 minutes. After completion of the dropwise addition, the solution was further stirred for 5 hours at room temperature. Methanol (8.00 g) was added to the above solution, and then the solution was further stirred for 1 hour. The reaction solution (the above solution) was filtered through Celite, and methoxyhydroquinone (144.6 mg) was added to the above reaction solution (the filtrate) after filtration. The solvent in the reaction solution was distilled off under reduced pressure to obtain 330.2 g of a compound represented by Formula (b-1) (a fluorinated acrylate (b-1)).

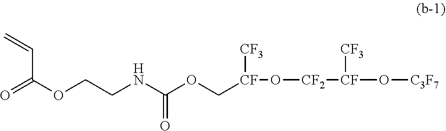

The raw material used in Synthesis Example b1 was changed to obtain a fluorinated acrylate (b-2).

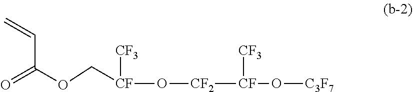

[Synthesis of Fluorine-Containing Polymer (Specific Structure (a) or (b))]

### Synthesis Example 1

Cyclohexanone (25.0 g) was charged into a three-neck flask having a capacity of 300 ml and equipped with a stirrer, a thermometer, a reflux condenser, and a nitrogen gas introduction pipe, and the temperature was raised to 80° C. Next, to the flask, a mixed solution consisting of the fluorinated acrylate (a-1) (20.00 g, 36.6 mmol), 60.5 g (111.8 mmol) of Blemmer AE-400 (polyethylene glycol-monoacrylate (n≈10), manufactured by NOF CORPORATION), cyclohexanone (25.0 g), and “V-601” (manufactured by Fujifilm Wako Pure Chemical Corporation) (0.342 g) were added dropwise at a constant rate so that the dropwise addition was completed in 180 minutes. After the dropwise addition was completed, stirring was further continued for 1 hour, and a solution consisting of “V-601” (0.342 g) and cyclohexanone (1.00 g) was added to the reaction solution in the inside of the flask. Immediately after the addition, the temperature of the reaction solution was raised to 93° C., and stirring was further continued for 2 hours to obtain 130 g of a cyclohexanone solution containing a fluorine-containing copolymer (Aa-1). The weight-average molecular weight (Mw) of the fluorine-containing copolymer (Aa-1) was 20,000.

### Synthesis Examples 2 to 6

Fluorine-containing polymers (Aa-2) to (Aa-4), (Bb-1), and (Bb-2) according to the embodiment of the present invention were obtained in the same manner except that the monomer and the compositional ratio used in Synthesis Example 1 were changed as shown in Table 1.

[Synthesis of Fluorine-Containing Polymer (Specific Structure (c))]

### Synthesis Example 7

Cyclohexanone (25.0 g) was charged into a three-neck flask of 300 ml and equipped with a stirrer, a thermometer, a reflux condenser, and a nitrogen gas introduction pipe, and the temperature was raised to 80° C. Next, to the flask, a mixed solution consisting of dimethylaminopropylacrylamide (20.00 g, 128.0 mmol), Blemmer AE-400 (polyethylene glycol-monoacrylate (n≈10), manufactured by NOF CORPORATION) (64.6 g, 126.97 mmol), and “V-601” (manufactured by Fujifilm Wako Pure Chemical Corporation) (0.587 g, 2.5 mmol) were added dropwise at a constant rate so that the dropwise addition was completed in 180 minutes. After the dropwise addition was completed, stirring was further continued for 1 hour, and a solution consisting of “V-601” (0.735 g) and cyclohexanone (1.00 g) was added to the reaction solution in the inside of the flask. Immediately after the addition, the temperature of the reaction solution was raised to 93° C., and the reaction solution was further stirred for 2 hours. Then, the temperature of the reaction solution was lowered to 40° C., a mixed solution of perfluoroheptanoic acid (46.60 g, 128.0 mmol) and cyclohexanone (108 g) was added to the reaction solution, and stirring was further carried out for 2 hours to obtain 100.8 g of a cyclohexanone solution of a fluorine-containing polymer (Cc-1). The weight-average molecular weight (Mw) of the fluorine-containing polymer (Cc-1) was 26,000.

The fluorine-containing polymers synthesized in Synthesis Examples 1 to 7 are shown. It is noted that the subscript of the constitutional unit in the structural formula indicates a mass ratio (in terms of % by mass) with respect to the total mass of the polymer. It is noted that regarding the fluorine-containing polymers (Aa-1) to (Aa-4), the constitutional unit shown at the left end is a constitutional unit based on the fluorinated acrylate (a-1), and regarding Rfₐ in the structural formula, there are both a case where Rfₐ is a group represented by Formula (a1) and a case where Rfₐ is a group represented by Formula (a2).

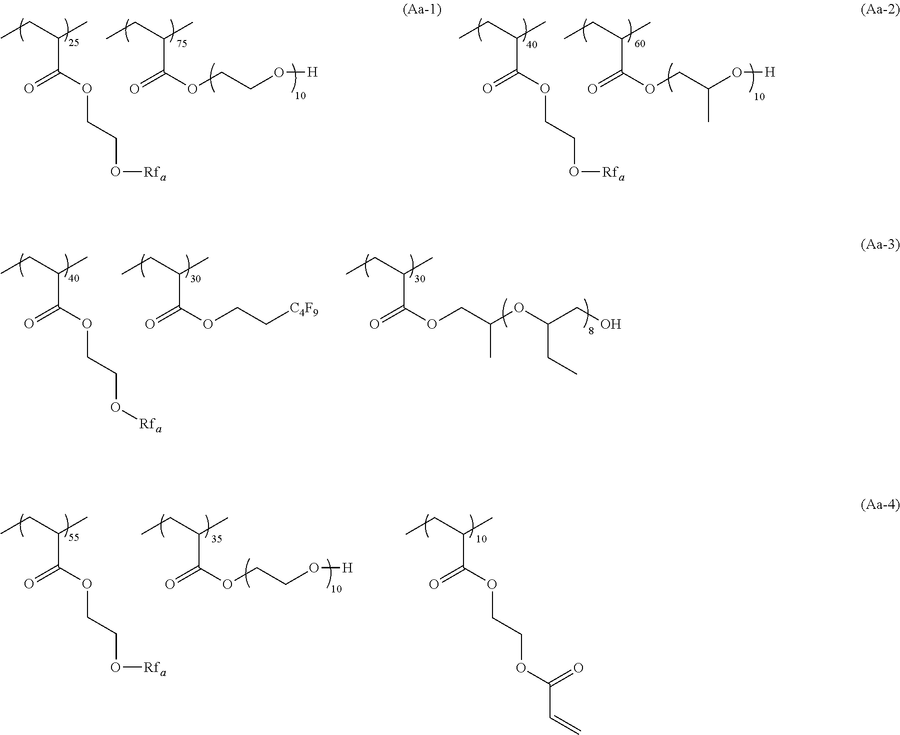

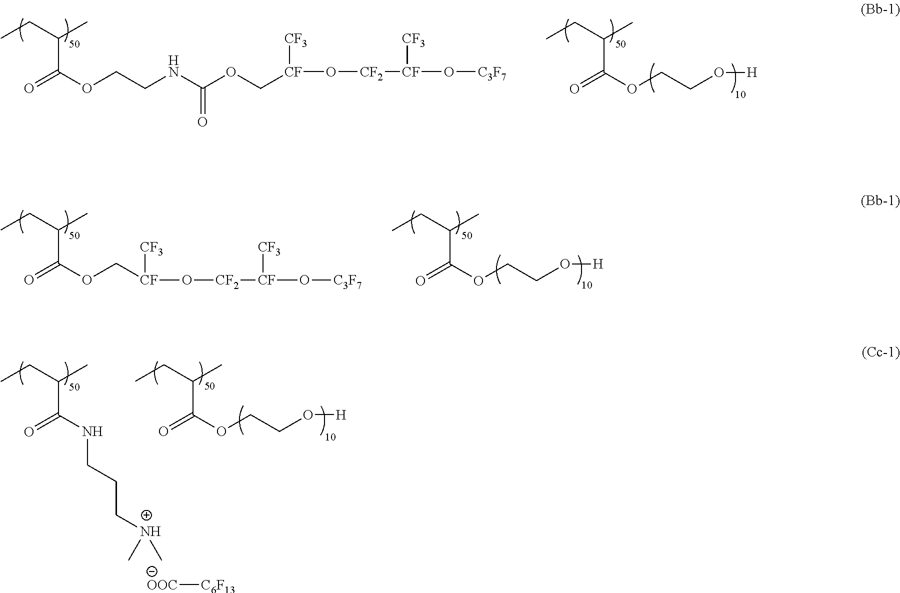

The weight-average molecular weight (Mw), the number-average molecular weight (Mn), and the dispersivity (Mw/Mn) of each fluorine-containing polymer were as follows.

| Fluorine-containing polymer | Mw | Mn | Mw/Mn |
|---|---|---|---|
| Aa-1 | 20,000 | 9,100 | 2.20 |
| Aa-2 | 24,000 | 11,000 | 2.18 |
| Aa-3 | 26,000 | 12,100 | 2.15 |
| Aa-4 | 18,000 | 7,400 | 2.43 |
| Bb-1 | 21,500 | 10,000 | 2.14 |
| Bb-2 | 20,100 | 9,300 | 2.16 |
| Cc-1 | 26,000 | 12,700 | 2.05 |

[Synthesis of Fluorinated Compound]

### Synthesis Example a4

Tetraethylene glycol monomethyl ether (374.8 g, 1.8 mol), triethylamine (218.6 g, 2.16 mol), and acetonitrile (1,000 g) were placed in a three-neck flask (3 L) equipped with a dropping funnel. A hexafluoropropene trimer (973.0 g, 2.16 mol) was placed in the dropping funnel and, with stirring, gradually added dropwise over 60 minutes to the solution in the inside of the flask. After completion of the dropwise addition, the solution was further stirred at room temperature for 3 hours.

1N hydrochloric acid (2,200 g) was added to the reaction mixture (the above solution) to terminate the reaction. Next, a desalting treatment was carried out, and the reaction mixture after the treatment was subjected to desolvation under reduced pressure to obtain 1,315.0 g of a compound represented by Formula (a-4) (a fluorinated compound (a-4)). The molecular weight of the fluorinated compound (a-4) is 594.3.

It is noted that in Formula (a-4), there are both a case where Rfₐ is the group represented by Formula (a1) described above and a case where Rfₐ is the group represented by Formula (a2) described above.

That is, the fluorinated compound (a-4) is a mixture of a compound represented by Formula (a-4) in which Rfₐ is a group represented by Formula (a1) and a compound represented by Formula (a-4) in which Rfₐ is a group represented by Formula (a2).

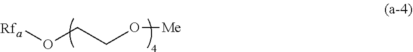

### Examples 1 to 8 and Comparative Example 1 (Test in Aspect in which Composition is Negative Type Photosensitive Resin Composition)

[Manufacturing of Resin]

<Abbreviation for Compound>

In the following synthesis examples, the following abbreviations respectively represent the following compounds.

St: Styrene (manufactured by FUJIFILM Wako Pure Chemical Corporation)

MAA: Methacrylic acid (manufactured by Fujifilm Wako Pure Chemical Corporation)

MMA: Methyl methacrylate (manufactured by FUJIFILM Wako Pure Chemical Corporation)

BzMA: Benzyl methacrylate (manufactured by Fujifilm Wako Pure Chemical Corporation)

AA: Acrylic acid (manufactured by Tokyo Chemical Industry Co., Ltd.)

PGMEA: Propylene glycol monomethyl ether acetate (manufactured by Showa Denko K.K.)

MEK: Methyl ethyl ketone (manufactured by SANKYO CHEMICAL Co., Ltd.)

V-601: Dimethyl-2,2′-azobis(2-methylpropionate) (manufactured by FUJIFILM Wako Pure Chemical Corporation)

<Synthesis of Resin A-1>

PGMEA (116.5 parts) was placed in a three-neck flask, and the temperature was raised to 90° C. in a nitrogen atmosphere. A mixed solution of St (52.0 parts), MMA (19.0 parts), MAA (29.0 parts), V-601 (4.0 parts), and PGMEA (116.5 parts) was added dropwise over 2 hours to the solution in the inside of the flask maintained at 90° C.±2° C. After completion of the dropwise addition, the solution in the flask was stirred at 90° C.±2° C. for 2 hours to obtain a solution containing the resin A-1 (solid content concentration: 30.0% by mass).

<Synthesis of Resins A-2 and A-3>

The kind of the monomer to be used and the like are changed as shown below, and other conditions are obtained by the same method as that of the resin A-1 to obtain a solution containing the resin A-2 and a solution containing the resin A-3. The solid content concentrations of the solution containing the resin A-2 and the solution containing the resin A-3 were each 30% by mass.

Hereinafter, the kind and mass ratio of each monomer used for synthesizing each resin, and the weight-average molecular weight of each resin are shown.

It is noted that all of the resins A-1 to A-3 correspond to the alkali-soluble resin.

| | A-1 | A-2 | A-3 |
|---|---|---|---|
| St | 52 | — | 32 |
| BzMA | — | 81 | — |
| MAA | 29 | 19 | 28 |
| MMA | 19 | — | 40 |
| Mw | 60,000 | 40,000 | 40,000 |

[Preparation of Photosensitive Resin Compositions 1 to 9]

According to the prescriptions shown in Table 1 shown in the latter part, components were stirred and mixed to prepare photosensitive resin compositions 1 to 9. It is noted that the unit of the amount of each component is part by mass.

The formulation of each of the photosensitive resin compositions 1 to 9 is shown below.

In the table, the numerical value for each component in each photosensitive resin composition indicates the adding amount (in terms of part by mass) of each component.

It is noted that the resin was added to each photosensitive resin composition in a form of a solution containing the resin. In the table, the numerical value indicating the adding amount of the resin is the mass of the added “solution containing the resin”.

Hereinafter, the same shall apply to components which are added to the composition in a form of being contained in the mixed solution, unless otherwise specified.

In the table, the column “Average film thickness of photosensitive resin layer (pm)” indicates the average film thickness of the photosensitive resin layer formed in a case where a test has been carried out using each photosensitive resin composition. Details of the test will be described later.

TABLE 1

| | | | | | | | | | | Comparative |
|---|---|---|---|---|---|---|---|---|---|---|
| | | Example 1 | Example 2 | Example 3 | Example 4 | Example 5 | Example 6 | Example 7 | Example 8 | Example 1 |
| | | Photo- | Photo- | Photo- | Photo- | Photo- | Photo- | Photo- | Photo- | Photo- |
| | | sensitive | sensitive | sensitive | sensitive | sensitive | sensitive | sensitive | sensitive | sensitive |
| | | resin | resin | resin | resin | resin | resin | resin | resin | resin |
| | | compo- | compo- | compo- | compo- | compo- | compo- | compo- | compo- | compo- |
| | | sition 1 | sition 2 | sition 3 | sition 4 | sition 5 | sition 6 | sition 7 | sition 8 | sition 9 |
| Resin | A-1 | | | | | | 62.20 | | | |
| | A-2 | 50.00 | 50.00 | 50.00 | 50.00 | 50.00 | | | 51.00 | 50.00 |
| | A-3 | | | | | | | 59.20 | | |
| Polymerizable | BPE-500 | 36.20 | 36.20 | 36.20 | 36.20 | 36.20 | | 27.00 | 15.00 | 36.20 |
| compound | BPE-200 | | | | | | 20.00 | | | |
| | Dimethacrylate of | | | | | | | | 10.00 | |
| | polyoxyalkylene- | | | | | | | | | |
| | modified bisphenol | | | | | | | | | |
| | A in which fifteen | | | | | | | | | |
| | ethylene oxides in | | | | | | | | | |
| | average and two | | | | | | | | | |
| | propylene oxides in | | | | | | | | | |
| | average are added to | | | | | | | | | |
| | both ends of bisphenol | | | | | | | | | |
| | A, respectively | | | | | | | | | |
| | M-270 | 5.00 | 5.00 | 5.00 | 5.00 | 5.00 | | | | 5.00 |
| | A-TMPT | | | | | | 6.00 | | 5.00 | |
| | SR-454 | | | | | | 9.00 | | 5.00 | |
| | SR-502 | | | | | | | 4.00 | | |
| | A-9300-CLI | | | | | | | 7.80 | 9.77 | |
| Photopoly- | B-CIM | 7.00 | 7.00 | 7.00 | 7.00 | 7.00 | 1.90 | 1.10 | 3.00 | 7.00 |
| merization | SB-PI701 | 0.60 | 0.60 | 0.60 | 0.60 | 0.60 | 0.30 | 0.10 | 0.30 | 0.50 |
| initiator | | | | | | | | | | |
| Coloring | Leucocrystal violet | 0.40 | 0.40 | 0.40 | 0.40 | 0.40 | 0.40 | 0.66 | 0.60 | 0.40 |
| agent | Brilliant green | | | | | | 0.05 | | 0.02 | |
| Additive | N-phenylglycine | 0.20 | 0.20 | 0.20 | 0.20 | 0.20 | | | | 0.20 |
| | CBT-1 | 0.10 | 0.10 | 0.10 | 0.10 | 0.10 | 0.03 | 0.03 | | 0.10 |
| | 1:1 mixture (in | | | | | | | | 0.10 | |
| | terms of mass ratio) | | | | | | | | | |
| | of 1-(2-di-n- | | | | | | | | | |
| | butylaminomethyl)-5- | | | | | | | | | |
| | carboxybenzotriazole | | | | | | | | | |
| | and 1-(2-di-n- | | | | | | | | | |
| | butylaminomethyl)-6- | | | | | | | | | |
| | carboxybenzotriazole | | | | | | | | | |
| | TDP-G | 0.30 | 0.30 | 0.30 | 0.30 | 0.30 | | | | 0.30 |
| | Irganox 245 | | | | | | 0.10 | 0.10 | 0.20 | |
| | N-nitrosophenyl | | | | | | 0.02 | 0.01 | 0.01 | |
| | hydroxylamine | | | | | | | | | |
| | aluminum salt | | | | | | | | | |
| | Phenidone | 0.01 | 0.01 | 0.01 | 0.01 | 0.01 | | | | 0.01 |
| Compound | Aa-1 | 0.29 | | | | | | | | |
| A or | Aa-2 | | | | | | 0.29 | | | |
| comparative | Aa-3 | | | | 0.29 | | | | | |
| compound | Aa-4 | | | | | 0.29 | | | | |
| | Bb-1 | | 0.29 | | | | | | | |
| | Bb-2 | | | | | | | 0.29 | | |
| | Cc-1 | | | 0.29 | | | | | 0.29 | |
| | F552 | | | | | | | | | 0.29 |
| Solvent | 1-methoxy-2- | 227 | 227 | 227 | 227 | 227 | 227 | 227 | 227 | 227 |
| | propylacetate | | | | | | | | | |
| | Methyl ethyl ketone | 340 | 340 | 340 | 340 | 340 | 340 | 340 | 340 | 340 |

| | | | | | | | | | |
|---|---|---|---|---|---|---|---|---|---|
| Average film thickness of | 2.0 | 2.0 | 2.0 | 2.0 | 2.0 | 2.0 | 2.0 | 2.0 | 2.0 |
| photosensitive resin layer (μm) | | | | | | | | | |

Details of each component in Table 1 are as follows.
BPE-500: 2,2-bis (4-((meth)acryloxypentethoxy)phenyl)propane, manufactured by SHIN-NAKAMURA CHEMICAL Co., Ltd.
BPE-200: 2,2-bis(4-((meth)acryloxydiethoxy)phenyl)propane, manufactured by SHIN-NAKAMURA CHEMICAL Co., Ltd.
M-270: Polypropylene glycol diacrylate (n≈12), manufactured by Toagosei Co., Ltd.
A-TMPT: Trimethylolpropane triacrylate, manufactured by SHIN-NAKAMURA CHEMICAL Co., Ltd.
SR-454: Ethoxylated (3) trimethylolpropane triacrylate, manufactured by Arkema S.A.
SR-502: ethoxylated (9) trimethylolpropane triacrylate, manufactured by Arkema S.A.
A-9300-CL1: A caprolactone-modified (meth)acrylate compound, manufactured by SHIN-NAKAMURA CHEMICAL Co., Ltd.
B-CIM: 2,2′-bis(2-chlorophenyl)-4,4′,5,5′-tetraphenylbisimidazole, manufactured by Hampford Research Inc.
SB-PI 701: 4,4′-bis(diethylamino)benzophenone, manufactured by Sanyo Trading Co., Ltd.
Leucocrystal violet: manufactured by Tokyo Chemical Industry Co., Ltd.
Brilliant green: manufactured by Tokyo Chemical Industry Co., Ltd.
N-phenylglycine: manufactured by Tokyo Chemical Industry Co., Ltd.
CBT-1: Carboxybenzotriazole, manufactured by JOHOKU CHEMICAL Co., Ltd.
TDP-G: Phenothiazine, manufactured by Kawaguchi Chemical Industry Company, Limited
Irganox 245: a hindered phenol-based antioxidant, manufactured by BASF SE
N-nitrosophenyl hydroxylamine aluminum salt: manufactured by Fujifilm Wako Pure Chemical Corporation
Phenidone: manufactured by Tokyo Chemical Industry Co., Ltd.
F552: MEGAFACE F552, manufactured by DIC Corporation, a fluorine-based surfactant which does not correspond to the compound A
Aa-1, Aa-2, Aa-3, Aa-4, Bb-1, Bb-2, and Cc-1: Fluorine-containing polymers (Aa-1) to (Aa-4), (Bb-1), (Bb-2), (Cc-1), a fluorinated compound (a-4), respectively manufactured by the methods described above (all correspond to the compound A)

[Test]

### Example 1

The prepared photosensitive resin composition 1 was applied at a width of 1.0 m using a slit-shaped nozzle onto a polyethylene terephthalate film (Lumirror 16KS40 (manufactured by Toray Industries, Inc.)) having a thickness of 16 pm so that the average film thickness of the photosensitive resin layer to be obtained was a specified film thickness.

Then, the polyethylene terephthalate film (the temporary support) was allowed to pass through, over 60 seconds, a drying zone of 3 m in which the temperature was set to 80° C. and the film surface wind speed was set to be 3 m/sec by adjusting the intake amount and the exhaust amount, thereby obtaining a photosensitive resin layer (a negative type photosensitive resin layer) on the temporary support.

### Examples 2 to 8 and Comparative Example 1

Each photosensitive resin layer was produced in the same manner as in the photosensitive resin composition 1 and evaluated, except that the used photosensitive resin composition was changed as described in Table 1.

### Examples 9 and 10, and Comparative Example 2 (Tests in Aspect in which Composition is Thermoplastic Resin Composition)

[Preparation of Thermoplastic Resin Compositions 1 to 3]

The following components were mixed according to parts by mass shown in Table 2 below to prepare thermoplastic resin compositions 1 to 3. It is noted that the unit of the amount of each component is part by mass.

TABLE 2

| | | | | Comparative |
|---|---|---|---|---|
| | | Example 9 | Example 10 | Example 2 |
| | | Thermoplastic | Thermoplastic | Thermoplastic |
| | | resin | resin | resin |
| | | composition 1 | composition 2 | composition 3 |
| Resin | A-4 | 42.85 | 35.15 | 35.15 |
| | Acrybase FF187 (manufactured by Fujikura Kasei | | 35.15 | 35.15 |
| | Co., Ltd.) | | | |
| Coloring agent | B-1 | 0.08 | | |
| Photoacid | C-1 | 0.32 | | |
| generator | | | | |
| Plasticizer | Tricyclodecanedimethanol diacrylate (A-DCP, | 4.63 | 6.01 | 6.01 |
| | manufactured by SHIN-NAKAMURA CHEMICAL Co, Ltd.) | | | |
| | Monomer having carboxy group, ARONIX TO-2349 | 2.31 | 3.00 | 3.00 |
| | (manufactured by Toagosei Co., Ltd.) | | | |
| | Urethane acrylate 8UX-015A | 0.77 | 1.00 | 1.00 |
| | (manufactured by Taisei Fine Chemical Co., Ltd.) | | | |
| Compound A or | Aa-1 (fluorine-containing polymer (Aa-1) manufactured | 0.03 | 0.03 | |
| comparative | by method described above) | | | |
| compound | MEGAFACE F551A (manufactured by DIC Corporation, | | | 0.03 |
| | fluorine-based surfactant which does not correspond | | | |
| | to compound A) | | | |
| Solvent | Methyl ethyl ketone | 39.5 | 39.5 | 39.5 |
| | Propylene glycol monomethyl ether acetate | 9.51 | 9.51 | 9.51 |

| | | | |
|---|---|---|---|
| Average film thickness of thermoplastic resin layer (μm) | 2.0 | 7.0 | 7.0 |

Details of each component in Table 2 are as follows.
A-4: A resin that contains a constitutional unit based on benzyl methacrylate, a constitutional unit based on methyl methacrylate, and a constitutional unit based on acrylic acid by 75% by mass, 10% by mass, and 15% by mass, respectively, with respect to the total mass of the resin, and has a weight-average molecular weight of 30,000. It is noted that A-4 corresponds to a resin which is an alkali-soluble resin which is a thermoplastic resin. In addition, A-4 was added to the thermoplastic resin composition in a form of a solution containing A-4 (solid content concentration: 30.0% by mass, solvent: PGMEA).
ACRYBASE FF187: A solution containing a resin which is a thermoplastic resin and an alkali-soluble resin, solid content (concentration: 40% by mass, solvent: PGMEA, manufactured by Fujikura Kasei Co., Ltd.)

B-1: A compound having the structure shown below (a coloring agent that develops color by an acid)

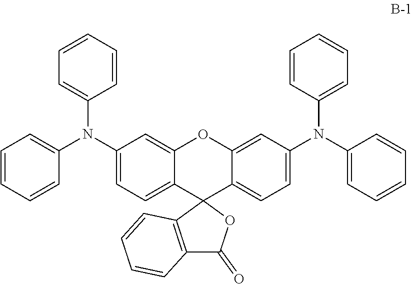 [SMILES: O=C1OC2(c3ccc(N(c4ccccc4)c4ccccc4)cc3Oc3cc(N(c4ccccc4)c4ccccc4)ccc32)c2ccccc21]

C-1: A compound having a structure shown below (a photoacid generator, the compound described in paragraph 0227, which is synthesized according to the method described in paragraph 0227 of JP2013-047765A)

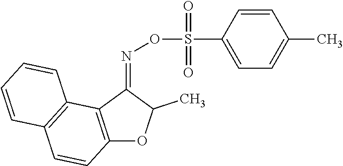 [SMILES: Cc1ccc(S(=O)(=O)O/N=C2/c3c(ccc4ccccc34)OC2C)cc1]

Aa-1: A fluorine-containing polymer (Aa-1) manufactured by the method described above.

[Test]

### Example 9

The prepared thermoplastic resin composition 1 was applied at a width of 1.0 m using a slit-shaped nozzle onto a polyethylene terephthalate film (Lumirror 16KS40 (manufactured by Toray Industries, Inc.)) having a thickness of 16 pm so that the average film thickness of the thermoplastic resin layer to be obtained was a specified film thickness.

Then, the polyethylene terephthalate film (the temporary support) was allowed to pass through, over 60 seconds, a drying zone of 3 m in which the temperature was set to 80° C. and the film surface wind speed was set to be 3 m/sec by adjusting the intake amount and the exhaust amount, thereby obtaining a thermoplastic resin layer on the temporary support.

### Example 10 and Comparative Example 2

Each thermoplastic resin layer was produced in the same manner as in the thermoplastic resin composition 1 and evaluated, except that the average film thicknesses of the used thermoplastic resin composition and the thermoplastic resin layer to be formed were changed as described in Table 2.

### Examples 11 and Comparative Example 3 (Test in Aspect in which Composition is Coloration Resin Composition that is Also Negative Type Photosensitive Resin Composition)

[Preparation of Photosensitive Resin Compositions 10 and 11]

According to the prescriptions described in Table 3 below, components were stirred and mixed to prepare photosensitive resin compositions 10 and 11. It is noted that the unit of the amount of each component is part by mass.

TABLE 3

| | | | Comparative |
|---|---|---|---|
| | | Example 11 | Example 3 |
| | | Photosensitive | Photosensitive |
| | | resin | resin |
| | | composition 10 | composition 11 |
| Pigment | Black pigment dispersion | 186.4 | 186.4 |
| | FDK-T-11 | | |
| Resin | ACRIT 8KB-001 | 182.6 | 182.6 |
| Polymerizable | A-NOD-N | 4.4 | 4.4 |
| compound | A-DCP | 13.3 | 13.3 |
| | 8UX-015A | 8.9 | 8.9 |
| | 75% by mass PGMEA solution of | 3.9 | 3.9 |
| | KAYARAD DPHA | | |
| Photopolymerization | Irgacure OXE-02 | 7.7 | 7.7 |
| initiator | | | |
| Solvent | 1-methoxy-2-propylacetate | 195.8 | 195.8 |
| | Methyl ethyl ketone | 392.5 | 392.5 |
| Additive | 1,2,4-triazole | 3.2 | 3.2 |
| Compound A or | Aa-1 | 0.4 | |
| comparative compound | MEGAFACE F555A | | 1.3 |

| | | |
|---|---|---|
| Average film thickness of photosensitive resin layer (μm) | 3.0 | 3.0 |

Details of the components described in Table 3 are as shown below.

—Pigment—
Black pigment dispersion FDK-T-11: An aqueous solution having a solid content concentration of 27% by mass, pigment: carbon black, manufactured by TOKYO PRINTING INK MFG. Co., Ltd.

—Polymerizable Compound—
A-NOD-N: 1,9-nonanediol diacrylate, manufactured by SHIN-NAKAMURA CHEMICAL Co., Ltd.
A-DCP: Tricyclodecanedimethanol diacrylate (manufactured by SHIN-NAKAMURA CHEMICAL Co., Ltd.)
8UX-015A: Urethane acrylate, manufactured by Taisei Fine Chemical Co., Ltd.
75% by mass PGMEA solution of KAYARAD DPHA: A 75% by mass propylene glycol monomethyl ether acetate solution of KAYARAD DPHA (product name: manufactured by Nippon Kayaku Co., Ltd. The composition of KAYARAD DPHA is shown below.

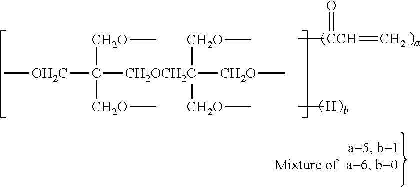

—Resin (Alkali-Soluble Resin)—
ACRIT 8 KB-001: A non-crosslinkable acrylic binder, solid content concentration: 38% by mass, solvent: PGMEA, manufactured by Taisei Fine Chemical Co., Ltd., ACRIT (registered trade name) 8 KB-001)

—Photopolymerization Initiator—
Irgacure OXE-02: manufactured by BASF SE, ethanone, 1-[9-ethyl-6-(2-methylbenzoyl)-9H-carbazole-3-yl]-1-(o-acetyloxime)

—Solvent—
1-methoxy-2-propylacetate
Methyl ethyl ketone

—Additive—
1,2,4-triazole: manufactured by Tokyo Chemical Industry Co., Ltd.

—Compound A or Comparative Compound—
Aa-1: A fluorine-containing polymer (Aa-1) manufactured by the method described above.
MEGAFACE F555A: manufactured by DIC Corporation, a fluorine-based surfactant which does not correspond to the compound A

[Test]

### Example 11

The prepared photosensitive resin composition 10 was applied at a width of 1.0 m using a slit-shaped nozzle onto a polyethylene terephthalate film (Lumirror 16KS40 (manufactured by Toray Industries, Inc.)) having a thickness of 16 pm so that the average film thickness of the photosensitive resin layer to be obtained was a specified film thickness.

Then, the polyethylene terephthalate film (the temporary support) was allowed to pass through, over 60 seconds, a drying zone of 3 m in which the temperature was set to 80° C. and the film surface wind speed was set to be 3 m/sec by adjusting the intake amount and the exhaust amount, thereby obtaining a photosensitive resin layer (a coloration resin layer) on the temporary support.

### Comparative Example 3

Each coating film was produced in the same manner as in the photosensitive resin composition 10 and evaluated, except that the average film thicknesses of the used photosensitive resin composition and the photosensitive resin composition to be formed were changed as described in Table 3.

### Examples 12 and 13 and Comparative Example 4 (Test in Aspect in which Composition is Negative Type Photosensitive Resin Composition)

[Manufacturing of Resin]

<Synthesis of Resin A-5>

Propylene glycol monomethyl ether acetate (60 g, Fujifilm Wako Pure Chemical Corporation) and propylene glycol monomethyl ether (240 g, Fujifilm Wako Pure Chemical Corporation) were introduced into a flask having a capacity of 2,000 mL. The obtained liquid was heated to 90° C. while being stirred at a stirring speed of 250 rounds per minute (rpm; the same applies hereinafter).

For the preparation of a dropping liquid (1), methacrylic acid (107.1 g, manufactured by Mitsubishi Chemical Corporation, product name: Acryester M), methyl methacrylate (5.46 g, manufactured by Mitsubishi Gas Chemical Company, Inc., product name: MMA), and cyclohexyl methacrylate (231.42 g, manufactured by Mitsubishi Gas Chemical Company, Inc., product name: CHMA) were mixed and diluted with propylene glycol monomethyl ether acetate (60.0 g) to obtain the dropping liquid (1).

For the preparation of a dropping liquid (2), dimethyl 2,2′-azobis(2-methylpropionate) (9.637 g, FUJIFILM Wako Pure Chemical Corporation, product name: V-601) was dissolved in propylene glycol monomethyl ether acetate (136.56 g) to obtain a dropping liquid (2).

The dropping liquid (1) and the dropping liquid (2) were simultaneously added dropwise over 3 hours to the above-described flask (specifically, the 2,000 mL flask containing a liquid heated to 90° C.) having a capacity of 2,000 mL. After completion of the dropwise addition, V-601 (2.401 g) was added to the flask every hour three times. Then, stirring was further carried out at 90° C. for 3 hours.

Then, the solution (the reaction solution) obtained in the flask was diluted with propylene glycol monomethyl ether acetate (178.66 g). Next, tetraethylammonium bromide (1.8 g, Fujifilm Wako Pure Chemical Corporation) and hydroquinone monomethyl ether (0.8 g, Fujifilm Wako Pure Chemical Corporation) were added to the above reaction solution. Thereafter, the temperature of the reaction solution was raised to 100° C.

Next, 76.03 g of glycidyl methacrylate (manufactured by NOF Corporation, product name: Blemmer G) was dropwise added to the reaction solution over 1 hour. The above reaction solution was reacted at 100° C. for 6 hours to obtain 1,158 g of a solution of the resin A-5 (solid content concentration: 36.3% by mass). The obtained resin A-5 had a weight-average molecular weight of 27,000, a number-average molecular weight of 15,000, and an acid value of 95 mgKOH/g. The amount of the residual monomer measured by using gas chromatography was less than 0.1% by mass with respect to the polymer solid content.

A resin A-6 was obtained with reference to the synthesis method for the resin A-5.

Specifically, in the dropping liquid (1) used in the synthesis of the resin A-5, the use of the monomers of methacrylic acid (107.1 g), methyl methacrylate (5.46 g), and cyclohexyl methacrylate (231.42 g) was changed to a configuration in which monomers 47.7 parts by mass of styrene, 19 parts by mass of methacrylic acid, and 1.3 parts by mass of methyl methacrylate in terms of mass ratio.

Further, the use of glycidyl methacrylate (76.03 g) was changed to a configuration in which 32 parts by mass of glycidyl methacrylate was used.

The solid content concentration of the obtained solution of the resin A-6 was 36.3% by mass, and the weight-average molecular weight of the obtained resin A-6 was 17,000.

It is noted that all of the resins A-5 and A-6 correspond to the alkali-soluble resin. Each of the resins A-5 and A-6 was added to the photosensitive resin composition in a form of a solution containing each of the resins.

[Synthesis of Blocked Isocyanate Compound]

<Synthesis of Blocked Isocyanate Compound Q-1>

Butanone oxime (manufactured by Idemitsu Kosan Co., Ltd.) (453 g) was dissolved in methyl ethyl ketone (700 g) under a nitrogen stream. To the obtained solution, 1,3-bis(isocyanatomethyl)cyclohexane (a mixture of cis and trans isomers, manufactured by Mitsui Chemicals, Inc., TAKENATE 600) (500 g) was added dropwise over 1 hour under ice cooling, and after the dropwise addition, the reaction was further carried out for 1 hour. Then, the temperature of the solution was raised to 40° C., and the reaction was carried out for 1 hour. It was confirmed that the reaction was completed by ¹H-nuclear magnetic resonance (NMR) and high performance liquid chromatography (HPLC), and a methyl ethyl ketone solution (solid content concentration: 57.7% by mass) of a blocked isocyanate compound Q-1 (see the following formula) was obtained.

It is noted that the blocked isocyanate compound Q-1 was added to the photosensitive resin composition in a form of a solution containing the blocked isocyanate compound Q-1.

| Blocked isocyanate | | |
|---|---|---|
| compound | Structure | NCO value [mmol/g] |
| Q-1 | 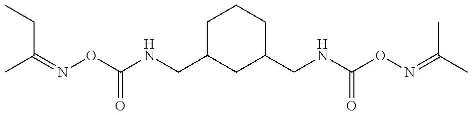 [SMILES: CC/C(C)=N\OC(=O)NCC1CCCC(CNC(=O)ON=C(C)C)C1] | 5.4 |

<Synthesis of Blocked Isocyanate Compound Q-8>

A methyl ethyl ketone solution (solid content concentration: 75.0% by mass) of a blocked isocyanate compound Q-8 (see the following formula) was obtained with reference to a synthesis method for the blocked isocyanate compound Q-1.

It is noted that the blocked isocyanate compound Q-8 was added to the photosensitive resin composition in a form of a solution containing the blocked isocyanate compound Q-8.

| Blocked isocyanate | | |
|---|---|---|
| compound | Structure | NCO value [mmol/g] |
| Q-8 | 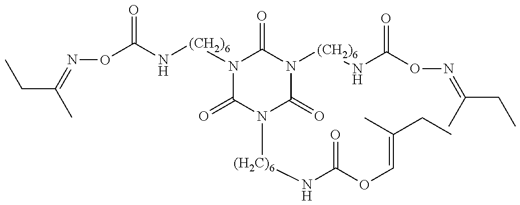 | 3.9 |

[Preparation of Photosensitive Resin Compositions 12 to 14]

According to the prescriptions shown in Table 4 below, components were stirred and mixed to prepare photosensitive resin compositions 12 to 14. It is noted that the unit of the amount of each component is part by mass.

TABLE 4

| | | | | Comparative |
|---|---|---|---|---|
| | | Example 12 | Example 13 | Example 4 |
| | | Photosensitive | Photosensitive | Photosensitive |
| | | resin | resin | resin |
| | | composition 12 | composition 13 | composition 14 |
| Polymerizable | Tricyclodecanedimethanol diacrylate (A-DCP, manufactured | 5.60 | 18.26 | 5.60 |
| compound | by SHIN-NAKAMURA CHEMICAL Co, Ltd.) | | | |
| | 1,9-nonanediol diacrylate (A-NOD-N, manufactured by | | 2.79 | |
| | SHIN-NAKAMURA CHEMICAL Co., Ltd.) | | | |
| | Dipentaerythritol hexaacrylate | | 8.15 | |
| | (A-DPH, manufactured by SHIN-NAKAMURA CHEMICAL Co., Ltd.) | | | |
| | Monomer having carboxy group, ARONIX TO-2349 | 0.93 | 3.04 | 0.93 |
| | (manufactured by Toagosei Co., Ltd.) | | | |
| | Urethane acrylate 8UX-015A | 2.80 | | 2.80 |
| | (manufactured by Taisei Fine Chemical Co., Ltd.) | | | |
| Resin | A-5 | 42.85 | | 42.85 |
| | A-6 | | 49.03 | |
| Photopolymerization | 1-[9-ethyl-6-(2-methylbenzoyl)-9H-carbazole-3-yl]ethanone-1- | 0.11 | 0.37 | 0.11 |
| initiator | (O-acetyloxime) (Irgacure OXE-02, manufactured by BASF SE) | | | |
| | 2-methyl-(4-methylthiophenyl)-2-morpholinopropane-1-one | 0.21 | 0.74 | 0.21 |
| | (Irgacure 907, manufactured by BASF SE) | | | |
| Additive | DURANATE TPA-B80E (blocked isocyanate compound, | 4.53 | | 4.53 |
| | manufactured by Asahi Kasei Chemicals Co., Ltd.) | | | |
| | Blocked isocyanate compound Q-l | | 2.97 | |
| | Blocked isocyanate compound Q-8 | | 12.50 | |
| | N-phenylglycine (manufactured by Tokyo Chemical Industry Co., Ltd.) | 0.03 | 0.10 | 0.03 |
| | Benzimidazole (manufactured by Tokyo Chemical Industry Co., Ltd.) | 0.09 | 0.13 | 0.09 |
| | Isonicotinamide (manufactured by Tokyo Chemical Industry Co., Ltd.) | | 0.52 | |
| | SMAEF-40 (copolymer of styrene/maleic acid anhydride = 4:1 (molar | | 1.20 | |
| | ratio), acid anhydride value: 1.94 mmol/g, Mw: 10,500, | | | |
| | manufactured by Cray Valley) | | | |
| | Aa-1 (fluorine-containing polymer (Aa-1) | 0.16 | 0.16 | — |
| | manufactured by method described above) | | | |
| | MEGAFACE F551A (manufactured by DIC Corporation, fluorine-based | — | — | 0.16 |
| | surfactant which does not correspond to compound A) | | | |
| Solvent | Methyl ethyl ketone | 42.69 | 42.69 | 42.69 |

| | | | |
|---|---|---|---|
| Total (part by mass) | 100 | 143 | 100 |
| Average film thickness of photosensitive resin layer (μm) | 8.0 | 5.0 | 8.0 |

[Test]

### Example 12

Using a slit-shaped nozzle, the coating amount of the photosensitive resin composition was adjusted so that the average film thickness of the photosensitive composition layer after drying was a specified film thickness, and the photosensitive resin composition 12 was applied onto a temporary support of a polyethylene terephthalate film (Lumirror 16KS40 (manufactured by Toray Industries, Inc.)) having a thickness of 16 μm.

Next, the temporary support was allowed to pass through, over 60 seconds, a drying zone of 3 m in which the temperature was set to 80° C. and the film surface wind speed was set to be 3 m/sec by adjusting the intake amount and the exhaust amount, thereby forming a photosensitive resin layer (a negative type photosensitive resin layer) on the temporary support.

### Example 13 and Comparative Example 4

Each coating film was produced in the same manner as in the photosensitive resin composition 12 and evaluated, except that the average film thicknesses of the photosensitive resin composition and the photosensitive resin layer to be formed were changed as described in Table 4.

### Examples 14 and 15 and Comparative Example 5 (Test in Aspect in which Composition is Water-Soluble Resin Composition)

[Preparation of Water-Soluble Resin Compositions 1 to 3]

According to the prescriptions shown in Table 5 below, components were stirred and mixed to prepare water-soluble resin compositions 1 to 3. It is noted that the unit of the amount of each component is part by mass.

It is noted that the water-soluble resin compositions 1 to 3 are suitable compositions for forming the interlayer.

In addition, Kuraray Poval 4-88LA, Kuraray Poval 5-88, and polyvinyl pyrrolidone, which have been used in the preparation of the water-soluble resin compositions 1 to 3, all correspond to water-soluble resin.

TABLE 5

| | | | Comparative |
|---|---|---|---|
| | Example 14 | Example 15 | Example 5 |
| | Water-soluble | Water-soluble | Water-soluble |
| | resin | resin | resin |
| | composition 1 | composition 2 | composition 3 |
| Kuraray Poval 4-88LA (manufactured by KURARAY Co., Ltd., polyvinyl | 32.2 | | |
| alcohol having degree of saponification: 86.7 to 88.7% by mole) | | | |
| Kuraray Poval 5-88 (manufactured by KURARAY Co., Ltd., polyvinyl | | 32.2 | 32.2 |
| alcohol having degree of saponification: 86.5 to 89.0% by mole) | | | |
| Polyvinyl pyrrolidone (manufactured by NIPPON SHOKUBAI Co., Ltd.) | 14.90 | 14.90 | 14.90 |
| a-4 (fluorine-containing compound (a-4) manufactured by method | 0.01 | 0.01 | |
| described above) | | | |
| MEGAFACE F444 (manufactured by DIC CORPORATION, fluorine-based | | | 0.01 |
| surfactant which does not correspond to compound A) | | | |
| Ion exchange water | 524.0 | 524.0 | 524.0 |
| Methanol (manufactured by Mitsubishi Chemical Corporation) | 429.0 | 429.0 | 429.0 |
| Total (part by mass) | 1000.1 | 1000.1 | 1000.1 |
| Average film thickness of composition layer (μm) | 1.0 | 1.0 | 1.0 |

[Test]

### Example 14

Using a slit-shaped nozzle, the coating amount was adjusted so that the average film thickness of the composition layer after drying was a specified film thickness, and the water-soluble resin composition 1 was applied onto a temporary support of a polyethylene terephthalate film (Lumirror 16KS40 (manufactured by Toray Industries, Inc.)) having a thickness of 16 pm.

Then, the temporary support was allowed to pass through, over 60 seconds, a drying zone of 3 m in which the temperature was set to 100° C. and the film surface wind speed was set to be 3 m/sec by adjusting the intake amount and the exhaust amount, thereby forming a composition layer (a water-soluble resin layer) on the temporary support.

### Example 15 and Comparative Example 5

Each composition layer was produced in the same manner as in the water-soluble resin composition 1 and evaluated, except that the average film thicknesses of the used water-soluble resin composition and the composition layer to be formed were changed as described in Table 5.

### Examples 16 and 17 and Comparative Example 6 (Test in Aspect in which Composition is Composition Containing Specific Material)

[Manufacturing of Resin]

<Synthesis of Resin A-7>

Propylene glycol monomethyl ether (270.0 g) was introduced into a three-neck flask, and the temperature was raised to 70° C. under a nitrogen stream while stirring.

On the other hand, allyl methacrylate (45.6 g, Fujifilm Wako Pure Chemical Corporation) and methacrylic acid (14.4 g) were dissolved in propylene glycol monomethyl ether (270.0 g), and further, V-65 (3.94 g, FUJIFILM Wako Pure Chemical Corporation) was dissolved therein to prepare a dropping liquid, which was added dropwise into the flask over 2.5 hours. The stirred state was maintained as it was, and the reaction was carried out for 2.0 hours. Then, the temperature of the contents in the flask was returned to room temperature, the contents in the flask were added dropwise into 2.7 L of ion-exchanged water in a stirred state, and reprecipitation was carried out to obtain a suspension. The suspension was filtered through Nutche (a Buchner funnel) in which a filter paper was placed, and the filtrate was further washed with ion-exchanged water to obtain a powder in a state of being wet. It was subjected to blast drying at 45° C., and it was confirmed that a constant weight was reached, whereby a resin A-7 was obtained as a powder at a yield of 70%. The amount of the residual monomer measured by using gas chromatography was less than 0.1% by mass with respect to the polymer solid content.

[Preparation of Water-Soluble Resin Compositions 4 to 6]

According to the prescriptions shown in Table 6 below, components were stirred and mixed to prepare water-soluble resin compositions 4 to 6. It is noted that the unit of the amount of each component is part by mass.

It is noted that the water-soluble resin compositions 4 to 6 are compositions containing a specific material, which are used for forming the refractive index adjusting layer.

In addition, the resin A-7 and ARUFON UC-3920 which are used in the preparation of the water-soluble resin compositions 4 to 6 have solubility in alkali and solubility in water.

TABLE 6

| | | | | Comparative |
|---|---|---|---|---|
| | | Example 16 | Example 17 | Example 6 |
| | | Water-soluble | Water-soluble | Water-soluble |
| | | resin | resin | resin |
| | | composition 4 | composition 5 | composition 6 |
| NanoUse OZS-30M (ZrO₂ particle (containing tin oxide)) Methanol dispersion liquid | | 4.34 | 4.34 | 4.34 |
| non-volatile fraction: 30.5%, manufactured by Nissan Chemical Industries, Ltd.) | | | | |
| Ammonia water (25%) | | 7.84 | 7.84 | 7.84 |
| Resin | A-7 (acid value: 130 mg KOH/g, resin P-2 | 0.21 | 0.20 | 0.21 |
| | manufactured by method described above) | | | |
| | ARUFON UC-3920 (styrene-acrylic resin having | 0.08 | 0.02 | 0.08 |
| | carboxy group, manufactured by Toagosei Co., Ltd.) | | | |

| | | | |
|---|---|---|---|
| ARONIX TO-2349 (monomer having carboxy group, manufactured by Toagosei Co., Ltd.) | 0.03 | 0.03 | 0.03 |
| Benzotriazole BT-LX (1-[N,N-bis(2-ethylhexyl)aminomethyl]benzotriazole, | 0.03 | | 0.03 |
| manufactured by JOHOKU CHEMICAL Co., Ltd.) | | | |
| Adenine (manufactured by Tokyo Chemical Industry Co., Ltd.) | | 0.03 | |
| N-methyldiethanolamine (manufactured by Tokyo Chemical Industry Co., Ltd.) | | 0.03 | |
| Monoisopropanolamine | 0.02 | | 0.02 |
| a-4 (fluorine-containing compound (a-4) manufactured by method described above) | 0.01 | 0.01 | — |
| MEGAFACE F444 fluorine-based surfactant which does not correspond to compound A, | | | 0.01 |
| manufactured by DIC Corporation) | | | |
| Ion exchange water | 21.7 | 21.3 | 21.7 |
| Methanol | 65.8 | 66.2 | 65.8 |
| Total (part by mass) | 100.0 | 100.0 | 100.0 |
| Average film thickness of composition layer (μm) | 80 | 80 | 80 |

[Test]

### Example 16

Using a slit-shaped nozzle, the coating amount was adjusted so that the average film thickness of the composition layer after drying was a specified film thickness, and the water-soluble resin composition 4 was applied onto a temporary support of a polyethylene terephthalate film (Lumirror 16KS40 (manufactured by Toray Industries, Inc.)) having a thickness of 16 μm.

Then, the temporary support was allowed to pass through, over 60 seconds, a drying zone of 3 m in which the temperature was set to 80° C. and the film surface wind speed was set to be 3 nm/sec by adjusting the intake amount and the exhaust amount, thereby forming a composition layer (a refractive index adjusting layer) on the temporary support.

### Example 17 and Comparative Example 6

Each composition layer was produced in the same manner as in the water-soluble resin composition 4 and evaluated, except that the average film thicknesses of the used water-soluble resin composition and the composition layer to be formed were changed as described in Table 6.

### Example 18 and Comparative Example 7 (Test in Aspect in which Composition is Chemical Amplification Type Photosensitive Resin Composition)

[Manufacturing of Resin]

<Abbreviation for Compound>

In the following synthesis examples, the following abbreviations respectively represent the following compounds.

ATHF: Tetrahydrofuran-2-yl acrylate (a synthetic product)

AA: Acrylic acid (manufactured by Fujifilm Wako Pure Chemical Corporation)

EA: Ethyl acrylate (manufactured by Fujifilm Wako Pure Chemical Corporation)

MMA: Methyl methacrylate (manufactured by FUJIFILM Wako Pure Chemical Corporation)

CHA: Cyclohexyl acrylate (manufactured by Fujifilm Wako Pure Chemical Corporation)

PMPMA: 1,2,2,6,6-pentamethyl-4-piperidyl methacrylate (manufactured by FUJIFILM Wako Pure Chemical Corporation)

PGMEA: Propylene glycol monomethyl ether acetate (manufactured by Showa Denko K.K.)

V-601: Dimethyl-2,2′-azobis(2-methylpropionate) (manufactured by FUJIFILM Wako Pure Chemical Corporation)

<Synthesis of ATHF>

Acrylic acid (72.1 parts by mass, 1.0 molar equivalent) and hexane (72.1 parts by mass) were added to a three-neck flask and cooled to 20° C. After dropwise adding camphorsulfonic acid (0.007 parts by mass, 0.03 mmol equivalent) and 2-dihydrofuran (77.9 parts by mass, 1.0 molar equivalent) into the flask, the contents (the reaction solution) in the flask were stirred at 20° C.±2° C. for 1.5 hours, the temperature was subsequently raised to 35° C., and stirring was carried out for 2 hours. After spreading KYOWAAD 200 (a filter material, an aluminum hydroxide powder, manufactured by Kyowa Chemical Industry Co., Ltd.) and KYOWAAD 1000 (a filter material, a hydrotalcite powder, manufactured by Kyowa Chemical Industry Co., Ltd.) on Nutche (a Buchner funnel) in this order, the above reaction solution was filtered to obtain a filtrate. Hydroquinone monomethyl ether (MEHQ, 0.0012 parts) was added to the obtained filtrate, and then the concentration under reduced pressure was carried out at 40° C. to prepare 140.8 parts of tetrahydrofuran-2-yl acrylate (ATHF) as a colorless oily substance (yield: 99.0%).

### Synthesis Example of Resin A-8

PGMEA (75.0 parts) was placed in a three-neck flask, and the temperature was raised to 90° C. in a nitrogen atmosphere. A solution to which ATHF (29.0 parts), MMA (35.0 parts), ethyl acrylate (EA, 30.0 parts), cyclohexyl acrylate (CHA, 5.0 parts), 1,2,2,6,6-pentamethyl-4-piperidyl methacrylate (PMPMA, 1.0 parts), V-601 (4.0 parts), and PGMEA (75.0 parts) was added dropwise over 2 hours to a solution in a three-neck flask maintained at 90° C.±2° C. After completion of the dropwise addition, stirring was carried out at 90° C.±2° C. for 2 hours to obtain a solution containing the resin A-8 (solid content concentration: 40.0% by mass). It is noted that the resin A-8 was added to each photosensitive resin composition in a form of a solution containing the resin A-8.

[Photoacid Generator]

A photoacid generator shown below was used in the preparation of the photosensitive composition.

C-1: A compound having a structure shown below (the compound described in paragraph 0227, which is synthesized according to the method described in paragraph 0227 of JP2013-047765A) (the same one as the photoacid generator C-1 used in the production of the thermoplastic resin compositions 1 to 3)

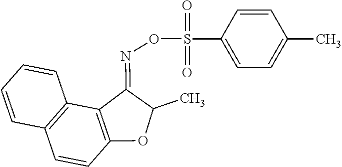 [SMILES: Cc1ccc(S(=O)(=O)O/N=C2/c3c(ccc4ccccc34)OC2C)cc1]

[Benzotriazole Compound]

A benzotriazole compound shown below was used in the preparation of the photosensitive composition.

D-1: 1,2,3-benzotriazole (the following compound)

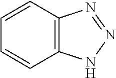

[Preparation of Photosensitive Resin Compositions 15 and 16]

According to the prescriptions shown in Table 7 below, components were stirred and mixed to prepare photosensitive resin compositions 15 and 16. It is noted that the unit of the amount of each component is part by mass.

TABLE 7

| | | Comparative |
|---|---|---|
| | Example 18 | Example 7 |
| | Photosensitive | Photosensitive |
| | resin | resin |
| | composition 15 | composition 16 |
| A-8 | 94.12 | 94.12 |
| C-1 | 5 | 5 |
| D-1 | 0.17 | 0.17 |
| Aa-1 (fluorine-containing compound (Aa-1) | 0.13 | |
| manufactured by method described above) | | |
| MEGAFACE F552 (manufactured by DIC Corporation, fluorine-based | | 0.13 |
| surfactant which does not correspond to compound A) | | |
| n-propyl acetate | 567 | 567 |
| Average film thickness of photosensitive resin layer (μm) | 3.0 | 3.0 |

[Test]

### Example 18

Using a slit-shaped nozzle, the coating amount of the photosensitive resin composition 15 was adjusted so that the average film thickness of the photosensitive resin layer after drying was a specified film thickness, and the photosensitive resin composition 15 was applied onto a temporary support of a polyethylene terephthalate film (Lumirror 16KS40 (manufactured by Toray Industries, Inc.)) having a thickness of 16 pm.

Then, the temporary support was allowed to pass through, over 60 seconds, a drying zone of 3 m in which the temperature was set to 80° C. and the film surface wind speed was set to be 3 m/sec by adjusting the intake amount and the exhaust amount, thereby forming a photosensitive resin layer (a chemical amplification type photosensitive resin layer) on the temporary support.

### Comparative Example 7

Each photosensitive resin layer was produced in the same manner as in the photosensitive resin composition 15 and evaluated, except that the used photosensitive resin composition was changed as described in Table 7.

[Evaluation of Coatability]

By observing a state from application to drying, the coatability of the composition in a case where the composition layer (the photosensitive resin layer or the like) was formed by using each composition (the photosensitive resin composition or the like) as described above was evaluated based on five stages of A to E.

The meanings of A to E are as follows. It is noted that a level of C or higher is a practical level.

A: Immediately after coating, the coating is completely uniform over the entire surface, and the coatability is extremely good.

B: Immediately after coating, only a few millimeters of both ends of the coating liquid film are coated slightly thickly; however, leveling is achieved by the time when dried, and the coatability is good.

C: Immediately after coating, slight unevenness is observed; however, leveling is achieved by the time when dried except for a few millimeters of both ends of the coating liquid film, and the coatability is normal.

D: Immediately after coating, no cissing is observed; however, unevenness is observed, leveling is not achieved by the time when dried, and the coatability is poor.

E: Immediately after coating, cissing occurs on the entire surface or coating cannot be achieved, and the coatability is extremely poor.

The results of the evaluation are shown below.

In the following, the “used compound” indicates the kind of the compound A or the comparative compound contained in the composition.

| | | Used | Evaluation |
|---|---|---|---|
| Test example | Composition | compound | result |
| Example 1 | Photosensitive resin composition 1 | Aa-1 | A |
| Example 2 | Photosensitive resin composition 2 | Bb-1 | B |
| Example 3 | Photosensitive resin composition 3 | Cc-1 | C |
| Example 4 | Photosensitive resin composition 4 | Aa-3 | A |
| Example 5 | Photosensitive resin composition 5 | Aa-4 | A |
| Example 6 | Photosensitive resin composition 6 | Aa-2 | A |
| Example 7 | Photosensitive resin composition 7 | Bb-2 | B |
| Example 8 | Photosensitive resin composition 8 | Cc-1 | B |
| Comparative Example 1 | Photosensitive resin composition 9 | F552 | D |
| Example 9 | Thermoplastic resin composition 1 | Aa-1 | A |
| Example 10 | Thermoplastic resin composition 2 | Aa-1 | A |
| Comparative Example 2 | Thermoplastic resin composition 3 | F551A | D |
| Example 11 | Photosensitive resin composition 10 | Aa-1 | A |
| Comparative Example 3 | Photosensitive resin composition 11 | F555A | D |
| Example 12 | Photosensitive resin composition 12 | Aa-1 | A |
| Example 13 | Photosensitive resin composition 13 | Aa-1 | A |
| Comparative Example 4 | Photosensitive resin composition 14 | F551A | D |
| Example 14 | Water-soluble resin composition 1 | a-4 | A |
| Example 15 | Water-soluble resin composition 2 | a-4 | A |
| Comparative Example 5 | Water-soluble resin composition 3 | F444 | E |
| Example 16 | Water-soluble resin composition 4 | a-4 | A |
| Example 17 | Water-soluble resin composition 5 | a-4 | A |
| Comparative Example 6 | Water-soluble resin composition 6 | F444 | E |
| Example 18 | Photosensitive resin composition 15 | Aa-1 | A |
| Comparative Example 7 | Photosensitive resin composition 16 | F552 | D |

From the results of Examples, it has been confirmed that the composition according to the embodiment of the present invention has excellent coatability and enables the production of a film having high homogeneity.

Among the above, in a case where the composition contains the compound A containing the specific structure (a), it has been confirmed that the coatability is more excellent.

[[Preparation of Transfer Film]]

Transfer films DFR1 to DFR24 were produced using the above-described compositions.

The produced transfer film is a transfer film having a configuration in which one to three layers (the first to third composition layers) of the composition layer formed of the above-described composition are formed on a temporary support, and further, a cover film is affixed on the formed composition layer.

It is noted that among the first to third composition layers, the first composition layer was always formed, and the second composition layer and the third composition layer were optionally formed. In addition, the first composition layer, the second composition layer formed as desired, and the third composition layer formed as desired were formed in this order from the temporary support side.

The specific configuration of the produced transfer film is shown below.

In the table, the description of “16KS40” means a polyethylene terephthalate film having a thickness of 16 pm (a product of Toray Industries, Inc.), the description of “16FB40” means a polyethylene terephthalate film having a thickness of 16 pm (a product of Toray Industries, Inc.), and the description of “12KW37” means a polypropylene film having a thickness of 12 pm (a product of Toray Industries, Inc.).

Regarding the following transfer films, for example, DFR1 to DFR14 can be suitably used for a use application to an etching resist, DFR15 to DFR21 can be suitably used for a use application to wire protective film formation, and DFR22 to DFR24 can be suitably used for a use application to light shielding film formation.

TABLE 8

| | Configuration of transfer film | | | | |
|---|---|---|---|---|---|
| | | First composition layer | Second composition layer | | |
| | Temporary | (positioned on temporary | (positioned between first resin | Third composition layer | Cover |
| | support | support side) | layer and second resin layer) | (positioned on cover film side) | film |
| DFR1 | 16KS40 | Thermoplastic resin composition 1 | Water-soluble resin composition 1 | Photosensitive resin composition 1 | 16KS40 |
| | | (Film thickness: 2.0 μm) | (Film thickness: 1.0 μm) | (Film thickness: 2.0 μm) | |
| DFR2 | 16FB40 | Photosensitive resin composition 6 | Absent | Absent | 12KW37 |
| | | (Film thickness: 5.0 μm) | | | |
| DFR3 | 16KS40 | Photosensitive resin composition 15 | Absent | Absent | 12KW37 |
| | | (Film thickness: 3.0 μm) | | | |
| DFR4 | 16KS40 | Thermoplastic resin composition 2 | Water-soluble resin composition 2 | Photosensitive resin composition 15 | 16KS40 |
| | | (Film thickness: 7.0 μm) | (Film thickness: 1.0 μm) | (Film thickness: 3.0 μm) | |
| DFR5 | 16KS40 | Photosensitive resin composition 7 | Absent | Absent | 12KW37 |
| | | (Film thickness: 5.0 μm) | | | |
| DFR6 | 16KS40 | Photosensitive resin composition 8 | Absent | Absent | 12KW37 |
| | | (Film thickness: 5.0 μm) | | | |
| DFR7 | 16KS40 | Photosensitive resin composition 1 | Absent | Absent | 12KW37 |
| | | (Film thickness: 5.0 μm) | | | |
| DFR8 | 16KS40 | Photosensitive resin composition 3 | Absent | Absent | 12KW37 |
| | | (Film thickness: 5.0 μm) | | | |
| DFR9 | 16KS40 | Thermoplastic resin composition 1 | Water-soluble resin composition 1 | Photosensitive resin composition 2 | 16KS40 |
| | | (Film thickness: 2.0 μm) | (Film thickness: 1.0 μm) | (Film thickness: 2.0 μm) | |
| DFR10 | 16KS40 | Thermoplastic resin composition 2 | Water-soluble resin composition 2 | Photosensitive resin composition 3 | 16KS40 |
| | | (Film thickness: 2.0 μm) | (Film thickness: 1.0 μm) | (Film thickness: 2.0 μm) | |
| DFR11 | 16KS40 | Thermoplastic resin composition 2 | Water-soluble resin composition 2 | Photosensitive resin composition 4 | 16KS40 |
| | | (Film thickness: 2.0 μm) | (Film thickness: 1.0 μm) | (Film thickness: 2.0 μm) | |
| DFR12 | 16KS40 | Thermoplastic resin composition 1 | Water-soluble resin composition 1 | Photosensitive resin composition 5 | 16KS40 |
| | | (Film thickness: 2.0 μm) | (Film thickness: 1.0 μm) | (Film thickness: 2.0 μm) | |
| DFR13 | 16KS40 | Thermoplastic resin composition 1 | Water-soluble resin composition 1 | Photosensitive resin composition 6 | 16KS40 |
| | | (Film thickness: 2.0 μm) | (Film thickness: 1.0 μm) | (Film thickness: 2.0 μm) | |
| DFR14 | 16KS40 | Thermoplastic resin composition 1 | Water-soluble resin composition 1 | Photosensitive resin composition 7 | 16KS40 |
| | | (Film thickness: 2.0 μm) | (Film thickness: 1.0 μm) | (Film thickness: 2.0 μm) | |
| DFR15 | 16KS40 | Photosensitive resin composition 13 | Absent | Water-soluble resin composition 5 | 16KS40 |
| | | (Film thickness: 5.0 μm) | | (Film thickness: 80 nm) | |
| DFR16 | 16KS40 | Photosensitive resin composition 12 | Absent | Water-soluble resin composition 4 | 16KS40 |
| | | (Film thickness: 8.0 μm) | | (Film thickness: 80 nm) | |
| DFR17 | 16KS40 | Photosensitive resin composition 13 | Absent | Water-soluble resin composition 4 | 16KS40 |
| | | (Film thickness: 5.0 μm) | | (Film thickness: 80 nm) | |
| DFR18 | 16KS40 | Photosensitive resin composition 12 | Absent | Water-soluble resin composition 5 | 16KS40 |
| | | (Film thickness: 8.0 μm) | | (Film thickness: 80 nm) | |
| DFR19 | 16KS40 | Photosensitive resin composition 13 | Absent | Water-soluble resin composition 5 | 16KS40 |
| | | (Film thickness: 8.0 μm) | | (Film thickness: 80 nm) | |
| DFR20 | 16KS40 | Photosensitive resin composition 12 | Absent | Water-soluble resin composition 4 | 16KS40 |
| | | (Film thickness: 5.0 μm) | | (Film thickness: 80 nm) | |
| DFR21 | 16KS40 | Photosensitive resin composition 12 | Absent | Absent | 12KW37 |
| | | (Film thickness: 5.0 μm) | | | |
| DFR22 | 16KS40 | Thermoplastic resin composition 2 | Water-soluble resin composition 2 | Photosensitive resin composition 10 | 16KS40 |
| | | (Film thickness: 7.0 μm) | (Film thickness: 1.0 μm) | (Film thickness: 3.0 μm) | |
| DFR23 | 16KS40 | Photosensitive resin composition 10 | Absent | Absent | 12KW37 |
| | | (Film thickness: 3.0 μm) | | | |
| DFR24 | 16KS40 | Thermoplastic resin composition 1 | Water-soluble resin composition 1 | Photosensitive resin composition 10 | 16KS40 |
| | | (Film thickness: 2.0 μm) | (Film thickness: 1.0 μm) | (Film thickness: 3.0 μm) | |

### EXPLANATION OF REFERENCES

10: temporary support
12: thermoplastic resin layer
14: water-soluble resin layer (interlayer)
16: negative type photosensitive resin layer
18: cover film

What is claimed is:

1. A composition comprising:
a compound A having one or more specific structures selected from the group consisting of (a), (b), and (c); and
a resin;
(a) a perfluoroalkenyl group,
(b) a perfluoropolyether group, and
(c) a group represented by General Formula (C1) or General Formula (C2),
*—Cm⁺Am⁻[-L^{m}-(Rf)ₘ₂]ₘ₁ (C1)
*-An⁻Cn⁺[-Lⁿ-(Rf)ₙ₂]ₙ₁ (C2)
in General Formula (C1), * represents a bonding position, m1 represents an integer of 1 or more, m2 represents an integer of 1 or more, Cm⁺ represents a cationic group, Am⁻ represents an anionic group, L^{m} represents a single bond or an (m2+1)-valent linking group, and Rf represents a fluoroalkyl group.
in General Formula (C2), * represents a bonding position, n1 represents an integer of 1 or more, n2 represents an integer of 1 or more, An⁻ represents an anionic group, Cn⁺ represents a cationic group, Lⁿ represents a single bond or an (n2+1)-valent linking group, and Rf represents a fluoroalkyl group.

2. The composition according to claim 1,
wherein the (a) is a group selected from the group consisting of a group represented by General Formula (a1), a group represented by General Formula (a2), and a group represented by General Formula (a-3), 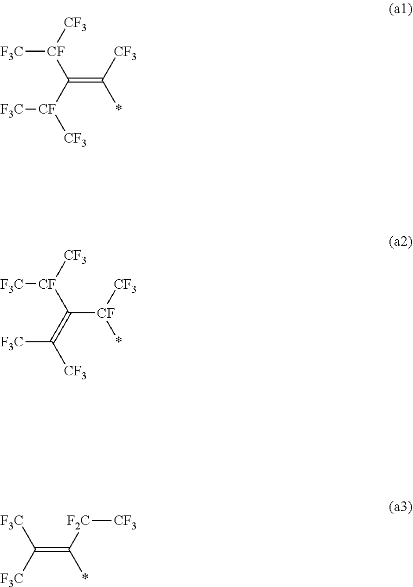
in General Formulae (a1) to (a3), * represents a bonding position.

3. The composition according to claim 1,
wherein the compound A is a high-molecular-weight compound containing a constitutional unit having the specific structure in a side chain.

4. The composition according to claim 1,
wherein the compound A has a molecular weight of 2,000 or less.

5. The composition according to claim 1, further comprising:
a polymerizable compound; and
a polymerization initiator,
wherein the resin is an alkali-soluble resin.

6. The composition according to claim 1, further comprising:
a photoacid generator,
wherein the resin is a resin having an acid group protected by an acid-decomposable group.

7. The composition according to claim 1,
wherein the resin is a water-soluble resin.

8. The composition according to claim 1,
wherein the resin is a thermoplastic resin.

9. The composition according to claim 1, further comprising one or more kinds of materials selected from the group consisting of a metal oxide, a compound having a triazine ring, and a compound having a fluorene skeleton.

10. The composition according to claim 1, further comprising a pigment.

11. A transfer film comprising:
a temporary support; and
one or more composition layers,
wherein at least one layer of the composition layers is a layer formed of the composition according to claim 1.

12. A manufacturing method for a laminate, comprising:
an affixing step of bringing a substrate into contact with a surface of the transfer film according to claim 11 on a side opposite to the temporary support and affixing the transfer film to the substrate to obtain a transfer film-attached substrate;
an exposure step of subjecting the composition layer to pattern exposure;
a development step of developing the exposed composition layer to form a resin pattern; and
a peeling step of peeling the temporary support from the transfer film-attached substrate, between the affixing step and the exposure step or between the exposure step and the development step.

13. A manufacturing method for a circuit wire, comprising:
an affixing step of bringing a surface of the transfer film according to claim 11 on a side opposite to the temporary support into contact with a substrate having a conductive layer and affixing the transfer film to the substrate having the conductive layer to obtain a transfer film-attached substrate;
an exposure step of subjecting the composition layer to pattern exposure;
a development step of developing the exposed composition layer to form a resin pattern;
an etching step of subjecting the conductive layer in a region where the resin pattern is not disposed to an etching treatment; and
a peeling step of peeling the temporary support from the transfer film-attached substrate, between the affixing step and the exposure step or between the exposure step and the development step.

14. A manufacturing method for an electronic device, comprising:
the manufacturing method for a laminate according to claim 12,
wherein the electronic device includes the resin pattern as a cured film.

15. A composition comprising:
a compound A having one or more specific structures selected from the group consisting of (a), (b), and (c); and
a resin,
wherein the (a) is a group selected from the group consisting of a group represented by General Formula (a1), a group represented by General Formula (a2), and a group represented by General Formula (a3),
wherein the compound A is a high-molecular-weight compound containing a constitutional unit having the specific structure in a side chain and has a molecular weight of 2,000 or less,
wherein the composition further comprises a polymerizable compound and a polymerization initiator, and
wherein the resin is an alkali-soluble resin,
(a) a perfluoroalkenyl group,
(b) a perfluoropolyether group, and
(c) a group represented by General Formula (C1) or General Formula (C2),
*—Cm⁺Am⁻[-L^{m}-(Rf)ₘ₂]ₘ₁ (C1)
*-An⁻Cn⁺[-Lⁿ-(Rf)ₙ₂]ₙ₁ (C2)
in General Formula (C1), * represents a bonding position, m1 represents an integer of 1 or more, m2 represents an integer of 1 or more, Cm⁺ represents a cationic group, Am⁻ represents an anionic group, L^{m} represents a single bond or an (m2+1)-valent linking group, and Rf represents a fluoroalkyl group,
in General Formula (C2), * represents a bonding position, n1 represents an integer of 1 or more, n2 represents an integer of 1 or more, An⁻ represents an anionic group, Cn⁺ represents a cationic group, Lⁿ represents a single bond or an (n2+1)-valent linking group, and Rf represents a fluoroalkyl group, 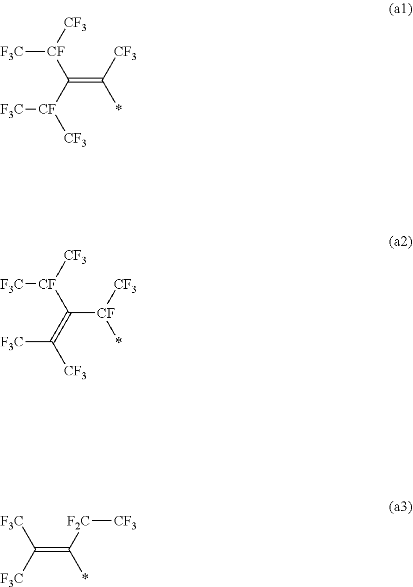
in General Formulae (a1) to (a3), * represents a bonding position.

16. The composition according to claim 15,
wherein the alkali-soluble resin contains a constitutional unit based on a monomer having a carboxy group and a constitutional unit based on a monomer having an aromatic hydrocarbon group.

17. The composition according to claim 15,
wherein the polymerizable compound is a bifunctional ethylenically unsaturated compound having a bisphenol A structure.

18. A cured film formed by curing the composition according to claim 15.
